(19) United States
(12) Patent Application Publication
(10) Pub. No.: US 2026/0111622 A1
(43) Pub. Date: Apr. 23, 2026

(54) TANGIBLE/VIRTUAL DESIGN SYSTEMS AND METHODS FOR AMUSEMENT PARK ATTRACTION DESIGN

(71) Applicant: Universal City Studios LLC, Universal City, CA (US)

(72) Inventors: Akiva Meir Krauthamer, Ocoee, FL (US); Timothy Fitzgerald Garnier, Orlando, FL (US)

(21) Appl. No.: 19/424,032

(22) Filed: Dec. 17, 2025

Related U.S. Application Data
(63) Continuation-in-part of application No. 18/242,444, filed on Sep. 5, 2023.
(60) Provisional application No. 63/495,954, filed on Apr. 13, 2023.
(60) Provisional application No. 63/403,981, filed on Sep. 6, 2022.

(51) Int. Cl. G06F 30/17

(52) U.S. Cl. CPC G06F 30/17

(57) ABSTRACT

An amusement park attraction design system may include an object token comprising a sensor to generate a sensor signal, an image sensor to generate image data indicative of the object token, and a controller communicatively coupled to the image sensor. The controller may receive the image data from the image sensor, determine movement of the object token based on the image data, and generate first image content based on the sensor signal indicating that the movement is intentional. The controller may also generate second image content based on the sensor signal indicating that the movement is unintentional. The amusement park attraction design system may also include a projector communicatively coupled to the controller, where the projector outputs the first image content or the second image content.

### CROSS REFERENCE TO RELATED APPLICATIONS

This application is a continuation-in-part of U.S. Application No. 18/242,444, filed September 5, 2023, and entitled “TANGIBLE/VIRTUAL DESIGN SYSTEMS AND METHODS FOR AMUSEMENT PARK ATTRACTION DESIGN,” which claims benefit of U.S. Provisional Application No. 63/403,981, entitled “TANGIBLE/VIRTUAL DESIGN SYSTEMS AND METHODS FOR AMUSEMENT PARK ATTRACTION DESIGN,” filed September 6, 2022, and U.S. Provisional Application No. 63/495,954, entitled “TANGIBLE/VIRTUAL DESIGN SYSTEMS AND METHODS FOR AMUSEMENT PARK ATTRACTION DESIGN,” filed April 13, 2023, both of which are hereby incorporated by reference in their entireties for all purposes.

### BACKGROUND

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Throughout amusement parks and other entertainment venues, special effects can be used to help immerse guests in the experience of a ride or attraction. Immersive environments may include three-dimensional (3D) props and set pieces, robotic or mechanical elements, and/or display surfaces that present media. In addition, the immersive environment may include audio effects, smoke effects, and/or motion effects. Thus, immersive environments may include a combination of dynamic and static elements. However, design, implementation, and operation of special effects may be complex. For example, it may be difficult to operate certain elements of the special effects in a consistent and desirable manner to create the immersive environment. With the increasing sophistication and complexity of modern ride attractions and experiences, and the corresponding increase in expectations among theme or

amusement park guests, present techniques for designing attractions may be time-consuming and costly. As such, techniques to efficiently design and ensure consistent operation may be desirable.

### BRIEF DESCRIPTION

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In an embodiment, an amusement park attraction design system may include an object token comprising a sensor to generate a sensor signal, an image sensor to generate image data indicative of the object token, and a controller communicatively coupled to the image sensor. The controller may receive the image data from the image sensor, determine movement of the object token based on the image data, and generate first image content based on the sensor signal indicating that the movement is intentional. The controller may also generate second image content based on the sensor signal indicating that the movement is unintentional. The amusement park attraction design system may also include a projector communicatively coupled to the controller, where the projector outputs the first image content or the second image content.

In an embodiment, a method may include, by processing circuitry, receiving, image data indicative of an object token from an image sensor, where the object token comprises a sensor to generate a sensor signal and determining an indication of movement of the object token based on the image data. The method may also generate, via the processing circuitry, first image content based on the sensor signal indicating that the movement of the object token is intentional and generate, via the processing circuitry, second image content based on the sensor signal indicating that the movement of the object token is unintentional.

In an embodiment, an amusement park attraction design system may include an object token including a tracker, machine-readable indicia, and a sensor, where the sensor generates a sensor signal, an image sensor to generate image data indicative of the object token, and a controller communicatively coupled to the image sensor. The

controller may receive the image data from the image sensor, determine a position and/or an orientation of the object token based on the tracker, and determine movement of the object token from a first position to a second position based on the image data and the tracker. The controller may also generate first image content based on the sensor signal indicating that the movement is intentional and generate second image content based on the sensor signal indicating that the movement is unintentional. The amusement park attraction design system may also include a projector communicatively coupled to the controller and to output the first image content or the second image content.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a block diagram of a tangible/virtual design system including a display surface, in accordance with an embodiment of the present disclosure;

FIG. 2 is a perspective diagram of an example embodiment of the tangible/virtual design system of FIG. 1 for detecting object tokens on a display surface;

FIG. 3 is a perspective diagram of another example embodiment of the tangible/virtual design system of FIG. 1 for designing an amusement park attraction;

FIG. 4 is a flowchart of a process for generating object visualizations using the tangible/virtual design system of FIG. 1, in accordance with an embodiment of the present disclosure;

FIG. 5 is a perspective diagram of another example embodiment of the tangible/virtual design system of FIG. 1 for detecting object tokens on a display surface;

FIG. 6 is a block diagram of an example embodiment of an object token of the tangible/virtual design system of FIG. 1;

FIG. 7A is a perspective diagram of an example embodiment of a first object token of the tangible/virtual design system of FIG. 1 in the form of an interlocking brick;

FIG. 7B is a perspective diagram of an example embodiment of a second object token of the tangible/virtual design system of FIG. 1 in the form of train model;

FIG. 8 is a flowchart of a process for generating object visualizations using the tangible/virtual design system of FIG. 1, in accordance with an embodiment of the present disclosure;

FIG. 9 is a perspective diagram of the tangible/virtual design system of FIG. 1 tracking movement of a user, in accordance with an embodiment of the present disclosure;

FIG. 10 is a flowchart of a process for determining if movement of an object token is intentional within the tangible/virtual design system of FIG. 1, in accordance with an embodiment of the present disclosure;

FIG. 11 is a flowchart of a process for adjusting object token attributes using the tangible/virtual design system of FIG. 1, in accordance with an embodiment of the present disclosure;

FIG. 12 is a flowchart of a process for designing an amusement park illusion using the tangible/virtual design system of FIG. 1, in accordance with an embodiment of the present disclosure;

FIG. 13 is a flowchart of a process for adjusting position of object tokens using the tangible/virtual design system of FIG. 1, in accordance with an embodiment of the present disclosure;

FIG. 14 is a flowchart of a process for troubleshooting amusement park attraction designs using the tangible/virtual design system of FIG. 1, in accordance with an embodiment of the present disclosure;

FIG. 15A is a schematic diagram of an example embodiment of a visualization tool of the tangible/virtual design system of FIG. 1 in the form of a paintbrush tool;

FIG. 15B is a schematic diagram of an example embodiment of a first visualization tool of the tangible/virtual design system of FIG. 1 in the form of a magnifying tool;

FIG. 15C is a schematic diagram of an example embodiment of a second visualization tool of the tangible/virtual design system of FIG. 1 in the form of a scissor tool;

FIG. 15D is a schematic diagram of an example embodiment of a third visualization tool of the tangible/virtual design system of FIG. 1 in the form of a ruler tool;

FIG. 15E is a block diagram of an example embodiment of a fourth visualization tool of the tangible/virtual design system of FIG. 1, in accordance with an embodiment of the present disclosure;

FIG. 16 is a perspective diagram of an example embodiment of the visualization tool of tangible/virtual design system of FIG. 1 in the form of one or more filter tiles, in accordance with an embodiment of the present disclosure;

FIG. 17A is a perspective diagram of an example embodiment of the object visualization as a projection map generated by the tangible/virtual design system of FIG. 1 based on the visualization tool of FIG. 16;

FIG. 17B is a perspective diagram of an example embodiment of the object visualization as a projection map generated by the tangible/virtual design system of FIG. 1 based on the visualization tool of FIG. 16;

FIG. 17C is a perspective diagram of an example embodiment of the object visualization as a projection map generated by the tangible/virtual design system of FIG. 1 based on the visualization tool of FIG. 16;

FIG. 18 is a perspective diagram of another example embodiment of the tangible/virtual design system of FIG. 1 for designing an amusement park attraction;

FIG. 19 is a flowchart of a process for generating object visualizations within the tangible/virtual design system of FIG. 18, in accordance with an embodiment of the present disclosure;

FIG. 20 is a flowchart of a process for adjusting a position and/or an orientation of the object visualization within the tangible/virtual design system of FIG. 18, in accordance with an embodiment of the present disclosure;

FIG. 21 is a perspective diagram of another example embodiment of the tangible/virtual design system of FIG. 1 for designing and generating object tokens;

FIG. 22 is a flowchart of a process for generating an object token using the tangible/virtual design system of FIG. 21, in accordance with an embodiment of the present disclosure; and

FIG. 23 is a flowchart of a process for generating an object visualization based on the object tokens of FIG. 22 and via the tangible/virtual design system of FIG. 21, in accordance with an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment”

or “an embodiment” of the present disclosure are not intended to be interpreted as excluding the existence of additional embodiments that also incorporate the recited features.

Theme parks and other such entertainment venues are becoming increasingly popular. Further, immersive experiences within such entertainment venues are in high demand. In order to provide new and exciting experiences, attractions, such as ride experiences and scenes (e.g., visual shows including live action, animated figures, computer-generated imagery, and so on) have become increasingly complex, involving integration of lighting, sound, movement, interactive elements, visual media, and so on. Conventional attraction design software may provide low cost updates and changes to attractions, but may require specialized knowledge and training to utilize the design software. Alternatively, small-scale design models may not accurately represent all aspects of complex attractions and, as such, may not provide efficient troubleshooting.

Instead, the tangible/virtual design system of the present disclosure may display media content via projection mapping to more accurately visually represent textures, colors, and surfaces of an attraction and may also allow for modifications and updates to troubleshoot different designs. Additionally, the tangible/virtual design system of the present disclosure may utilize objects that correspond to virtual models (e.g., ride vehicle, building, structure, animated figure, guest, path, and so forth). As such, the tangible/virtual design system of the present disclosure may display the virtual models on display surfaces, electronic displays, and so forth. The objects may be fitted with trackers that enable tracking cameras to discern movements, positions, and orientations of the corresponding virtual models. Further, the tangible/virtual design system may include markers and/or tools that interact with the objects to modify or update textures, colors, surfaces, and other features of the corresponding model. As such, the tangible/virtual system provides an interactive experience for attraction design that includes customizable features and combines tangible and virtual elements, but without the challenges and/or costs associated with conventional techniques.

In view of the foregoing, the present disclosure relates generally to combination tangible/virtual design systems for an amusement park attraction and/or experience. Notably, the tangible/virtual design system includes any number of object

tokens, such as small-scale models (e.g., ride vehicle, building, structure, scenery, animated figure, guest, path, and so forth) or other tangible objects, which may represent a corresponding virtual model. For example, the object token may include a machine-readable indicia (e.g., barcode, Quick Response (QR) code, a pattern of dots, identification numbers, radio frequency (RF) tag, and so forth) that may enable cameras or other scanning devices to detect object tokens and capture image data including a QR code. The tangible/virtual design system may identify corresponding virtual models based on the QR code. The tangible/virtual design system may then generate a model visualization based on the virtual model and may display the visualization via a projector, an electronic display, and so forth. For example, the object token may correspond to a virtual model of a building and the tangible/virtual design system may project an image of the building on a display surface as the virtualization of the object token.

In certain embodiments, the object tokens may include trackers, such as retroreflective markers, the machine-readable indicia, and so forth, that enable cameras to discern movements, positions, and orientations of the object tokens and/or projection surfaces in real-time via optical performance capture or optical motion capture. Thus, the tangible/virtual design system may dynamically generate and display projected images onto the object tokens and/or the display surface that emulate corresponding structures, figures, characters, movement, and/or reaction to other effects (e.g., environmental effects, visual effects, pyrotechnic effects, fluid flow effects) associated with the amusement park attraction or experience. In some embodiments, the object tokens may take the shape of the corresponding virtual model. Additionally or alternatively, the object tokens may include a label identifying the corresponding virtual model. Accordingly, the tangible/virtual design system may allow for efficient design and troubleshooting for amusement park attractions or experiences by detecting object tokens and projecting images in corresponding positions and/or orientations to accurately represent the amusement park attractions or experiences.

Additionally, imagery may be projected onto the display surface and/or the object token to create an illusion of structure, texture, material, color, or the like. For example, to enhance the authenticity and visual representation of an amusement park attraction or experience, any number of projection surfaces may display textures (e.g.,

smooth, rough, bumpy, pointy, wavy, and the like) and/or materials (e.g., brick, stone, wood, metal, glass, and so forth) for a virtual model of an object. In certain embodiments, the tangible/virtual design system includes any number of visualization tools that may represent corresponding attributes (e.g., structure, texture, material, color, length, width, point of view, angle, or the like). The visualization tools include a machine-readable indicia that may enable cameras or other scanning devices to detect visualization tools and capture image data. The tangible/virtual design system may identify corresponding attributes based on the captured image data and may generate and/or update projected images based on the identified attributes. For example, the tangible/virtual design system may detect and identify a visualization tool that corresponds to a brick material. As such, the tangible/virtual design system may operate and control projectors to project imagery corresponding to the brick material on the display surface, the object token, and/or a designated area corresponding to an object token as the virtualization of the object token.

Additionally or alternatively, the tangible/virtual design system may detect an interaction between object tokens and visualization tools. For example, cameras may determine a proximity between a visualization tool and an object token and/or may determine a nearest object token to a visualization tool. For example, the tangible/virtual design system may detect and identify a visualization tool that corresponds to a paintbrush that adds a brick material to an object visualization, such as a building or a portion of an amusement park ride. As such, the tangible/virtual design system may operate and control projectors to adjust one or more object attributes of the object visualization, such as changing a material of the house or a portion of the amusement park ride to a brick material. That is, the visualization of the object token may be generated and/or updated based on the nearby visualization tool. In certain instances, the projectors may project imagery based on the visualization tool onto the display surface and/or the object tokens.

By way of example, visualization tools may interact with object tokens to alter, update, or determine one or more attributes of the virtual models corresponding to the object tokens. For example, a paintbrush tool may alter a color of the virtual model or apply a color to the virtual model based interactions between the visualization tool and the object token. The tangible/virtual design system may detect interactions

between a paintbrush tool and the object token, and may control projectors to update the visualizations of the object tokens (e.g., model virtualization). For example, the paintbrush tool may correspond to color and interactions between the paintbrush tool and the object token may cause the tangible/virtual design system to operate and control projects to project imagery corresponding to the color on the display surface, the object token, and/or the designated area corresponding to the object token. In another example, a magnifying tool may enable visualization at different points-of-view (e.g., bird’s eye view, close-up or zoomed-in view, zoomed-out view, perspective view) of the virtual model by interactions with the object token. The tangible/virtual design system may detect interactions between the magnifying tool and the object token and may control projectors to update the visualizations of the object token. Additionally or alternatively, the tangible/virtual design system may determine a physical property (e.g., length, width, surface area, angle, shape, mass, density, specific heat, odor, color) of the virtual model that corresponds to the object token based on interactions between the visualization tool the object token. For example, a measurement tool may enable measurement of the virtual model, such as a height, a length, a width, a surface area, and the like. Additionally or alternatively, the measurement tool may measure brightness (e.g., light, luminance), sound volume, temperature, and the like of the virtual model and/or within a designated area corresponding to the object token tangible/virtual design system.

Still in another example, one or more filter tools may enable display of attributes associated with the virtual model corresponding to the object token. The attributes may include cost, brightness, sound volume, viewing time, user input, and the like. For example, a cost filter tile may cause the tangible/virtual design system to control projectors to project imagery corresponding to a cost associated with each portion of the virtual model. Additionally, multiple filter tools may be combined or stacked to provide visualization indicative of multiple attributes of the virtual model. For example, a first filter tool may correspond to a cost of building the virtual model and a second filter tool may correspond to an amount of time a guest may view the virtual model (e.g., when passing the object while traveling in a vehicle). By combining the filters (e.g., stacking the first filter tool on top of the second filter tool), the tangible/virtual design system may determine an amount of time each portion of the virtual model may be viewed by a guest (e.g., while on a ride, while walking within the

attraction system) divided by a cost associated with each corresponding portion of the virtual model. When combining the filter tools in the opposite manner (e.g., second filter tool on top of the first filter tool), the tangible/virtual design system may determine the cost divided by the amount of time each portion of the virtual model may be viewed by the guest. As such, the visualization tools may alter, change, or measure one or more attributes of the virtual model for efficient design and troubleshooting of amusement park attractions or experiences.

In an embodiment, the tangible/virtual design system includes effect tiles that correspond to environmental effects, visual effects, pyrotechnic effects, fluid flow effects, and the like. The effect tiles may include machine-readable indicia that enables the tangible/virtual design system to determine corresponding effects and/or markers that enable cameras to determine a position and/or an orientation of the effect tiles. For example, a clock tile may correspond to a time of day and may adjust lighting effects based on a determined position of the sun. The tangible/virtual design system may determine a time of day based on an orientation and/or a position of the clock tile. The projectors may project imagery corresponding to a virtual light source based on the time of day and a determined position and angle of the sun. As another example, a weather tile may correspond to a selected weather and may adjust lighting effects, environmental effects, and so forth for any number of objects. Environmental effects may include a wind speed, precipitation, cloud cover, humidity, fog, and the like. The environmental effects may alter the visualization of one or more objects. For example, projectors project imagery of branches and leaves moving in the wind for scenery objects. In this way, the effect tiles may alter visualization of one or more objects.

In certain instances, the effect tiles may include a timeline tool to advance, reverse, stop, or pause time within the system. For example, the timeline tool may include a physical device coupled to the display surface and the physical device may be pushed, pulled, or otherwise adjusted with respect to the display surface. The display surface may also be coupled to a sensor, which may receive an indication of movement of the physical device. In certain instances, the tangible/virtual design system may receive indication of the movement and adjust a simulated time of day within the tangible/virtual design system. For example, the tangible/virtual design system may advance the simulated time of day from morning to afternoon based on the indication

of the movement. In other instances, the tangible/virtual design system may receive indication of the movement and adjust a real, project time. For example, the tangible/virtual design system may receive user input indicative of starting a project or continuing a project and control a camera to capture and store imagery of the display surface with the object tokens, the projected imagery, or both over a period of time. In response to receiving the indication of the movement, the tangible/virtual design system may playback the captured imagery. In other words, the real time of the project may be reversed. Additionally or alternatively, the tangible/virtual design system may pause or stop the playback in response to receiving the indication of the movement.

In certain embodiments, the tangible/virtual design system includes a camera object that enables visualization of a point-of-view based on a position and/or orientation of the camera object. The tangible/virtual design system may generate the point-of-view visualization for display on an electronic display and/or the display surface. Additionally or alternatively, the tangible/virtual design system may detect interactions between the camera object and other object tokens, such as a ride vehicle. For example, interactions between the camera object and another object token may indicate a selection of the other object token, such as a ride vehicle, for generation of a point-of-view visualization. As such, the tangible/virtual design system generates a visualization for a rider’s point-of-view as a ride vehicle travels along a track. Additionally, any number of the object tokens may include actuators, such as an electric motor, to move the object token along or across the display surface.

The tangible/virtual design system facilitates design of various attractions or experiences, such as illusions generated on lighting effects. One such illusion is conventionally referred to as Pepper’s Ghost. The Pepper’s Ghost illusion utilizes reflective properties of translucent or transparent materials (e.g., glass, plastic, or the like) to virtually project images into a scene for viewing by guests. For example, an angled pane of glass may be positioned in front of a stage and imagery may be projected toward the glass from outside of a line of sight of the audience and then partially reflected toward the audience by the pane of glass. Thus, the audience perceives the reflected imagery in conjunction with viewing the scene presented behind the glass and in the line of sight of the audience. Depending on lighting, this effect can give the reflected imagery a ghostly appearance because light behind the glass remains

observable through the reflected imagery. Accordingly, the tangible/virtual design system may determine positions and/or orientations of object tokens that correspond to the reflective material and the projected imagery. As such, the tangible/virtual design system determines a position and/or an orientation of the reflected imagery and generates a visualization of the reflected imagery. Additionally or alternatively, the tangible/virtual design system may include an object token that corresponds to the reflected imagery. The tangible/virtual design system may determine positions and/or orientations of two of the projected imagery, the reflected imagery, and the reflective material and may identify a position and/or an orientation of the remaining object token to complete the visual effect. In some embodiments, the object tokens may include actuators and the tangible/virtual design system may transmit signals to control the actuators and move the object tokens to the identified position and/or orientation.

In certain embodiments, the tangible/virtual design system may include constraints associated with an amusement park attraction or experience. For example, constraints may include a speed constraint (e.g., a threshold speed constraint, a maximum speed constraint, a minimum speed constraint, and so on), a turn constraint, a space constraint, and the like. In another example, constraints may include a brightness constraint (e.g., a minimum brightness constraint, a maximum brightness constraint), a sound volume constraint (e.g., a minimum sound volume constraint, a maximum sound volume constraint), a temperature constraint, and the like. The tangible/virtual design system may compare the determined positions and/or orientations of the object tokens with any number of the constraints and identify any conflicts or errors with the design based on the comparison. The tangible/virtual design system may also capture image data and record configurations of different object tokens, tools, and so forth. Accordingly, the projectors may project imagery based on the recorded configurations to allow quick setup of an amusement park attraction or experience.

In certain embodiments, the object tokens, tools, and so forth may be disposed and detected on the same display surface as the projected image is displayed. Alternatively, a second staging surface may be utilized for object detection and position and/or orientation determination, and the display surface may be utilized to display the projected image. As such, cameras or other image capture devices capture image data

of objects on the staging surface and projectors project imagery based on the image data on to the display surface.

In certain instances, the cameras and/or other image capture devices may identify or confuse unintentional and/or false movements (e.g., small, micro-movements, unintentional movements) of the objects tokens or noise (e.g., generated by the tangible/virtual design system, such as an image sensor, a camera, or the like within the tangible/virtual design system) as intentional movements of the object token (e.g., those caused by a user) and update a corresponding virtualization (e.g., object visualization) of the object token. For example, noise within the tangible/virtual design system, such as by that caused by the cameras and/or image sensors or when transmitting image data within the system, may cause false movements to be identified by the tangible/virtual design system. In another example, vibration within the tangible/virtual design system, such vibration of a table interfacing with the object tokens, may cause unintentional movements of the object tokens to be identifiable by the tangible/virtual design system. That is, the tangible/virtual design system may identify movement (e.g., the micro-movements) of the object token when the object token is not being intentionally moved. When these unintentional and/or false movements are identified, the tangible/virtual design system may update a corresponding virtualization of the object token, such as position and/or an orientation of the virtualization. These unintentional and/or false movements of the object token may be amplified by the tangible/virtual design system when updating the corresponding virtualization of the object token. For example, the small rotation in the camera or spotlight token may result in the pool of light created by the spotlight to move by large amounts. As such, the tangible/virtual design system may update the virtualization of the object token when the user did not intentionally move the object token. Additionally or alternatively, anti-aliasing of a computer renderer may cause flickers or other display artifacts due to movements of the object tokens, which may, in certain instances, be due to unintentional movements and/or false movements resulting from noise caused by the image sensors and/or cameras. The flickers may appear natural when movement of the object token is large, such as due to intentional movements of a user, but the flickers may be extraneous when the object tokens is not being moved by the user.

The virtualizations of the object tokens may be recorded and saved to a database for reference. Since the tangible/virtual design system may update virtualizations of the object tokens based on false movements and/or unintentional movements, in some cases, a user may review the recordings and manually undo the updates to the virtualizations caused by the false or unintentional movements. For example, the user may undo the updates frame-by-frame in order to correct the recording, which may be time-consuming and tedious. As such, systems and methods for automatically (e.g., without user or manual intervention) identifying movement of the object tokens and determining if the movement is intentional may be desired.

Embodiments of the present disclosure include a tangible/virtual design system that receives an indication of movement of one or more object tokens and determines if the movement is an intentional movement or not an intentional movement (e.g., unintentional movement, false movement). The tangible/virtual design system may update the virtualization of the object token, such as the position and/or orientation of the virtualization, when the movement of the object token is determined to be intentional, thereby reducing or eliminating the need to review recordings and undo updates to virtualizations of the object token. That is, the tangible/virtual design system may only update the position and/or orientation of the virtualization of the object token when a user intended for the object token to be moved. To this end, the object token may include one or more sensors on a surface and/or integrated (e.g., at least partially integrated) within the object token. The sensor may identify intentional movement of the object token, such as by a user. For example, the sensor may be a button that may be pressed by the user to indicate an intention to move the object token, or a proximity sensor on a surface of the object token interfacing with the display surface that indicates that the user is nearby and thus intentionally means to move the object token. The sensor may transmit an indication of the intentional movement when the object token is moved around or lifted off the display surface by the user. The tangible/virtual design system may receive the indication and determine that movement of the object token by the user is intentional. If the sensor does not provide an indication of intentional movement but movement of the object token is detected, the tangible/virtual design system may determine the movement of the object token is not intentional and may not update the virtualization of the object token. For example, the user may accidently bump into an object token, thereby causing movement of the object token but may not

press down on the button to indicate the intention to move the object token. The automation controller may not update a position and/or orientation of the corresponding virtualization. That is, the automation controller may instruct the projectors to continue projecting image data generated based on a position and/or an orientation of the object token prior to the user bumping into the object token. As such, the tangible/virtual design system may update the virtualization of the object token, such as a position and/or an orientation of the virtualization, when the movement is intentional, thereby reducing or eliminating manual correction (e.g., undoing actions) within a recording of the virtualizations.

In this manner, the techniques described in the present disclosure may facilitate coordinating combined tangible and virtual representations of amusement park attractions or experiences based on identified objects that correspond to virtual models. Additionally or alternatively, the techniques described in the present disclosure may identify movement of an object token, determine if the movement is an intentional movement, and update the virtualization of the object token based on the determination. As such, the techniques of the present disclosure may facilitate design and troubleshooting of an amusement park, amusement park attractions, and/or amusement park experiences.

In certain embodiments, the tangible/virtual design system may generate an object visualization without a corresponding object token positioned on the display surface. For example, the tangible/virtual design system may identify an object token positioned on the display surface and generate display image content with an object visualization that corresponds to the object token based on an indication to generate the object visualization. The tangible/virtual design system may generate a “digital twin” of the object visualization based on identifying movement of the user that corresponds to instructions to generate the digital twin. The digital twin may be a digital copy (e.g., replicate) of the object visualization. As such, the digital twin may not correspond to a physical object token within the tangible/virtual design system. For example, the movement of the user may include the user pointing at the object token and subsequently pointing at another location of the display surface, the user pointing at the displayed object visualization and subsequently pointing at another location within the tangible/virtual design system, and so on. For example, the tangible/virtual design

system may generate updated image content with the object visualization and a second object visualization that may be a digital twin of the object visualization. The tangible/virtual design system may position the digital twin at the location of the display surface pointed at by (e.g., selected by) the user. As such, the tangible/virtual design system may generate object visualizations that may not include a corresponding object token.

The tangible/virtual design system may identify movement of the user corresponding to instructions to adjust a position and/or an orientation of the object visualization. For example, subsequent to generating the digital twin, the tangible/virtual design system may identify the user pointing at a location of the display surface corresponding to the digital twin and subsequently rotating a palm, moving the palm in a horizonal direction, moving the palm in a vertical direction, making a pinching motion with two fingers, and so on. The tangible/virtual design system may determine the movement of the user corresponds to instructions to adjust a position and/or orientation of the digital twin. For example, the tangible/virtual design system may adjust an orientation of the object visualization based on a yaw, a pitch, and/or a roll of the user’s palm rotation. In another example, the tangible/virtual design system may adjust a position of the object visualization based on identifying the palm moving in the horizontal direction or the vertical direction, and so on. Still in another example, the tangible/virtual design system may adjust a view of the object visualization of the object visualization, based on identifying the pinching motion. For example, the tangible/virtual design system may zoom in on the object visualization, zoom out on the object visualization, provide a cross-sectional view of the object visualization, provide an exploded view of the object visualization, and so on based on movement of the user. As such, the tangible/virtual design system may adjust the object visualization based on movement of the user.

In other embodiments, the tangible/virtual design system may adjust one or more object attributes of the object visualization based on input from a controller held by the user. For example, the tangible/virtual design system may adjust the position and/or the orientation of the object visualization based on input, e.g., from the controller. In another example, the tangible/virtual design system may adjust attributes of the object visualization based on input, e.g., from the controller. The object attributes

may include a color of the object visualization, visual details of the object visualization, and so on. In certain instances, the tangible/virtual design system may generate the object visualization based on a corresponding object token positioned on the display surface. Prior to adjustment of the object attributes, the object token may appear to visually resemble the object visualization. However, after the object attributes of the object visualization are adjusted, the object token may not visually resemble the object visualization. The tangible/virtual design system may generate an additional object token that visually resembles the adjusted object visualization. For example, a printer (e.g., three-dimensional (3D) printer) may generate the additional object token based on image data (e.g., the object visualization with the adjusted attributes) from the tangible/virtual design system. The additional object token may be the same or similar color and/or include the same or similar object attributes as the object visualization. As such, the additional object token may visually resemble the object visualization. In other examples, the tangible/virtual design system may generate an additional object token that corresponds to the digital twin. As such, the digital twin may correspond to a physical object token within the tangible/virtual design system.

In certain instances, the printer may generate the additional object token with a color and/or one or more attributes(s) that may not match the object visualization. For example, the object visualization may include a green dragon, but the printer may generate the additional object token using white filament. The tangible/virtual design system may use projection mapping to overlay (e.g., adjust) a color and/or one or more attribute(s) onto an exterior surface of the additional object token such that the additional object token visually resembles the object visualization. For example, the tangible/virtual design system may projection map the color green onto the additional object token made of the white filament to make it appear green and more closely resemble (e.g., match) the object visualization. As such, the additional object token may visually resemble the object visualization.

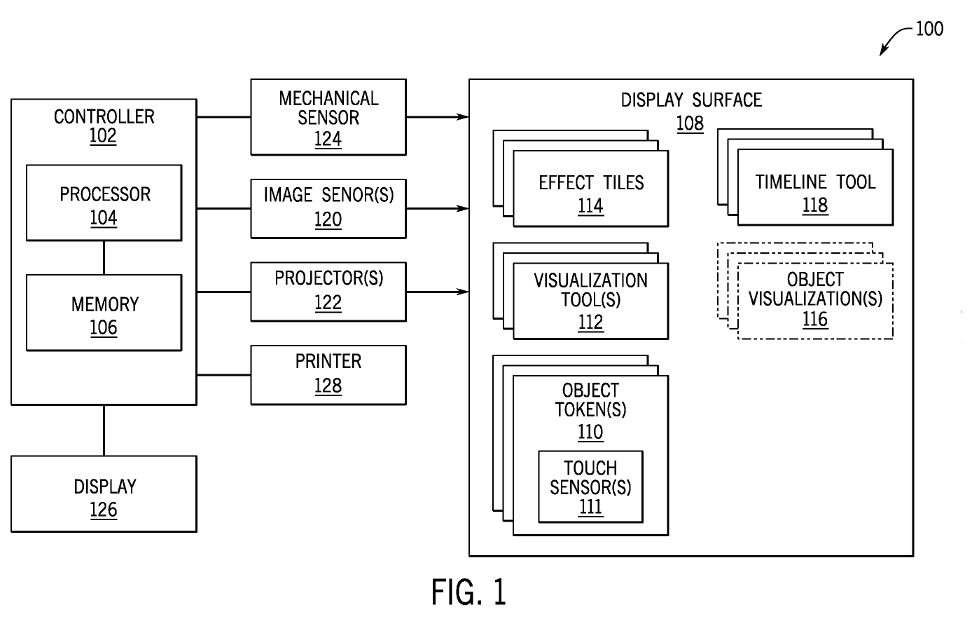

With the foregoing in mind, FIG. 1 illustrates an example of a tangible/virtual design system 100 including a controller (e.g., automation controller 102), a display surface 108, and a secondary display 126. The tangible/virtual design system 100 may be used to design and troubleshoot various elements of an amusement park attraction and/or experience. The tangible/virtual design system 100 may include

a control system having multiple controllers, such as an automation controller 102, each having at least one processor 104 and at least one memory 106. The automation controller 102 may control operation of any number of image sensors 120 and/or any number of projectors 122, and may process data received from the image sensors 120. The automation controller 102 may be communicatively coupled to the image sensors 120 and the projectors 122 by any suitable techniques for communicating data and control signals (e.g., an indication of image content) between the automation controller 102, the image sensors 120, and the projectors 122, such as a wireless, optical, coaxial, or other suitable connection. In some embodiments, the automation controller 102, the image sensors 120, the projectors 122, or any combination thereof, may include respective communications circuitry, such as antennas, radio transceiver circuits, radio transmitters, radio receivers, and signal processing hardware and/or software (e.g., hardware or software filters, analog-to-digital or digital-to-analog converters, multiplexers, amplifiers), or any combination thereof, and that may be configured to communicate over wired or wireless communication paths via radio frequency communication, infrared communication, Ethernet, satellite communication, broadcast radio, microwave radio, Bluetooth, Zigbee, Wi-Fi, ultrawideband communication, near field communication, and so forth.

The tangible/virtual design system 100 may also include a display surface 108 capable of displaying image content. The display surface 108 may correspond to a setting for an amusement park attraction or experience. For example, the display surface 108 may be used to design an amusement park attraction or experience using various object tokens 110, visualization tools 112, and effect tiles 114 disposed (e.g., placed) on the display surface 108 or a staging surface. Additionally or alternatively, the display surface 108 may include a first portion for placing the various objects and tools and a second portion for receiving projected image content (e.g., object visualizations 116) from the projectors 122. In certain embodiments, the display surface 108 may include any number of projection surfaces and each projection surface may depict image content associated with a setting for an amusement park attraction and/or experience. For example, an amusement park ride may appear to take place in an active volcano and the display surface 108 may depict image content associated with the active volcano (e.g., flowing lava, fire, and so forth). The image content may include ride vehicles, ride tracks, guests, pathways, buildings, scenery, structures,

natural features, and any other suitable components of an amusement park attraction or experience. In certain embodiments, the display surface 108 may include machine-readable indicia (e.g., a bar code, a QR code, and the like) and/or may include trackers (e.g., trackable markers) that are positioned on the display surface 108. The machine-readable indicia and/or the trackers may be positioned on or within any suitable portion of the display surface 108 that enables the machine-readable indicia and/or the trackers to be concealed or obscured from viewing and/or interfering with projected imagery.

The trackers may be shaped as rounded cylinders or light emitting diodes, though it should be understood that the trackers may have any suitable shape, including spherical shapes, rectangular prism shapes, and so forth. The trackers enable the image sensors 120 to sense or resolve a position and/or an orientation of the display surface 108, such as via optical performance capture or optical motion capture techniques. Optical performance capture or optical motion capture refers to a technique of recording an object by capturing data from image sensors, such as image sensors 120, and trackers coupled to a surface. In some embodiments, the trackers may be active devices, which may emit an individualized signal to the image sensors 120. For example, the trackers may emit infrared light, electromagnetic energy, or any other suitable signal that is undetectable by individuals while being distinguishable by the image sensors 120. Alternatively, the trackers may be passive devices (e.g., reflectors, pigmented portions) that do not emit a signal and that enable the image sensors 120 to precisely distinguish the passive devices from other portions of the display surface 108. In certain embodiments, the trackers may be flush with or recessed within an outer surface of the display surface 108. A type and/or a configuration of the image sensors 120 may be individually selected to correspond to a type of the trackers. The image sensors 120 may be designed to receive signals from trackers (e.g., active devices) to sense the position and/or orientation of the display surface 108. Additionally or alternatively, the image sensors 120 may be designed to discern the trackers (e.g., passive devices) on the display surface 108.

The machine-readable indicia and/or the trackers may correspond to a setting for an amusement park attraction or experience, such as a particular scenery (e.g., forest, volcano, mountain, desert, and the like), a particular topography (e.g., elevations, bodies of water, and so forth), a particular section of an amusement park

(e.g., a themed section, a path through the amusement park), a particular portion of an amusement park attraction or experience (e.g., a queue, a loading area, an unloading area, an effect area, and the like), or any other suitable location that may be depicted by projected image content onto the display surface 108. The image sensors 120 may generate and transmit image data that includes an image of the machine-readable indicia and/or the trackers. The processor 104 may receive the image data via the image sensors 120 by scanning a barcode, a QR code, or any other suitable machine-readable indicia. The machine-readable indicia may act as an identifier for scenery, topography, and so forth for an amusement park attraction or experience. For example, the processor 104 may process the image data to detect the machine-readable indicia and identify corresponding image content to project onto the display surface 108. The processor 104 may receive and/or retrieve the corresponding image content from the memory 106 based on the detected machine-readable indicia and may control operation of the projectors 122 to project the image content onto the display surface 108.

The tangible/virtual design system 100 may also include any number of object tokens 110 that may be disposed (e.g., placed) on the display surface 108 or any other suitable surface. The object tokens 110 may include machine-readable indicia and/or trackers that are positioned on one or more surfaces of the object tokens 110. In certain embodiments, the machine-readable indicia and/or the trackers may be positioned on or within any suitable portion of the object tokens 110 that enables the machine-readable indicia and/or the trackers to be concealed or obscured from viewing and/or interfering with projected imagery. The object tokens 110 may be captured in image data by the image sensors 120 and the automation controller 102 may detect the object tokens 110 based on the image data. The automation controller 102 may also identify the visualization tool 112 based on the image data. For example, the image sensors 120 may detect a position, an orientation, and/or a configuration of trackers on an exposed surface of the object tokens 110 and/or may detect machine-readable indicia on the exposed surface of the object tokens 110. The image sensors 120 may generate tracker data (e.g., location data, orientation data, configuration data) and/or scanning data based on the detected trackers and/or machine-readable indicia. As used herein, location data may include a current position, a current orientation, a current configuration of one or more trackers, and the like. The automation controller 102 may receive the tracker data and/or the scanning data and may identify corresponding image

content based on the tracker data and/or the scanning data. In certain embodiments, the object tokens 110 may correspond to various components of an amusement park attraction or experience, such as a building, a ride vehicle, portions of a ride track, guests, a pathway for guests, natural features, barriers, and the like. For example, an object token 110 disposed on the display surface 108 may correspond to a ride vehicle. The automation controller 102 may identify the corresponding ride vehicle based on the tracker data and/or the scanning data. Additionally, an object token 110 may correspond to a camera or guest. In certain instances, an amusement park attraction designer may utilize a camera object token to visualize a point-of-view or perspective of a guest viewing an attraction or experience. For example, the image sensor 120 may detect the camera object token and may generate position data and/or orientation data based on the detection. The automation controller 102 may determine a point-of-view or perspective of the camera object taken based on the position data and/or orientation data and may instruct the projectors 122 based on the point-of-view. For example, the automation controller 102 may determine the perspective of the camera object token is pointed towards another object token on the display surface 108 based on the orientation data. As such, the automation controller 102 may instruct the projector 122 to project image content including a visual representation of the view from the camera object token. As such, the tangible/virtual design system 100 may provide a visual representation of guest’s perspective when viewing amusement park attractions or experiences.

The automation controller 102 may determine a configuration of the trackers on the object token 110 and may compare the configuration with stored tracker configurations in the memory 106. The automation controller 102 may determine a correlation between the configuration on the object token 110 and one or more stored tracker configurations. As such, the automation controller 102 may identify and/or retrieve image content corresponding to the object token and may control operation of the projectors 122 to display the image content. For example, the automation controller 102 may control operation of the projectors 122 to generate one or more object visualizations 116 on the display surface 108. The object visualizations 116 may be image content that represents the identified object tokens 110. For example, the projectors 122 may project the object visualizations 116 on the display surface 108. The automation controller 102 may instruct the projectors 122 to adjust the object

visualizations 116 based on image data from the image sensors 120. For example, the image data may include an updated position of the object tokens 110, an updated orientation of the object tokens 110, additional object tokens 110, a removed object tokens 110, updated attributes (e.g., color, texture, material, and so forth) for object tokens 110, and the like. In certain embodiments, the object visualization 116 may include a projection mapping of image content onto the object token 110. Additionally or alternatively, the object visualizations 116 may correspond to a virtual model displayed on the display 126. As such, the automation controller 102 may control the display 126 to generate and/or update a visual model on the display 126.

The object tokens 110 may also include one or more sensor(s) 111 that may transmit a signal indicative of movement. The sensors 111 may be coupled to one or more surfaces of the object token 110 and/or integrated within the object token 110. For example, the object token 110 may include a first sensor coupled to the outer surface of the object token, a second sensor integrated in a bottom surface of the object token, and/or a third sensor within the object token 110. The sensors 111 may include a touch sensor (e.g., a capacitive touch sensor), an electronic switch, a button, a proximity sensor, a camera, an optical mouse sensor, a motion sensor (e.g., a gyroscope, an accelerometer), a light detection and ranging (LiDAR) sensor, or any other sensor or device that may indicate intentional movement of the object token 110.

For example, a capacitive touch sensor coupled to a surface of the object token 110 may transmit an indication of the object token 110 being touched and/or picked up by a user. In another example, a user may close or activate the electronic switch coupled to a surface of the object token prior to moving the object token 110. The automation controller 102 may determine the movement is intentional if the electronic switch is closed or activated. Still in another example, the button and/or the proximity sensor may be integrated with a surface (e.g., bottom surface) of the object token 110 that interfaces with the display surface 108 and the button and/or proximity sensor may transmit a signal indicative of movement if the object token 110 is lifted from the display surface 108. For example, the proximity sensor may detect the presence of a user, such as the user’s hand, and output a signal indicative of the presence. If the user picks up the object token 110, the proximity sensor may transmit an indication of the user’s hand touching the object token 110. In another example, the

button may detect a change in a position and/or orientation, which may be indicative of intentional movement of the object token 110. When the object token 110 rests on the display surface 108, the button may be depressed into and/or aligned with the surface of the object token 110 by the display surface 108. The button may be opened or raised with respect to the surface of the object token 110 when the object token 110 is lifted from the display surface 108 or when the button may not be interfacing with the display surface 108. As such, the button and/or proximity sensor may transmit an indication of movement when the object token 110 is not interfacing with the display surface 108.

Additionally or alternatively, the button may be integrated with a surface that may not interface with the display surface 108. The button may extend from the surface or protrude from the surface of the object token 110 and the user may depress the button prior to moving the object token 110. As such, the sensor 111 may generate a signal (e.g., sensor signal, sensor data) indicative of movement of the object token 110. The automation controller 102 may receive the indication of movement from the sensor 111 and determine the movement of the object token 110 to be intentional. If the movement of the object token 110 is intentional, then the automation controller 102 may update a corresponding object visualization 116, such as updating a position and/or an orientation of the object visualization 116 based on a change in the position and/or orientation of the object token 110. If the movement of the object token 110 is not intentional, then the automation controller 102 may not update the corresponding object visualization 116.

In certain instances, the automation controller 102 may identify movement of the object token 110 within the image data from the image sensors 120 and may not receive an indication of movement from the sensor 111. The automation controller 102 may determine that the detected movement within the image data is an unintentional movement and/or a false movement. As such, the automation controller 102 may not update the object visualization 116. Additionally or alternatively, the automation controller 102 may apply a computer algorithm, such as a machine learning algorithm and/or an artificial intelligence algorithm, to perform image analysis on the image data from the image sensors 120 and determine if movement of an object token 110 is intentional. As such, unintentional movements and/or false movements of the object

tokens 110 identified by the tangible/virtual design system 100 may be reduced or eliminated.

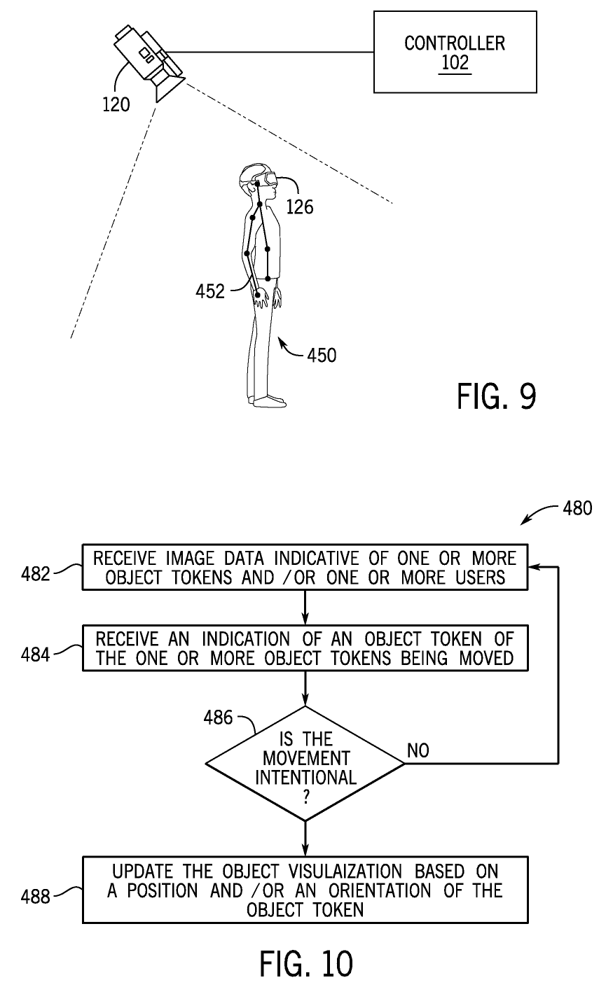

In other instances, the automation controller 102 may receive an indication of movement from a sensor 111 of the object token 110 and verify (e.g., validate) the movement based on image data from the image sensors 20. For example, the user may inadvertently move (e.g., bump into, knock over) an object token 110 causing a position and/or an orientation of the object token 110 to change, such as the surface interfacing with the display surface 108 to change. The object token 110 may include a sensor 111 (e.g., button) that may be depressed with respect to the surface of the object token 110 when interfacing with the display surface 108 and may be raised when the button may not be interfacing with the display surface 108. If the object token 110 rotates, such as due to the movement, the button may transition from depressed to raised, which may cause the button to transmit an indication of movement of the object token 110. The automation controller 102 may receive the indication and may verify the movement using image data from the image sensors 120. As further described with respect to FIG. 9, for example, the image data from the image sensors 120 may also include image data of the user and the automation controller 102 may use skeletal tracking of the user to determine if the user is intentionally moving an object token 110. For example, the automation controller 102 may identify the user reaching for another object token 110 and inadvertently moving (e.g., bumping) into the object token 110 and determine the movement of the object token 110 is unintentional movement based on the image data. As such, the automation controller 102 may not update the corresponding object visualization 116 of the object token 110.

The tangible/virtual design system 100 may include any number of visualization tools 112 that may interact with object tokens 110 disposed on the display surface 108 or any other suitable surface. The visualization tool 112 may facilitate applying an effect to an object visualization 116. For example, the visualization tool 112 may include a paintbrush and the effect may include applying and/or adjusting a color of an object visualization 116. In another example, the visualization tool 112 may include a magnifying glass and the effect may include zooming in or out on an object visualization 116. The visualization tools 112 may include machine-readable indicia and/or trackers that are positioned on one or more surfaces of the visualization tools

112. In certain embodiments, the machine-readable indicia and/or the trackers may be positioned on or within any suitable portion of the visualization tools 112 that enables the machine-readable indicia and/or the trackers to be concealed or obscured from view and/or interfering with projected imagery (e.g., object visualization 116). The machine-readable indicia and/or the trackers may be identified within image data generated by the image sensors 120 and the automation controller 102 may identify the visualization tool 112 based on the machine-readable indicia and/or the tracker. Additionally or alternatively, the visualization tool 112 may also include one or more sensors 111 on and/or integrated within the visualization tool 112. The automation controller 102 may determine if movement of the visualization tool 112 is intentional based on an indication from the sensors 111.

The visualization tools 112 may interact with the object tokens 110 to apply an effect (e.g., adjust, update) any number of object attributes, such as a color, a material, a texture, and the like. For example, a texture tool and/or a paintbrush tool may be disposed adjacent and/or in contact with an object token 110. The image sensors 120 may detect the paintbrush tool and/or the object token 110 and may generate image data based on the detections. The automation controller 102 may receive the image data and may determine the visualization tool 112 satisfies an interaction criteria (e.g., within a threshold distance from the object token 110, in contact with the object token 110) based on the image data. The automation controller 102 may apply the effect in response to determining that movement of the visualization tool 112 is intentional and/or receiving an indication of movement from the sensors 111.

The automation controller 102 may also identify the visualization tool 112 based on the image data. For example, the image sensors 120 may detect a position, an orientation, and/or a configuration of trackers on an exposed surface of the visualization tool 112 and/or may detect machine-readable indicia on the exposed surface of the visualization tool 112. The image sensors 120 may generate tracker data (e.g., location data, orientation data, configuration data) and/or scanning data based on the detected trackers and/or machine-readable indicia. The automation controller 102 may receive the tracker data and/or the scanning data and may identify corresponding image content based on the tracker data and/or the scanning data. For instance, the automation controller 102 may determine a configuration of the trackers on the visualization tool

112 and may compare the configuration with stored tracker configurations in the memory 106. The automation controller 102 may retrieve image content based on the comparison and may control the projectors 122 based on the image content. For example, the automation controller 102 may determine the visualization tool 112 corresponds to a paintbrush tool that adjusts a color attribute for the object token 110. The automation controller 102 may retrieve and/or update the color attribute for the object token 110 and may control the projectors 122 to display the object visualizations 116 based on the adjusted color attribute. As such, the automation controller 102 may generate and/or adjust image content (e.g., the object visualizations 116) displayed by the projectors 122 based on tracker data, scanning data, and/or the interaction criteria. In another example, a filter tool may correspond to an attribute of the object tokens 110, such as cost, brightness, sound volume, and the like. The tangible/virtual design system 100 may update a visualization of the object token 110 based on the filter tool. That is, the tangible/virtual design system 100 may update the object visualization 116 based on a visualization tool 112. Additionally, multiple filter tools may be positioned (e.g., stacked) to provide combined attributes of the object token 110. The tangible/virtual design system 100 may determine the combined attributes based on a position of the each of the filter effect tiles.

In certain instances, the visualization tool 112 may also include one or more sensors 111 that may transmit a signal indicative of movement. For example, one or more sensors 111 may be coupled to a surface of the visualization tool 112 and/or integrated within the visualization tool 112. The automation controller 102 may receive one or more signals from the sensors 111 to determine if movement of the visualization tool 112 may be an intentional movement (e.g., by detecting a button press, a user’s touch via a capacitive sensor, a user’s touch via an electronic switch, movement via a gyroscope and/or accelerometer). If the movement is intentional, then the automation controller 102 may implement the effect of the visualization tool 112, such as adjusting an object attribute of an object visualization 116. If the movement is not intentional, then the automation controller 102 may not implement the effect of the visualization tool 112.

The tangible/virtual design system 100 may include any number of effect tiles 114 that correspond to various visual effects that may be displayed on the display

surface 108 and/or any object tokens 110 on the display surface 108. The effect tiles 114 may include machine-readable indicia and/or trackers that are positioned on one or more surfaces of the effect tiles 114. In certain embodiments, the machine-readable indicia and/or the trackers may be positioned on or within any suitable portion of the effect tiles 114 that enables the machine-readable indicia and/or the trackers to be concealed or obscured from viewing. The effect tiles 114 may be captured in image data by the image sensors 120 and the automation controller 102 may detect the effect tiles 114 based on the image data. The effect tiles 114 may interact with the display surface 108 and/or the object tokens 110 to adjust projected image content. For example, a clock effect tile may correspond to a time of day and may adjust lighting effects based on a determined position of the sun. The tangible/virtual design system 100 may determine a time of day based on an orientation and/or a position of the clock tile. For example, the image sensors 120 may detect a position, an orientation, and/or a configuration of trackers on an exposed surface of the effect tile 114 and/or may detect machine-readable indicia on the exposed surface of the effect tile 114. Additionally or alternatively, the effect tiles 114 may include one or more sensors 111 coupled to and/or partially integrated within the effect tiles 114. The automation controller 102 may determine if movement of the effect tiles 114 is an intentional movement based on an indication from the sensor 111. The automation controller 102 may apply an effect of the effect tiles 114 if the movement of the effect tile 114 is determined to be an intentional movement.

The image sensors 120 may generate tracker data (e.g., location data, orientation data, configuration data) and/or scanning data based on the detected trackers and/or machine-readable indicia. The automation controller 102 may receive the tracker data and/or the scanning data and may identify corresponding image content based on the tracker data and/or the scanning data. For instance, the automation controller 102 may determine an orientation of the trackers on the clock tile and may compare the orientation with stored tracker orientations associated with the clock tile in the memory 106. The automation controller 102 may determine an associated time of day based on the comparison and may control the projectors 122 based on the time of day. For example, the automation controller 102 may determine the time of day is a sunset and may adjust lighting effects to depict shadows, lower brightness, movement of a virtual light source, and so forth. The automation controller 102 may control the

projectors 122 to adjust image content based on the lighting effects. As another example, a weather tile may correspond to a selected weather and may adjust lighting effects, environmental effects, and so forth for any number of objects. Environmental effects may include a wind speed, precipitation, cloud cover, humidity, fog, and the like. The environmental effects may alter the object visualizations 116. For example, the automation controller 102 may control projectors 122 to adjust image content of branches and leaves moving in the wind for scenery objects.

In an embodiment, the tangible/virtual design system 100 may include a timeline tool 118 coupled to the display surface 108 and/or a movement sensor 124. The timeline tool 118 may include a physical device, such as a rope, a pulley, a lever, a slider, a crank with or without chains, a wire, a gear, a sliding magnet, a cammed physical device on a timeline track, and the like, and/or software tools, such as a graphical user interface (GUI) integrated with the display surface 108. For example, the timeline tool 118 may associate a starting time (e.g., time = t0) with a first end of the timeline track and an ending time (e.g., time t= t1) with a second end of the timeline track. In another example, the timeline tool 118 may associate a first point (e.g., location, spot, mark) of the timeline track with reversing time (e.g., within the tangible/virtual design system 100), a second point of the timeline track with pausing time, and a third point of the timeline track with forwarding time. Areas between the first end, the second end, and/or the third end may be associated with a speed at which the time may be adjusted. Still in another example, the timeline tool 118 may include a rope that may be pulled, pushed, or otherwise moved relative to the display surface 108. The movement sensor 124 may receive an indication of the movement and the automation controller 102 may adjust a simulated time or a project time based on the indication. In another example, the timeline tool 118 may be integrated with the GUI and the display surface 108, and the GUI may receive a user input to adjust time. For example, the automation controller 102 may advance a simulated time, reverse the simulated time, stop the simulated time, or pause the simulated time within a simulation presented by the tangible/virtual design system 100. The automation controller 102 may control the projectors 122 to adjust image content based on the simulated time. As an example, throughput of a ride may be simulated by advancing simulated time within the tangible/virtual design system 100. In another example, the automation controller 102 may reverse project time, stop the project time, or pause the project time. The

automation controller 102 may control the image sensors 120 to capture imagery of the display surface 108 with the object tokens 110, the visualization tool(s) 112, the effect tiles 114, and/or the timeline tool 118 over a period of time and store the captured imagery in the memory 106. The automation controller 102 may also control the projectors 122 to store objection visualizations 116 within the memory 106. The automation controller 102 may store the imagery and/or the object visualizations with a time and/or a date (e.g., project time) of generation. In this way, the automation controller 102 may playback the stored imagery by controlling the projectors 122 and/or the display 126 in response to receiving indication of the movement.

In certain embodiments, the display 126 may be provided in the form of a computing device, such as a head-mounted display device, a personal computer, a laptop, a tablet, a mobile device (e.g., a smart phone), or any other suitable computing device. The automation controller 102 may control operation of the display 126 to display generated image content based on the various objects detected on the display surface 108. In some embodiments, the display 126 may be an electronic display, such as a light-emitting diode (LED) display, liquid crystal display, plasma display, projector, or any other suitable electronic display. Additionally or alternatively, the display 126 may be a head-mounted display that may be worn on the head of a user and the display 126 may be disposed in front of either one or both eyes of the user. The display 126 may display computer-generated imagery, live imagery, virtual reality imagery, augmented reality imagery, mixed reality imagery, and so on. In some embodiments, the display surface 108 and/or the display 126 may be viewed by any number of users. As such, multiple users may view the display 126 and/or the display surface 108 and may collaborate during design of an amusement park attraction or experience using the tangible/virtual design system 100.

The automation controller 102 may represent a unified hardware component or an assembly of separate components integrated through communicative coupling (e.g., wired or wireless communications). The automation controller 102 may be provided in the form of a computing device, such as a programmable logic controller (PLC), personal computer, a laptop, a tablet, a mobile device, a server, or any other suitable computing device. The memory 106 may include one or more tangible, non-transitory, computer-readable media that store instructions executable by the processor

104 (representing one or more processors) and/or data to be processed by the processor 104. For example, the memory 106 may include random access memory (RAM), read-only memory (ROM), rewritable non-volatile memory such as flash memory, hard drives, optical discs, and/or the like. Additionally, the processor 104 may include one or more general purpose microprocessors, one or more application specific integrated circuits (ASICs), one or more field programmable logic arrays (FPGAs), any suitable processing circuitry, or any combination thereof.

Further, the memory 106 may store image data obtained via the image sensors 120 and/or algorithms utilized by the processor 104 to help control operation of the image sensors 120 and/or the projectors 122. For example, the memory 106 may store image data of one or more users interacting with the display surface 108, the object tokens 110, the visualization tools 112, the effect tiles 114, and/or the timeline tool 118 over a period of time. In other instances, the memory 106 may store image data of the object visualizations 116. The processor 104 may control generation of the object visualizations 116 via the projectors 122. Additionally, the processor 104 may process image data to generate control signals for the projectors 122 and/or the image sensors 120, may control and/or monitor operation of the display 126, and/or may detect and determine a position, an orientation, motion attributes, and the like for any number of object tokens 110, visualization tools 112, and effect tiles 114.

In an embodiment, additional data may be accessed by, input into, and/or output by the tangible/virtual design system 100. For example, additional data may include measured data and/or data derived from measurements and/or predictions. Predictions may include mathematical predictions and/or statistical predictions. The additional data may include temperature, humidity, precipitation, wind, cloud, and/or celestial body data (e.g., rise and set times, height, angle, location), and the additional data may be relative to a location (e.g., location of an object token 110, location a data collection site located near an object token 110 (e.g., closest data collection sight to object token 110)). The additional data may come from internal sources (e.g., measured, derived, and/or predicted by the tangible/virtual design system 100 and/or the user) or external sources. External sources may include one or more scientific databases, government databases, research databases, and/or other relevant databases. The additional data may be displayed by the tangible/virtual design system 100 and/or

utilized by the tangible/virtual design system 100 to derive outputs that are displayed by the tangible/virtual design system 100. This may allow conditions (e.g., environmental conditions, astronomical conditions) for particular times of day and/or for particular times of the year to be displayed by the tangible/virtual design system 100. The conditions may be relative to a particular location (e.g., location of an object token 110, location of a data collection site located near an object token 110 (e.g., closest data collection sight to object token 110)). For example, the tangible/virtual design system 100 may display the brightness of light reflecting off of at least part of a feature represented by an object token 110. For example, the brightness of the light reflecting off the at least part of the feature represented by the object token 110 may be derived from sun position data relative to a particular coordinate position and/or elevation on the Earth and may be specific to a specific time of day and/or time of year. Another example may include using historical temperature and humidity data of a particular location on the Earth to predict certain temperatures across a period of time (e.g., a particular time of day and/or time of year) of one or more features represented by an object token, and displaying the predicted certain temperatures through, for example, through color scale of a particular output of the tangible/virtual design system 100.

In some embodiments, the image sensors 120 may be incorporated into the automation controller 102 and may be capable of capturing images and/or video of the display surface 108, the object tokens 110, the visualization tools 112, the effect tiles 114, and the like. The image sensors 120 may generate and/or may transmit image data corresponding to the captured images to the automation controller 102. The image sensors 120 may include any number of cameras, such as any number of video cameras, any number of depth cameras capable of determining depth and distance to the display surface 108 or objects, any number of infrared cameras, any number of digital cameras, and so forth. In certain embodiments, the image sensors 120 may process the image data before transmission to the automation controller 102. Alternatively, the image sensors 120 may transmit raw image data to the automation controller 102. As a specific example, the image sensors 120 may be an infrared camera that operates to detect an emitted infrared signal from a tracker. The automation controller 102 may receive information based on such detections and process the information to determine and monitor a location and/or an orientation of the display surface 108 and/or the

objects on the display surface 108. The automation controller 102 may control operation of the projectors 122 based on the detections, the locations, and/or the orientations. For instance, the image sensors 120 may detect trackers on an exposed surface of the display surface 108 and/or any number of objects on the display surface 108 and may generate location data and/or orientation data based on the detection. The automation controller 102 may receive the location data and/or orientation data from the image sensors 120 and may instruct the projectors 122 to depict image content on projection surfaces of the display surface 108 and/or the objects on the display surface 108. As such, the automation controller 102 may generate and/or adjust image content displayed by the projectors 122 based on location data and/or orientation data.

Additionally, the image sensors 120 may generate image data based on the detection. The automation controller 102 may receive the image data from the image sensors 120 and may process the image data to identify corresponding image content to be projected onto the display surface 108 and/or the objects on the display surface 108. For example, the image data may include one or more images of an object token 110 that corresponds to a ride vehicle. The image sensors 120 may detect a position, an orientation, and/or a configuration of trackers on an exposed surface of the object token 110 and/or may detect machine-readable indicia on the exposed surface of the object token 110. The image sensors 120 may generate tracker data (e.g., location data, orientation data, configuration data) and/or scanning data based on the detected trackers and/or machine-readable indicia. The automation controller 102 may receive the tracker data and/or the scanning data and may identify corresponding image content based on the tracker data and/or the scanning data. For instance, the automation controller 102 may determine a configuration of the trackers on the object token 110 and may compare the configuration with stored tracker configurations in the memory 106. The automation controller 102 may retrieve image content based on the comparison and may control the projectors 122 based on the image content. As such, the automation controller 102 may generate and/or adjust image content displayed by the projectors 122 based on tracker data and/or scanning data for the display surface 108 and/or any number of objects on the display surface 108.

In certain instances, the image sensors 120 may generate image data indicative of a movement of a user interacting with the tangible/virtual design system

100, and the automation controller 102 may generate and/or adjust image content displayed by the projectors 122 and/or the display 126 based on the movement. For example, tangible/virtual design system 100 may generate a digital twin of an object visualization 116 based on movement of the user. The digital twin may be a duplicate (e.g., replicate, copy) of the object visualization 116 and may not include a corresponding object token 110. The tangible/virtual design system 100 may adjust any number of object attributes of the digital twin based on image data indicative of one or more movement(s) of the user.

The tangible/virtual design system 100 may include a printer or other three-dimensional object-generating device 128 that may generate an object token 110 (e.g., an additional object token 110) based on the digital twin. The printer 128 may include a three-dimensional (3D) printer 128 that may generate (e.g., print) the object token 110 based on image data from the tangible/virtual design system 100. For example, the printer 128 may generate a 3D model that visually resembles the digital twin. In other instances, the tangible/virtual design system 100 may instruct the printer 128 to generate a three-dimensional model that visually resembles an object visualization 116 with a corresponding object token 110. The object token 110 may be generated as part of a design cycle and/or a design cycle. Using the tangible/virtual design system 100 and the printer 128, the user may quickly produce physical prototypes (e.g., the object token 110), analyze and/or test the prototypes, and adjust and/or refine the prototypes without waiting for traditional tooling and/or manufacturing. The adjustments and/or refinements may be made by the user and reprinted by the printer 128 within hours, rather than days or weeks in embodiments that employ traditional tooling and/or manufacturing. As such, the user may converge on one design for the object token 110 and/or the object visualization 116 much faster than traditional embodiments. Shortening an amount of time to converge on one design may reduce an amount of time to bring a product to market and may reduce an amount of resources used to bring the product to market. In this way, the tangible/virtual design system 100 may improve the design cycle and/or design process for bringing new products and/or experiences to the market.

Additionally or alternatively, the object attributes of the object visualization 116 may be adjusted based on interactions of a visualization tool 112 with the object

token 110. The tangible/virtual design system 100 may instruct the printer 128 to generate an additional object token 110 based on the adjusted object visualization 116. As such, the additional object token 110 may be the same color and/or include the same attributes as the adjusted object visualization 116. Additionally or alternatively, the tangible/virtual design system 100 may instruct the projectors 122 to projection map onto the object tokens 110 to adjust the object attributes. As such, the object tokens 110 may visually resemble the object visualizations 116.

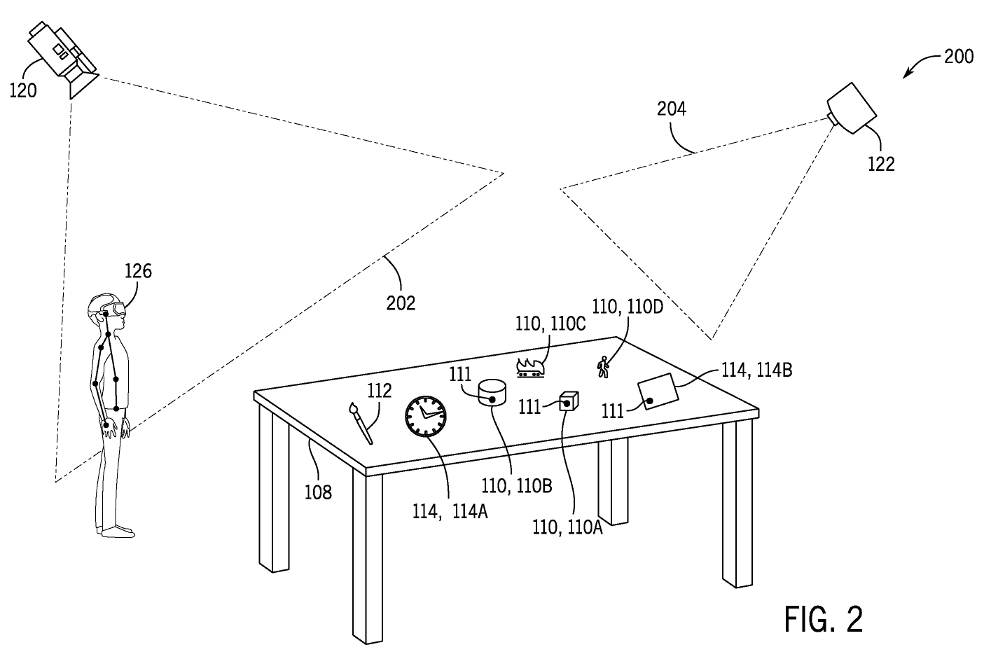

With the foregoing in mind, FIG. 2 is a perspective diagram that illustrates an example embodiment 200 of the tangible/virtual design system 100 in FIG. 1 including the display surface 108, the image sensor 120, the projector 122, and the display 126, in accordance with an embodiment of the present disclosure. In particular, the display 126 may be a head-mounted display worn by a user or multiple users to provide computer-generated imagery, live imagery, virtual reality imagery, augmented reality imagery, mixed reality imagery, and so on. The image sensor 120 may receive control signals from a control system, such as the automation controller 102 of FIG. 1. The image sensor 120 may capture images 202 of the display surface 108 and any number of object tokens 110, visualization tools 112, and/or effect tiles 114 on the display surface 108. The image sensor 120 may include a camera (e.g., an infrared camera) and may detect trackers on an exposed (e.g., upper) surface of the display surface 108, the object tokens 110 (individually referred to herein as a first object token 110A, a second object token 110B, a third object token 110C, and a fourth object token 110D), the visualization tool 112, the effect tiles 114 (individually referred to herein as a first effect tile 114, 114A and a second effect tile 114, 114B), and the like. The image sensor 120 may detect the display surface 108, the object tokens 110, the visualization tool 112, the effect tiles 114, and the like. The image sensor 120 may transmit image data to the control system (e.g., the automation controller 102) based on the detections.

The projector 122 may receive control signals (e.g., an indication of image content) from the control system. The projector 122 may project image content 204 onto any number of projection surfaces, such as the display surface 108, the object tokens 110, and the like. For example, the projector 122 may receive control signals to project the image content 204 onto the display surface 108 that corresponds to a setting for an amusement park attraction or experience. Additionally or alternatively, the

display 126 may receive the control signals and display the image content 204. For example, the user may wear the display 126 (e.g., head-mounted display) and view the tangible/virtual design system 100 as augmented reality, mixed reality, virtual reality, and the like. For example, the display 126 may use augmented reality to update the imagery and/or projection mapping to update the imagery for a mixed reality system.

As discussed with respect to FIG. 1, the automation controller 102 may update an object visualization 116 if movement of a corresponding object token 110 is intentional. For example, the automation controller 102 may receive an indication from one or more sensors 111 on and/or integrated within the object tokens 110 and update the object visualization 116 in response to receiving the indication. The automation controller 102 may determine an updated position and/or orientation of the object visualization 116 based on a position and/or orientation of the trackers on the surface of the object token 110. If the movement of the object token 110 is not intentional, then the automation controller 102 may not update the corresponding object visualization 116.

In certain instances, two or more object tokens 110 may be moved as a group. For example, a scene may include two or more object tokens 110 positioned proximate to each other and/or on a second surface, such as a board or a plate. The scene may be moved to another position on the display surface 108. For example, the second surface may be lifted and moved, thereby causing the two or more object tokens 110 to be moved. The automation controller 102 may identify similar movement among the two or more object tokens 110 in the scene and determine that movement of all object tokens 110 within the scene is intentional. In another example, the automation controller 102 may determine that the two or more object tokens 110 may be moving in a similar fashion, such as in a similar direction, a similar rotation, a similar change in position along an x-axis, y-axis, z-axis, pitch, yaw, and/or roll, and the like. The automation controller 102 may group together the two or more object tokens 110 with similar movements and determine that movement of the group is intentional if movement of one object token 110 within the group is intentional. For example, a sensor 111 of a first object token 110 may transmit an indication of movement between a first time and a second time (e.g., based on the sensor 111 indicating that a user intentionally moved the first object token 110). The automation controller 102 may

determine that the first object token 110 moved ten inches in a first direction. The automation controller 102 may also determine that a second object token 110 moved in a similar manner as the first object token 110, such as ten inches in the first direction. The automation controller 102 may group together the first object token 110 and the second object token 110 based on the similar movements between the first time and the second time.

In certain instances, the automation controller 102 may determine if a portion of the display surface 108 may be in an active status If the object token 110 is positioned in a portion of the display surface 108 not in active use, then the automation controller 102 may determine that any movement of the object token 110 is not intentional. Additionally or alternatively, a user may set a status of the object token 110 as “active” or “inactive.” In the active status, the automation controller 102 may update the corresponding object visualization 116 if movement of the object token 110 is intentional. In the inactive status, the automation controller 102 may not update the corresponding object visualization 116 even if the object token 110 is moved. In certain instances, the user may accidently knock over or bump into the object token 110. In another instance, the display surface 108 may shake, thereby causing the object tokens 110 to shake. The automation controller 102 may continue to monitor (e.g., track) the object token 110 in the inactive status and may identify the movement of the object tokens 110 as an unintentional movement. As such, the automation controller 102 may not update the object visualization 116 of the object token 110. In other instances, the user may override the inactive status by causing a sensor 111 on and/or integrated within the object token 110 to transmit an indication of intentional movement. For example, the sensor 111 may include an electronic switch built into the object token 110 and the user may close, activate, or hold down the electronic switch to override the inactive status and/or switch the status of the object token 110 to an active status. The automation controller 102 may set the object token 110 status to active in response to the user holding down the electronic switch and/or receiving the indication of intentional movement from the sensor 111. The automation controller 102 may update the corresponding object visualization 116 in response to the object token 110 status being active.

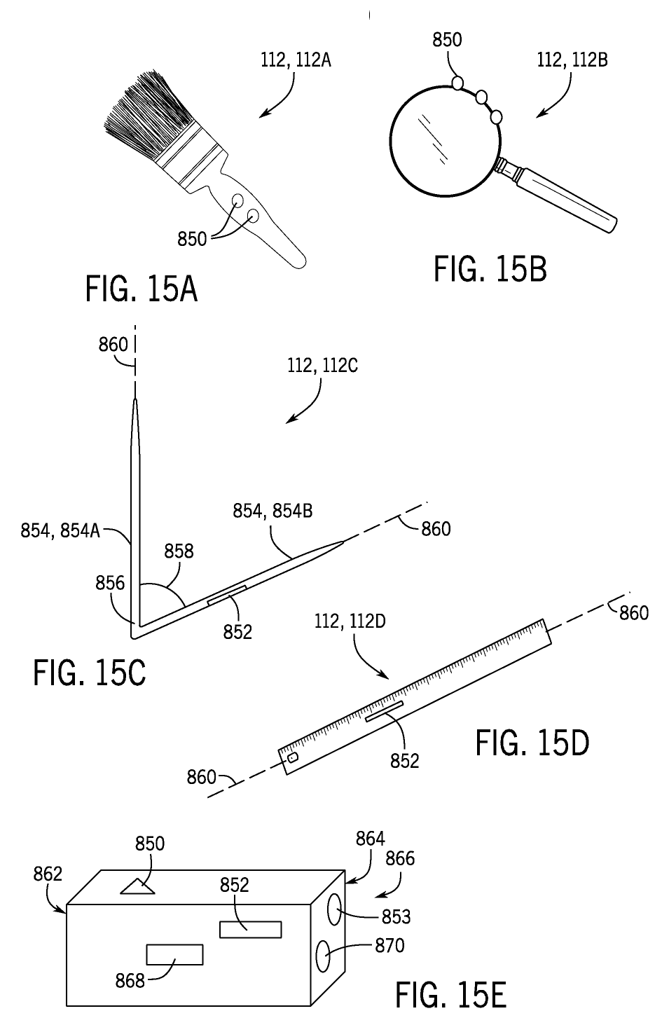

Although the discussion of intentional movement is associated with object tokens 110, it may be appreciated that the detection of intentional movement and its application to virtualization may be applied to visualization tools 112 and/or effect tiles 114. For example, two or more effect tiles 114 may be moved from a first portion of the display surface 108 to a second portion of the display surface 108, and the automation controller 102 may group the two or more effect tiles 114 together. The automation controller 102 may update one or more object visualizations 116 based on a determination that the movement is intentional and an interaction between the effect tiles 114 and the one or more object tokens 110. For example, a weather effect tile 114 and a sunlight effect tile 114 may be moved together from the first portion of the display surface 108 to the second portion of the display surface 108. Both the weather effect tile 114 and the sunlight effect tile 114 may include sensor 111, such as a capacitive touch sensor, that may be activated when the user touches the tiles 114. The automation controller 102 may receive the indication of movement of the two effect tiles 114 and may adjust light effects and/or weather effects based on the position of the effect tiles 114, the movement of the effect tiles 114 being intentional, or both. In another example, the visualization tools 112 may be set to an inactive status and activated by one or more sensors 111 on and/or partially integrated within the visualization tool 112. The automation controller 102 may update one or more object visualizations 116 based on a determination that the movement is intentional and an interaction between the visualization tool 112 and one or more object tokens 110. For example, the user may activate the sensor 111 on and/or integrated within the visualization tool 112 by picking up the visualization tool 112. That is, the user may set the visualization tool 112 to an active status and/or the automation controller 102 may determine that movement of the visualization tool 112 is intentional. As further described with respect to FIGS. 15A-E, the user may apply the effect of the visualization tool 112 by bringing the visualization tool 112 proximate to an object token 110.

Additionally or alternatively, the user may interact with the tangible/virtual design system 100 by adjusting the timeline tool 118, adjusting a position of the object tokens 110, and/or the visualization tools 112 and the controller may cause the display 126 to update the viewed imagery. In addition, additional users may wear the display 126 and view the updated imagery. For example, multiple users may wear the display 126 and the control signal may cause the projected image content within each display

126 to be updated in response to actions taken by one user. In other instances, the control signal may cause a first set of displays 126 to be updated and may not cause a second set of displays 126 to be updated, such as if a first group of users may be designing a first area of the amusement park attraction and a second group of users may be designing a second area of the amusement park attraction. The image content 204 may include scenery, buildings, structures, landscapes, natural features, topography, and so forth. Additionally or alternatively, the image content may include representations of ride vehicles, guests, animated figures, and the like.

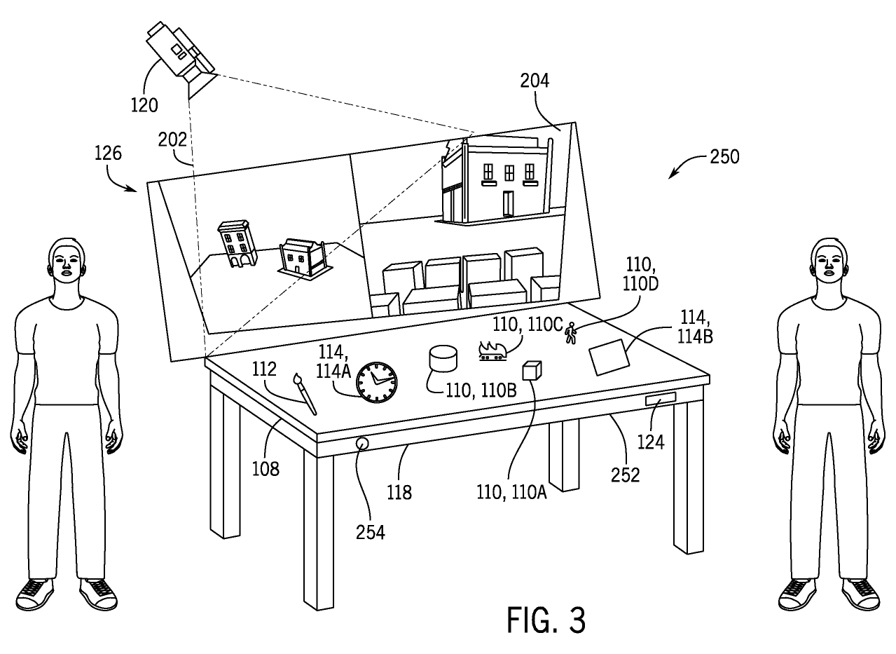

With the foregoing in mind, FIG. 3 is a perspective diagram that illustrates an example embodiment 250 of the tangible/virtual design system 100 in FIG. 1 including the display surface 108, the timeline tool 118, the image sensor 120, and the display 126, in accordance with an embodiment of the present disclosure. In the illustrated embodiment 250, the display 126 includes an electronic display, such as an LED display, a liquid crystal display, a plasma display, or any other suitable electronic display. In certain instances, the display 126 may include a projector (e.g., projector 122 described with respect to FIG. 2) that projects the image content 204 onto a screen for multiple users to view. The display 126 may project image content 204 to visually represent components and features of a real-world location or structure, such as an amusement park attraction or experience. The display 126 may also project image content 204 (e.g., stored image content captured or sensed by the image sensors 120) of one or more users interacting with the display surface 108, the object tokens 110, the visualization tools 112, the effect tiles 114, the timeline tool 118, and the like. In this way, one or more users may collaborate within the tangible/virtual design system 100 and view the object visualizations 116 in real-time or near real-time on the display 126.

Additionally, the display surface 108 may be coupled to the timeline tool 118 and the movement sensor 124, both of which may enable adjusting a time within the tangible/virtual design system 100. The timeline tool 118 may include a physical device, and the movement sensor 124 may generate sensor data indicative of movement of the physical device. As illustrated, the timeline tool 118 includes a pulley system with a rope 252 and a wheel 254 located underneath the display surface 108. The pulley system may be a fixed pulley system, a movable pulley system, a compound pulley system, and so on. The rope 252 may be disposed along a length and a width of the

display surface 108, such that multiple users may interact with the rope 252. For example, the rope 252 may be pulled in a clockwise direction (e.g., with respect to the display surface 108), a counterclockwise direction (e.g., with respect to the display surface 108), upwards towards the display surface 108, downwards away from the display surface 108, and the like. The rope 252 may be coupled to the wheel 254, which facilitates movement of the rope 252. While one wheel 254 is illustrated in the example embodiment 250, any suitable number of wheels may be coupled to the display surface 108 to move the rope 252.

In an embodiment, the timeline tool 118 may include an actuator coupled to the automation controller 102, which may control the actuator to move the rope 252. The actuator may include a mechanical linear actuator, an electric actuator, and the like. For example, the actuator may receive control signals from the automation controller 102 and adjust a position of the rope 252 based on the signal. Although the illustrated timeline tool 118 includes a pulley system, in other embodiments, the timeline tool 118 may include a lever, a dial, a slider, a GUI integrated with the display 126, and the like. For example, the timeline tool 118 may include a GUI integrated with the display surface 108, which may include one or more inputs (e.g., buttons) associated with adjusting time. Thus, the GUI may receive user input indicative of advancing time, reversing time, and/or pausing time.

The movement sensor 124 may generate sensor data indicative of movement of the rope 252 relative to the display surface 108. For example, the movement sensor 124 may include a pressure sensor, an accelerometer, a proximity sensor, a touch switch, a force sensor, and the like. The movement sensor 124 may detect a speed of movement, a direction of movement, and/or a position of the rope 252 relative to the display surface 108. For example, the movement sensor 124 may generate sensor data indicative of the rope 252 in a top position, a middle position, and/or a bottom position and transmit the sensor data to the control system based on the detected position. In another example, the movement sensor 124 may generate sensor data indicative of movement of the rope 252, such as in a clockwise direction, a counterclockwise direction, upwards, downwards, and the like. The movement sensor 124 may transmit the sensor data to the control system.

The automation controller 102 may receive the sensor data and adjust a simulation time or a real, project time. For example, clockwise movement of the rope 252 may correspond to advancing the simulation time, while counterclockwise movement of the rope 252 may correspond to reversing the simulation time. In another example, a top position of the rope 252 may correspond to advancing time, a middle position of the rope 252 may correspond to stop or pausing time, and a bottom position of the rope 252 may correspond to reversing time. In certain instances, the adjustment of time may be associated with a speed of movement. For example, slowly moving the rope in a clockwise direction may increment the time more slowly in comparison to quickly moving the rope. The automation controller 102 may output a control signal based on the sensor data.

The display 126 may receive control signals (e.g., an indication of image content) from the control system and project image content 204. In certain instances, the image content 204 may include the object visualizations 116 within the tangible/virtual design system 100. For example, the display 126 may display image content 204 of a ride vehicle progressing through a ride as the rope 252 moves in a clockwise direction (e.g., as simulation time advances). In another example, the image content 204 may include guest throughput at a vendor as simulation time advances and the image content 204 may be paused if the rope 252 stops moving (e.g., stopping or pausing simulation time).

In other instances, the image content 204 may include image data of the one or more users interacting with the tangible/virtual design system 100 and the display 126 may project a playback (e.g., recording) of the interactions. For example, the image sensors 120 may generate image data of multiple users interacting with the object tokens 110, the visualization tools 112, the effect tiles 114, and the like over a period of time. The display 126 may project (e.g., playback) the image data at a speed of the playback that may be based on the indication of the movement.

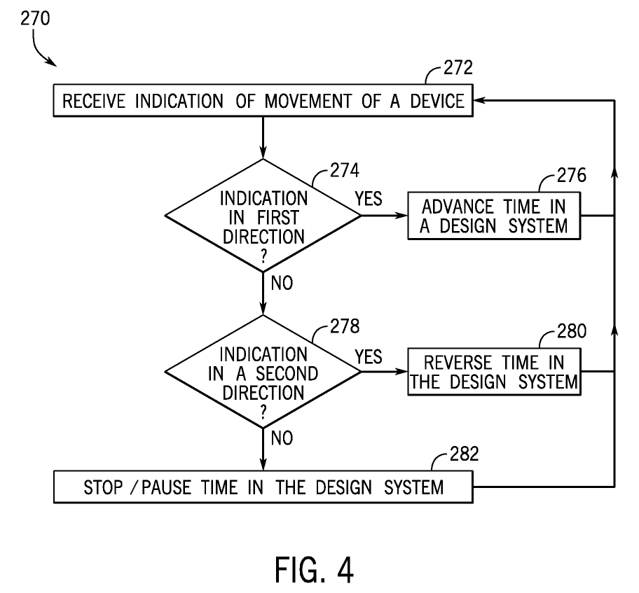

With the foregoing in mind, FIG. 4 illustrates a flowchart of a method or process 270 for adjusting time (e.g., simulation time, real, project time) within the tangible/virtual design system 100 of FIG. 1, in accordance with embodiments of the present disclosure. While the process 270 is described as being performed by the automation controller 102, it should be understood that the process 270 may be

performed by any suitable device or processing circuitry, such as the processor 104 and so forth, that may control and/or communicate with components of a tangible/virtual design system 100. Furthermore, while the process 270 is described using steps in a specific sequence, it should be understood that the present disclosure contemplates that the described steps may be performed in different sequences than the sequence illustrated, and certain described steps may be skipped or not performed altogether. In some embodiments, the process 270 may be implemented by executing instructions stored in a tangible, non-transitory, computer-readable medium, such as the memory 106, using any suitable processing circuitry, such as the processor 104.

At block 272, the automation controller 102 receives an indication of movement of a device (e.g., the timeline tool 118). For example, the timeline tool 118 may be moved in clockwise direction or a counterclockwise direction and the movement sensor 124 may generate sensor data indicative of the movement. Additionally, the sensor data may include a speed of movement and/or a position of the timeline tool 118. For example, the timeline tool 118 may be slowly moved (e.g., moved a small amount in a period of time) to cause the time to advance or rewind at a first, slower rate, or more quickly moved (e.g., moved a greater amount in the period of time) to cause the time to more advance or rewind at a second, faster rate.

At block 274, the automation controller 102 determines if the indication is in a first direction. For example, the timeline tool 118 may move in a clockwise direction or a counterclockwise direction relative to the display surface 108. In an instance, movement in a clockwise direction may be associated with advancing time in the tangible/virtual design system 100 while movement in a counterclockwise direction may be associated with reversing time, or vice versa. In another example, the timeline tool 118 may be moved to a top position, a bottom position, and/or a middle position (e.g., with respect to the display surface 108). The top position may be adjacent the display surface 108, the middle position may be adjacent and/or under the top position, and the bottom position may be adjacent and/or under the middle position. In certain instances, the top position may be associated with advancing time, the bottom position may be associated with reversing time, and the middle position may be associated with pausing time. In other instances, the top position may be associated with reversing time and the bottom position may be associated with advancing time.

If the automation controller 102 determines the indication is in the first direction, then at block 276 the automation controller 102 advances time in the tangible/virtual design system 100. The automation controller 102 may adjust the image data based on the advancement of time and control the display surface 108 to project the object visualizations 116. For example, the image data may include guest throughput at an attraction throughout a day. The automation controller 102 may simulate guest throughput at a simulated advanced time based on the timeline tool 118 being moved in the first direction. In another example, the image data may include users interacting with the object tokens 110 and the automation controller 102 may advance the project time based on the timeline tool 118 being moved in the first direction. The process 270 may return to block 272 to receive another indication of movement of the device.

If the automation controller 102 determines the indication is not in the first direction, then at block 278, the automation controller determines if the indication is in a second direction. For example, the second direction may be counterclockwise movement if the first direction is clockwise movement. In another example, the second direction may be movement to the bottom position.

If the automation controller 102 determines the indication is in the second direction, then at block 280, the automation controller 102 reverses time in the tangible/virtual design system 100. The automation controller 102 may adjust the image data based on the reversal of time within the tangible/virtual design system 100 and transmit the image data to the display 126. For example, the image data may include a ride vehicle moving backwards through a ride. In another example, the image data may include a playback of user interactions with the object tokens 110 of the tangible/virtual design system 100 over a period of time. The process 270 may return to block 272 to receive another indication of movement of the device.

If the automation controller 102 determines the indication is not in the second direction, then at block 282, the automation controller 102 stops or pauses time in the tangible/virtual design system 100. For example, pulling the rope 252 in a lateral direction or longitudinal direction with respect to the display 126 may be associated with stopping or pausing time within the tangible/virtual design system 100. In another example, positioning the rope 252 in a middle position may be associated with stopping

or pausing time. As such, the automation controller 102 may determine if the movement is not in a first direction or a second direction and the automation controller 102 may update the image data to stop or pause at a certain point. The process 270 may return to block 272 to receive indication of movement of the device.

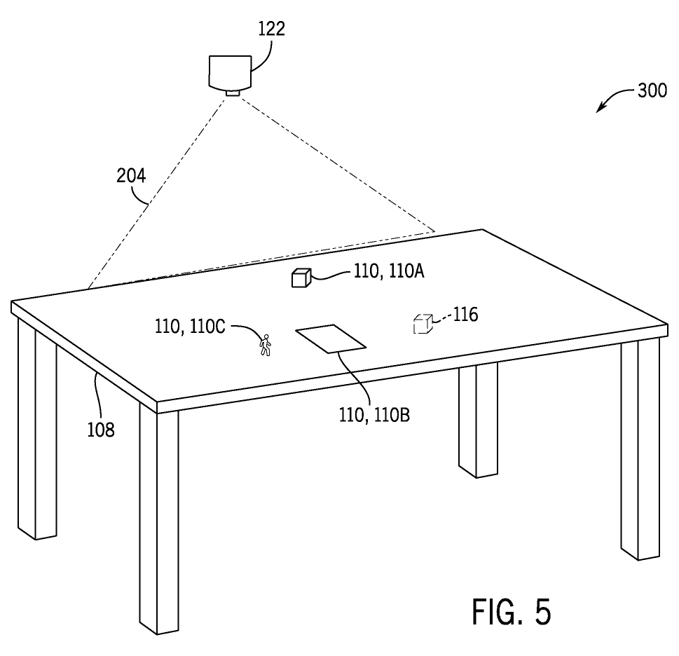

With the foregoing in mind, FIG. 5 is a perspective diagram that illustrates an example embodiment 300 of the tangible/virtual design system 100 in FIG. 1 including the display surface 108 and the projector 122, in accordance with an embodiment of the present disclosure. The projector 122 may project image content 204 onto the display surface 108 to visually represent components and features of an amusement park attraction or experience. For example, the tangible/virtual design system 100 in FIG. 1 may be utilized to design a Pepper’s Ghost illusion. The Pepper’s Ghost illusion utilizes reflective properties of translucent or transparent materials (e.g., glass, plastic, or the like) to virtually project images into a scene for viewing by guests. For example, an angled pane of glass may be positioned in front of a stage and imagery may be projected toward the glass from outside of a line of sight of the audience and then partially reflected toward the audience by the pane of glass.

As shown in FIG. 5, a first object token 110, 110A may represent imagery designed to be projected towards a second object token 110, 110B that represents a reflective material, such as an angled pane of glass. A third object token 110, 110C may represent one or more guests viewing the illusion. The image sensors 120 in FIG. 1 may capture image data of the object tokens 110 and determine position data, orientation data, configuration data, and the like for each of the object tokens 110. Additionally or alternatively, the image sensors 120 may capture image data and may detect trackers and/or machine-readable indicia for the object tokens 110. The image sensors 120 may identify the object tokens 110 based on the detected trackers and/or machine-readable indicia. In some embodiments, the automation controller 102 may receive the image data and may identify the object tokens 110 based on tracker data and/or scanned data generated by the image sensors 120. The automation controller 102 may determine the first object token 110, 110A corresponds to a device that projects imagery to provide a visual effect, the second object token 110, 110B corresponds to a reflective material or surface, and the third object token 110, 110C corresponds to one or more guests. The automation controller 102 may determine

positions and orientations of the first object token 110, 110A and the second object token 110, 110B and may generate position data and orientation data for the object tokens 110. The automation controller 102 may utilize the position data and orientation data to determine a position and orientation of reflected imagery perceived by the audience. As such, the automation controller 102 may instruct the projector 122 to generate an object visualization 116 that corresponds to the reflected imagery. The projector 122 may project image content 204 onto the display surface 108 at a corresponding position and orientation based on instructions from the automation controller 102. Accordingly, the tangible/virtual design system 100 may accurately represent visual effects to provide a better understanding of amusement park attractions or experiences

Additionally or alternatively, any number of the object tokens 110 may include actuators, such as electronic motors, capable of moving the object tokens along and about the display surface 108 to different positions. For example, a user may input a desired position and/or desired orientation for the reflected imagery in the Pepper’s Ghost illusion via a user input interface of the control system or any other suitable input device (e.g., mouse, keyboard, and so forth). Additionally or alternatively, a fourth object token may correspond to the reflected imagery and may be disposed on the display surface 108. The image sensors 120 may detect the position and/or the orientation of the fourth object token and may generate position and/or orientation data based on the detection. Additionally or alternatively, the user may place the third object token 110, 110C that corresponds to one or more guests of the amusement park at a second desired position and/or second desired orientation. The image sensors 120 may detect the position and/or the orientation of the third object token 110, 110C and may generate or update position and/or orientation data based on the detection. The automation controller 102 may receive the position and/or orientation data and may determine locations and/or orientations for the first object token 110, 110A and the second object token 110, 110B. In an instance, the automation controller 102 may instruct the projector 122 to project image content corresponding to the determined locations and/or orientations. As such, the projector 122 may project a marker or indicator onto the display surface 108 that indicates the location and/or orientation of the projected imagery and/or the reflective material. Additionally or alternatively, the automation controller 102 may control the actuators of the first object token 110, 110A

and/or the second object token 110, 110B to move to the determined locations and/or orientations. The tangible/virtual design system 100 may also monitor the display surface and object tokens 110 for updates to their positions and/or orientations. Accordingly, adjustment of the position of any of the object tokens 110, 110A, 110B, 110C may result in adjustment of the remaining object tokens 110 and/or the object visualizations 116.

In certain embodiments, the automation controller 102 may compare the orientation data and/or position data with constraint criteria (e.g., line of sight criteria, threshold angles, brightness threshold, and the like). The automation controller 102 may determine the reflected imagery may not be produced based on one or more of the constraint criteria. For example, the automation controller 102 may determine another object is disposed between the projected imagery object token 110, 110A and the reflective material object token 110, 110B. As such, the projected imagery may not be reflected by the reflective material. The automation controller 102 may instruct one or more components of the tangible/virtual design system 100 based on the constraint criteria. For instance, the automation controller 102 may instruct the projector 122 to project image content that identifies one or more incorrectly disposed object tokens 110. Additionally or alternatively, the automation controller 102 may instruct the projector 122 and/or the display 126 to display a notification indicative of the constraint criteria.

In some embodiments, the tangible/virtual design system 100 may capture image data that includes configurations, positions, and/or orientations of object tokens 110, visualization tools 112, and/or effect tiles 114. The image sensors 120 may generate configuration data, position data, and/or orientation data based on the detected objects. The automation controller 102 may receive the configuration data, position data, and/or orientation data and may store the data as a particular design. For example, the tangible/virtual design system 100 may receive an input that instructs the automation controller to store the data as a design for an amusement park attraction or experience. The automation controller 102 may store the data and images in the memory 106. Accordingly, the tangible/virtual design system 100 may store a database of any number of amusement park attraction designs. Additionally, the automation controller 102 may retrieve stored designs and may control components of the

tangible/virtual design system 100 based on the stored design. For example, the automation controller 102 may retrieve configuration data, position data, orientation data, image data, and the like. The automation controller 102 may instruct the projector 122 based on the stored design. For example, the projector 122 may project image content that includes indicators for placement of object tokens 110, visualization tools 112, effect tiles, and so forth on the display surface 108 and/or a staging surface. Additionally or alternatively, the automation controller 102 may instruct actuators of the objects to move the objects to desired positions and/or orientations based on the stored design.

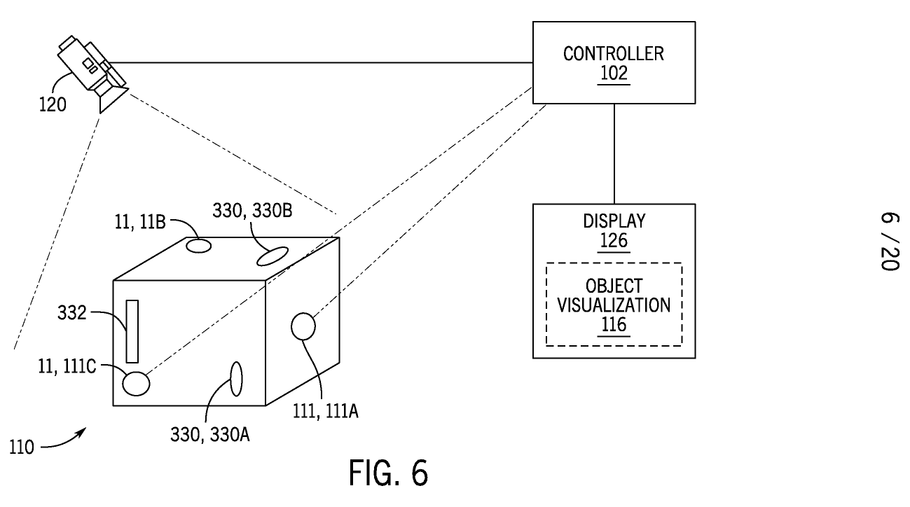

FIG. 6 is a block diagram of an embodiment of the object token 110 with one or more sensors 111 (individually referred to herein as a first sensor 111, 111A, a second sensor 111, 111B, and a third sensor 111, 111C), one or more trackers 330 (individually referred to herein as a first tracker 330, 330A and a second tracker 330, 330B), and a machine-readable indicia 332. The sensors 111 may be disposed on and/or integrated (e.g., at least partially integrated) within the object token 110. The trackers 330 and/or the machine-readable indicia 332 may be exposed on a surface of the object token 110. In certain instances, the trackers 330 and/or the machine-readable indicia 332 may be positioned on a portion of the object token 110 that enables the trackers 330 and/or machine-readable indicia 332 to be concealed or obscured from interfering with projected imagery.

As discussed with respect to FIG. 1, the sensors 111 may include a touch sensor (e.g., a capacitive touch sensor), an electronic switch, a button, a proximity sensor, a camera, an optical mouse, a LiDAR sensor, a gyroscope, an accelerometer, or any suitable sensor for detecting intention, motion, and/or touch. The sensors 111 may be on and/or integrated within the object token 110. In an embodiment, the object token 110 may include multiple sensors 111 that each transmit an indication of movement of the object token 110. The automation controller 102 may determine if the movement of the object token 110 is intentional based on one or more of the signals received from the sensors 111. In an embodiment, the automation controller 102 may receive multiple signals from different sensors 111 of one object token 110 and determine if the movement of the object token 110 is intentional or unintentional based on the multiple signals. For example, the first sensor 111, 111A may include a capacitive sensor that

transmits an indication of the user touching the object token 110, the second sensor 111, 111B may include a button that transmits an indication of the user pressing on the button, and the third sensor 111, 111C may include an accelerometer that transmits an indication of movement of the object token 110. The automation controller 102 may receive the signals from the three sensors 111 and determine that movement of the object token 110 is intentional. In another example, the automation controller 102 may determine that movement of the object token 110 is intentional based on an indication from the second sensor 111, 111B of the user pressing down on the button and an indication from the third sensor 111, 111C of movement of the object token 110. That is, the automation controller 102 may determine that the movement is intentional based on a majority (or any other proportion) of the signals from the sensors 111 indicating movement.

In other embodiments, the automation controller 102 may determine movement of the object token 110 to be intentional based on an indication of movement from one sensor 111 of multiple sensors 111 of the object token 110. For example, the automation controller 102 may receive an indication from the first sensor 111, 111A indicative of the user touching the object token 110. The automation controller 102 may determine the status of the object token 110 to be “active” and track movement of the object token 110 in order to update the corresponding object visualization 116 of the object token 110 based on the movement. In another example, the automation controller 102 may receive an indication from the second sensor 111, 111B of the user pressing and/or holding down the button. The automation controller 102 may determine the movement of the object token 110 is intentional for as long as the second sensor 111, 111B transmits the indication. The object token 110 may be active over a period of time the user holds down the button. In other words, the period of time may be for as long as sensor 111 transmits the indication of movement. As long as one sensor 111 is activated, the automation controller 102 may determine movement of the object token 110 is intentional. The user may place the object token 110 back onto the display surface 108, which may cause the second sensor 111, 111B to stop transmitting the indication and the period of time to lapse. As such, subsequent movement of the object token 110 (e.g., while the automation controller 102 determines that the object token is inactive) may be determined to be unintentional. In this way, unintentional movements

picked up by the image data and/or detected by the automation controller 102 may be reduced or eliminated.

In another example, the image data from the image sensors 120 may indicate movement of the object token 110, but sensor data from one or more sensors 111 may indicate no movement of the object token 110. The automation controller 102 may determine that the object token 110 is not moving based on the sensor data and may not update the object visualization of the object token 110. As such, unintentional movements (e.g., due to noises or artifacts in the image sensor signals or the tangible/virtual design system 100) may be reduced or eliminated. In certain instances, the automation controller 102 may apply a smoothing or rounding threshold to motion being detected within the image data to reduce or eliminate erroneous motion detections within the image data, micro-movement detections, and/or noise within the tangible/virtual design system 100. The automation controller 102 may make the threshold a discrete distinction or blend the threshold between different motion determinations. The blend threshold (e.g., ratio) may be based on a time delay, a confidence value in the motion’s intention, a motion speed, and the like.

In certain instances, the object token 110 may include multiple sensors 111 where one sensor 111 may be malfunctioning. For example, the first sensor 111, 111A may transmit an erroneous indication (e.g., signal), but the other two sensors 111 may transmit a correct indication. In another example, a first sensor 111 may transmit a first indication of the object token 110 being moved while a second sensor 111 may transmit a second indication of the object token 110 remaining stationary. The automation controller 102 may use image data from the image sensors 120, the first indication, and the second indication to determine if the object token 110 is being intentionally moved. If the image data confirms the user moving the object token 110, the automation controller 102 may confirm the first sensor 111 is functioning properly and determine that the second sensor 111 is malfunctioning. The automation controller 102 may output an error notification to the user. In some embodiments, the automation controller 102 may stop using the malfunctioning sensor as a factor in determining whether movement of the object token 110 is intentional. By including multiple sensors 111 on and/or within one object token 110, the chances of an erroneous determination by the automation controller 102 may be reduced or eliminated. Additionally, the automation

controller 102 may use image data from the image sensors 120 to determine and/or verify that if the movement is intentional or unintentional. For example, the automation controller 102 may use live camera feeds from the image sensors 120, laser curtains, motion detection, skeletal trackers, and/or other detection/tracking solutions to determine if movement of the object tokens 110 is intentional. As further described with respect to FIG. 9, the automation controller 102 may use skeletal tracking to determine if a user may be moving an object token 110.

The object tokens 110 may also include the trackers 330, which may include active devices (e.g., light emitting diodes), passive devices (e.g., reflectors, pigmented portions). The trackers 330 may be any suitable shape and/or size. The automation controller 102 may determine the position and/or orientation of the object token 110 within the tangible/virtual design system 100 based on the position and/or orientation of the trackers 330. For example, the trackers 330 may include active devices that transmit a signal to the image sensors 120 and/or the automation controller 102. The automation controller 102 may determine the position and/or orientation of the object 110 based on a comparison of the signal to known indicators, such as the position and/or orientation of the trackers 330 within the display surface 108. For example, the trackers 330 may include one or more light emitting diodes that may emit light based on a pattern, a frequency, a wavelength, or any combination thereof. The automation controller 102 may determine a position and/or orientation of the light emitting diode by determining an intensity of light emitted by the light emitting diode, the position of light relative to other objects (e.g., object tokens 110, effect tiles 114, visualization tools 112) within the tangible/virtual design system 100, a pattern and/or frequency of light emitted, and the like. In another example, the automation controller 102 may compare an orientation (e.g., rotation) of a pattern the trackers 330 to a known pattern of the trackers 330 stored in a database, such as one stored in the memory 105. The automation controller 102 may determine an angle of rotation based on the comparison. In another example, the trackers 330 may include passive devices and the image sensors 120 may generate image data of the object token 110 and/or the display surface 108. Based on a comparison between the trackers 330 on the object token 110 and the trackers 330 on the display surface 108, the automation controller 102 may determine the position and/or orientation of the object token 110. For example, the trackers 330 may include four trackers 330 oriented in a trapezoid shape and the orientation of the

object token 110 may be determined based on an orientation of the trapezoid shape within the tangible/virtual design system 100.

The machine-readable indicia 332 may include a bar code, a QR code, a radio frequency (RF) tag, or any suitable identifier that identifies the object token 110. The automation controller 102 may determine a corresponding object visualization 116 based on the machine-readable indicia 332. For example, a database, such as one stored in the memory 106, may store a relationship between a machine-readable indicia 332, an object token 110, and an object visualization 116. For example, the automation controller 102 may identify an object token 110 based on machine-readable indicia 332 exposed on a surface of the object token 110. The automation controller 102 may receive image data from the image sensors 120, identify the machine-readable indicia 332 within the image data, and interpret and/or decode the machine-readable indicia 332 to identify the object token 110. The automation controller 102 may identify a corresponding object visualization 116 based on the machine-readable indicia 332 and/or a relationship between the machine-readable indicia 332, the object token 110, and the object visualization 116 stored in the database.

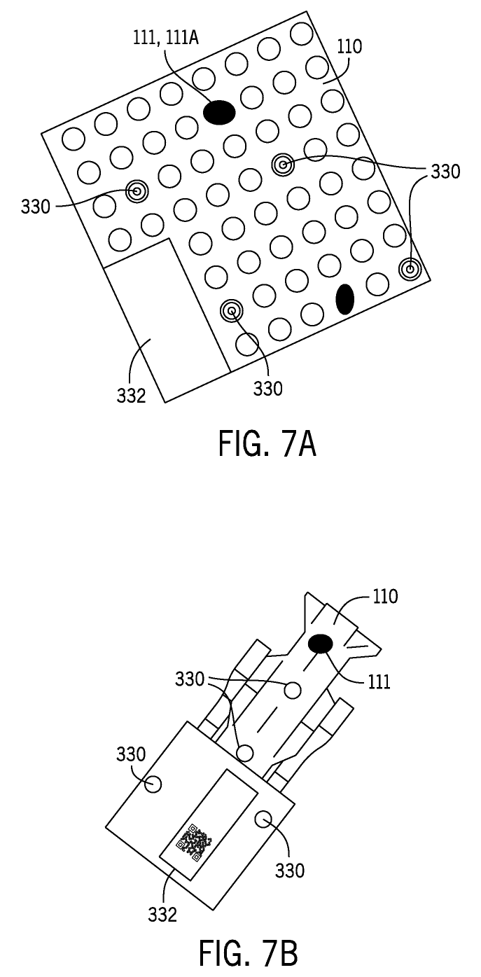

With the foregoing in mind, FIG. 7A is a perspective diagram of an embodiment of the object token 110 with sensors 111, one or more trackers 330, and a machine-readable indicia 332. The object token 110 may be any suitable shape, size, or color. For example, the object token 110 may include an interlocking brick with the sensors 111, the trackers 330, and the machine-readable indicia 332 exposed on a surface. As illustrated, the object token 110 may include a square piece with circular extensions. The automation controller 102 may identify an object visualization 116 (e.g., virtual model) associated with the object token 110 based on the machine-readable indicia 332 exposed on the surface of the object token 110. The automation controller 102 may identify, interpret, and/or decode the machine-readable indicia 332 exposed on a surface of the object token 110 to identify a corresponding object visualization 116. The automation controller 102 may retrieve image content (e.g., object visualization 116) corresponding to the object token 110 and may control operation of the projectors 122 to display the image content. For example, the object token 110 may correspond to a building token and/or the corresponding object visualization 116 may be correspond to a building. The automation controller 102 may interpret and/or decode

the machine-readable indicia 332 of the object token 110 to identify a building as the corresponding object visualization 116 and control operation of the projectors 122 to generate an object visualization 116 corresponding to the building on the display surface 108.

Additionally or alternatively, the automation controller 102 may utilize the configuration (e.g., position, orientation) of the trackers 330 to identify the position and/or orientation of the object token 110 and adjust a position and/or orientation of the corresponding object visualization 116. For example, the image sensors 120 may generate image data and the automation controller 102 may determine tracker data (e.g., location data, orientation data, configuration data) based on the image data. The trackers 330 may be in a configuration that may be mapped to a known configuration stored in a database, such as one stored in the memory 106. As illustrates, trackers 330 may include four dots in a rectangular configuration. The automation controller 102 may identify the position and/or the orientation of the object token 110 with respect to the display surface 108 based on the rectangular configuration of the trackers. Additionally or alternatively, the automation controller 102 may identify the position and/or orientation of the object token 110 with respect to other object tokens 110 disposed on the display surface 108.

In some embodiments, the automation controller 102 may identify movement of the object token 110 and may determine if the movement is intentional or unintentional. For example, the automation controller 102 may receive image data from the image sensors 120 indicative of the object token 110 moving. The automation controller 102 may determine the movement to be intentional if the sensors 111 transmit an indication of movement. By way of example, the object token 110 may include two sensors 111, such as a capacitive sensor 111, 111A and an accelerometer 111, 111B. The capacitive sensor 111, 111A may transmit an indicative of the object token 110 being touched by a user and/or the accelerometer 111, 111B may transmit an indication of the object token 110 being moved by the user. The automation controller 102 may update the object visualization 116 in response to receiving an indication of movement from the capacitive sensor 111, 111A and/or the accelerometer 111, 111B. In an embodiment, the automation controller 102 may determine that movement of the object token 110 is intentional based on an indication from one of the sensors 111. In other

embodiments, the automation controller 102 may determine that the movement is intentional based on multiple indications from each of the sensors 111. Additionally or alternatively, the object token 110 may include a third sensor 111, such as a button, embedded on a surface of the object token 110. The user may press the button to activate the object token and the automation controller 102 may update the corresponding object visualization 116 in response to the user pressing the button.

With the foregoing in mind, FIG. 7B is a perspective diagram of an object token 110 with sensors 111, trackers 330, and machine-readable indicia 332. As illustrated, the object token 110 may be a train model with sensors 111, trackers 330, and machine-readable indicia 332 on an exposed surface (e.g., projection surface). As illustrated, the trackers 330 include four dots positioned across the exposed surface and used by the automation controller 102 to determine a position and/or an orientation of the object token 110 within the tangible/virtual design system 100.

The object token 110 may also include machine-readable indicia 332, such as a barcode, a QR code, an RF tag, and the like. The illustrated machine-readable indicia 332 includes a QR code that may be captured the image sensors 120 as image data. The automation controller 102 may identify the QR code within the image data and compare the QR code to stored machine-readable indicia stored in the memory 106. The automation controller 102 may determine a match between the machine-readable indicia 332 and the stored machine-readable indicia to determine an associated object visualization 116. For example, the automation controller 102 may identify one or more attributes of the object token 110, such as a color, a texture, a material, a speed of movement, a number of passengers, a cost, and so on. The automation controller 102 may instruct the projectors 122 to adjust the object visualization 116 based on the attributes of the object token 110 (e.g., to display the color, the texture, the material, an indication of the speed of the movement, the number of passengers, an indication of the cost, and so on). As an example, the object token 110 may include four sensors 111, such as a capacitive sensor 111, 111A integrated into a first surface of the object token 110, an electronic switch 111, 111B integrated into a second surface of the object token 110, a proximity sensor 111, 111C integrated in a third surface of the object token 110, and a camera and/or optical mouse sensor 111, 111D integrated in the fourth surface of the object token 110. In some embodiments, the sensors 111 may conform to the shape

and/or size of the object token 110. For example, the capacitive sensor 111, 111A may be curved and integrated within a wheel of the object token 110, which may interface with a palm of the user when grabbing the object token 110. In another example, the electronic switch 111, 111B may be integrated in above a passenger compartment of the object token 110 so that the user may easily reach and press down the switch when moving the object token 110. Although the illustrated object token 110 of FIG. 7B includes four sensors 111, as discussed herein, the object token 110 may include any suitable number of sensors 111 and/or any suitable type of sensors 111 for detecting movement of the object token 110 and/or if the movement is intentional.

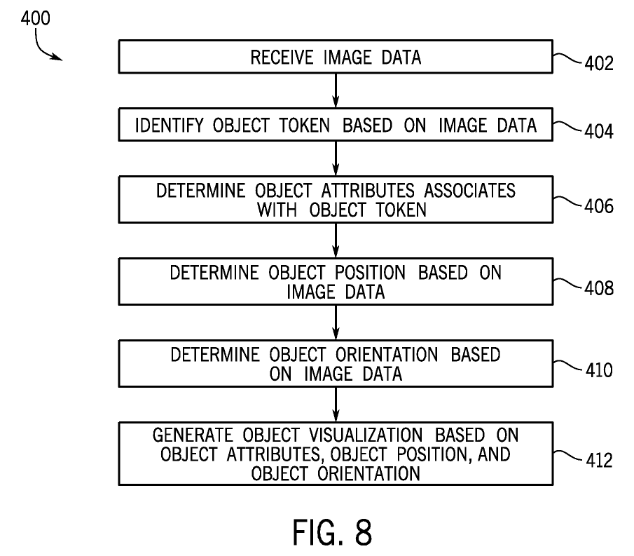

With the foregoing in mind, FIG. 8 illustrates a flowchart of a process 400 for operating the tangible/virtual design system 100 of FIG. 1, in accordance with an embodiment of the present disclosure. While the process is described as being performed by the automation controller 102, it should be understood that the process 400 may be performed by any suitable device or processing circuitry, such as the processor 104 and so forth, that may control and/or communicate with components of a tangible/virtual design system 100. Furthermore, while the process 400 is described using steps in a specific sequence, it should be understood that the present disclosure contemplates that the described steps may be performed in different sequences than the sequence illustrated, and certain described steps may be skipped or not performed altogether. In some embodiments, the process 400 may be implemented by executing instructions stored in a tangible, non-transitory, computer-readable medium, such as the memory 106, using any suitable processing circuitry, such as the processor 104.

At block 402, the automation controller 102 receives image data via the image sensors 120. The image sensors 120 may detect one or more object tokens 110 on the display surface 108 and may capture the image data based on the detection. In some embodiments, the image sensors 120 may detect the image data in the form of trackers 330 and/or machine-readable indicia 332 displayed on the object tokens 110. At block 404, the automation controller 102 may identify the object tokens 110 based on the image data. The automation controller 102 may process the image data to detect the trackers 330 and/or machine-readable indicia 332. In some embodiments, the automation controller 102 may scan the machine-readable indicia 332 to identify a corresponding object (e.g., building, ride vehicle, ride path, guest, scenery, and the

like). The automation controller 102 may also determine a configuration of the trackers 330 displayed on a surface of the object token 110. Each object token 110 may have a unique configuration of trackers that may be mapped to a corresponding object stored in a database, such as the memory 106. As such, the configuration of the trackers 330 may serve as an identifier of the object token 110.

The automation controller 102 may determine attributes (block 406) associated with the identified object token 110. For example, the automation controller 102 may retrieve physical attributes (e.g., size, color, texture, material, and the like) for the identified object token. For instance, the object token 110 may correspond to a ride vehicle. The automation controller 102 may receive and/or retrieve attributes of the ride vehicle, such as a design, a shape, a color, a size, a number of seats, a number of wheels, restraints, a presence of one or more riders, a number of riders, and so forth.

The automation controller 102 may also determine position data (block 408) for the object token 110 based on the image data. For example, the automation controller 102 may determine a position of the object token 110 on the display surface 108. The automation controller 102 may also determine a position of the object token 110 relative to one or more other object tokens 110, one or more visualization tools 112, and/or one or more effect tiles 114 on the display surface 108. At block 410, the automation controller 102 may determine orientation data for the object token 110 based on the image data. For example, the automation controller 102 may determine an orientation of the trackers 330 displayed on a surface of the object token 110. The automation controller 102 may determine the trackers are located on a front surface, a top surface, a rear surface, a bottom surface, a side surface, and so forth of the object token 110. Accordingly, the automation controller 102 may utilize the orientation of the trackers 330 to generate orientation data for the object token 110.

The automation controller 102 may generate (block 412) object visualization 116 based at least in part on the object attributes, position data, and/or the orientation data. For example, the automation controller 102 may determine if a ride vehicle object token 110 is oriented with a top surface facing upwards towards the image sensors 120 and/or the projectors 122. As such, the automation controller 102 may instruct the projectors 122 to project image content that includes a visualization of the top surface of the ride vehicle onto the object token 110 and/or the display surface

108. As discussed herein, the automation controller 102 may update and/or adjust the object visualization 116 in response to receiving an indication from a sensor 111 on or partially integrated with an object token 110 that movement of the object token 110 was intentional. Accordingly, the tangible/virtual design system 100 may provide visualizations to accurately represent features and aspects of an amusement park attraction or experience.

FIG. 9 is a perspective diagram of the tangible/virtual design system 100 tracking movement of a user 450, in accordance with an embodiment of the present disclosure. The image sensors 120 may generate image data of the display surface 108, the object tokens 110, the visualization tools 112, and/or the effect tiles 114 as well as of the user 450. For example, the image data may be indicative of the user 450 interacting with any of the components on the display surface 108.

The automation controller 102 may use, for example, a skeletal tracking system to determine identify and/or determine movement of the user 450. In one embodiment, the user 450 may be tracked based on one or more tags 452 coupled to clothing of the user 450. The tags 452 may be active devices, such as light emitting diodes, that send an indication to the automation controller 102, or passive devices, such as retroreflectors. The automation controller 102 may track movement of the user 450 based on movement of the one or more tags 452. In another embodiment, the automation controller 102 may track the user 450 based on positions and/or orientations of body parts. For example, the automation controller 102 may identify a position and/or an orientation of shoulders, elbows, knees, hands, and the like, of the user 450. The automation controller 102 may identify hand movements and/or hand gestures of the user 450 to determine if the user 450 may be interacting with one or more object tokens 110. In certain instances, the automation controller 102 may limit tracking to a portion of the user 450, such as an upper body of the user 450, to reduce processing time and/or processing power. Moreover, reducing a number of body parts being tracked may decrease latency and/or improve operation of the tangible/virtual design system 100.

FIG. 10 is a flowchart of a process 480 for operating the tangible/virtual design system 100 of FIG. 1, in accordance with an embodiment of the present disclosure. While the process is described as being performed by the automation

controller 102, it should be understood that the process 480 may be performed by any suitable device or processing circuitry, such as the processor 104 and so forth, that may control and/or communicate with components of a tangible/virtual design system. Furthermore, while the process 480 is described using steps in a specific sequence, it should be understood that the present disclosure contemplates that the described steps may be performed in different sequences than the sequence illustrated, and certain described steps may be skipped or not performed altogether. In some embodiments, the process 480 may be implemented by executing instructions stored in a tangible, non-transitory, computer-readable medium, such as the memory 106, using any suitable processing circuitry, such as the processor 104.

At block 482, the automation controller 102 receives image data indicative of one or more object tokens 110 and/or one or more users 450. For example, the automation controller 102 may receive image data from the image sensors 120 indicative of the display surface 108, the object tokens 110, the effect tiles 114, the visualization tools 112, and/or the users 450. In some embodiments, the automation controller 102 may use image analysis techniques, a machine learning algorithm, and/or an artificial intelligence algorithm to identify and/or track each of the components within the tangible/virtual design system 100. For example, the automation controller 102 may identify a type of object token 110 based on a machine-readable indicia 332 and/or identify a position and/or orientation of the object token 110 based on the trackers 330. In another example, the automation controller 102 may track body parts of the user 450 to determine if the user 450 is moving one or more object tokens 110.

At block 484, the automation controller 102 receives an indication of an object token 110 of the one or more object tokens 110 being moved. For example, the automation controller 102 may receive an indication from a sensor 111 on or partially integrated within an object token 110 of movement. In another example, the automation controller 102 may determine that the object token 110 is being moved based on the image data.

At determination block 486, the automation controller 102 determines if the movement of the object token 110 is intentional. For example, the automation controller 102 may determine if a status of the object token 110 is active or inactive to determine if the movement is intentional. In another example, the automation controller

102 may receive one or more indications from one or more sensors 111 of the object token 110 for determining whether the movement is intentional. Still in another example, the automation controller 102 may use the image data, the indication from the sensor 111, the status of the object token 110, and so on to determine if the movement is intentional.

If the movement of the object token 110 is intentional, then at block 488, the automation controller 102 updates the object visualization 116 based on a position and/or an orientation of the object token 110. The automation controller 102 may determine a position and/or orientation change of the object token 110 based on one or more trackers 330 exposed on a surface of the object token 110 within the image data. The automation controller 102 may update the position and/or orientation of the corresponding object visualization 116 based on a relationship between the position and/or orientation of the object token 110 and the position and/or orientation of the object visualization 116. That is, the automation controller 102 may update the position and/or orientation of the object visualization 116 based on the position and/or orientation of the object token 110.

If the movement of the object token 110 is not intentional, the automation controller 102 may return to block 482 to receive image data indicative of the one or more object tokens 110 and/or the one or more users 450. For example, the automation controller 102 may not receive an indication (e.g., a sensor signal) from sensors 111 on and/or partially integrated with the object token 110 and determine the movement identified in the image data to not be intentional. As such, the automation controller 102 may not update the corresponding object visualization 116. The automation controller 102 may return to block 482 to receive image data indicative of the object tokens 110 and/or the users 450, block 484 to receive an indication of the object token 110 being moved, and determination block 486 to determine if the movement is intentional.

In certain instances, two or more object tokens 110 may be moved together as part of a group or a scene. The automation controller 102 may perform the process 480 to determine if movement of the two or more object tokens 110 is intentional and update the corresponding object visualizations 116 based on the determination. As

such, erroneous updates of object visualizations 116, such as a position and/or an orientation of the object visualization 116, may be reduced or eliminated.

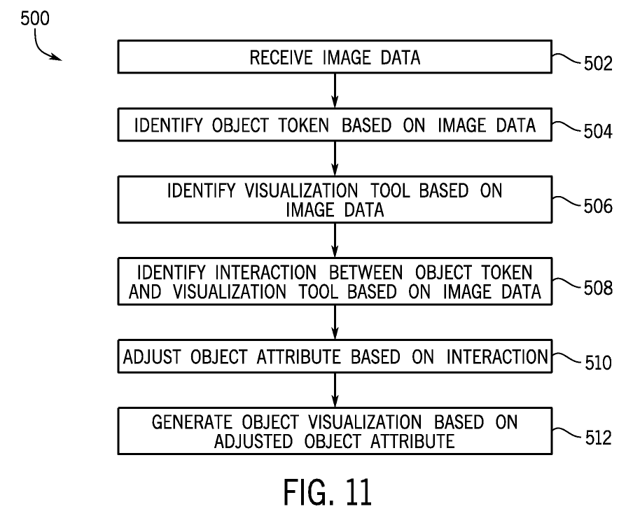

With the foregoing in mind, FIG. 11 illustrates a flowchart of a process 500 for operating the tangible/virtual design system 100 of FIG. 1, in accordance with an embodiment of the present disclosure. While the process is described as being performed by the automation controller 102, it should be understood that the process 500 may be performed by any suitable device or processing circuitry, such as the processor 104 and so forth, that may control and/or communicate with components of a tangible/virtual design system. Furthermore, while the process 500 is described using steps in a specific sequence, it should be understood that the present disclosure contemplates that the described steps may be performed in different sequences than the sequence illustrated, and certain described steps may be skipped or not performed altogether. In some embodiments, the process 500 may be implemented by executing instructions stored in a tangible, non-transitory, computer-readable medium, such as the memory 106, using any suitable processing circuitry, such as the processor 104.

At block 502, the automation controller 102 receives image data via the image sensors 120. The image sensors 120 may detect one or more object tokens 110, one or more visualization tools 112, and one or more effect tiles 114 on the display surface 108 and may capture the image data based on the detection. In some embodiments, the image sensors 120 may detect trackers 330 and/or machine-readable indicia 332 displayed on the object tokens 110, the visualization tools 112, and the effect tiles 114. At block 504, the automation controller 102 may identify the object tokens 110 based on the image data. The automation controller 102 may process the image data to detect the trackers 330 and/or machine-readable indicia 332. In some embodiments, the automation controller 102 may scan the machine-readable indicia 332 to identify a corresponding object (e.g., building, ride vehicle, ride path, guest, scenery, and the like). The automation controller 102 may also determine a configuration of the trackers 330 displayed on a surface of the object token 110. Each object token 110 may have a unique configuration of trackers 330 that may be mapped to a corresponding object stored in a database, such as the memory 106. As such, the configuration of the trackers 330 may serve as an identifier of the object token 110.

At block 506, the automation controller 102 may identify the visualization tools 112 based on the image data. The automation controller 102 may process the image data to detect markers and/or machine-readable indicia displayed on a surface of the visualization tools 112. In some embodiments, the automation controller 102 may control the image sensors 120 to scan the machine-readable indicia to identify a corresponding visualization tool 112 (e.g., a paintbrush tool, a texture tool, a material tool, a magnifying tool, a measurement tool, a filter tool, and the like). The automation controller 102 may also determine a configuration of the trackers displayed on the surface of the visualization tool 112. Each visualization tool may have a unique configuration of trackers that may be mapped to a corresponding visualization tool stored in a database, such as the memory 106. As such, the configuration of the trackers may server as an identifier of the visualization tool 112.

At block 508, the automation controller 102 may identify an interaction between the object token 110 and the visualization tool 112 based on the image data. The automation controller 102 may process the image data to determine position data and/or orientation data for the object tokens 110 and/or the visualization tools 112. The automation controller 102 may utilize the position data and/or the orientation data to determine the visualization tool 112 satisfies interaction criteria (e.g., within a threshold distance from the object token 110, in contact with the object token 110) based on the image data.

The automation controller may adjust (block 510) one or more attributes of the object token 110 based on the identified interaction. For example, the visualization tool 112 may correspond to a material tool that updates a material attribute, a texture attribute, a color attribute, and so forth for the object token 110. The automation controller 102 may store the adjusted attributes in the memory 106. At block 512, the automation controller 102 may generate object visualization 116 for the object token 110 based on the adjusted object attributes and may control the projector 122 to project image content based on the adjusted object attributes. As such, the tangible/virtual design system 100 may generate and/or adjust object visualizations 116 to reflect interactions between the object tokens 110 and various visualization tools 112.

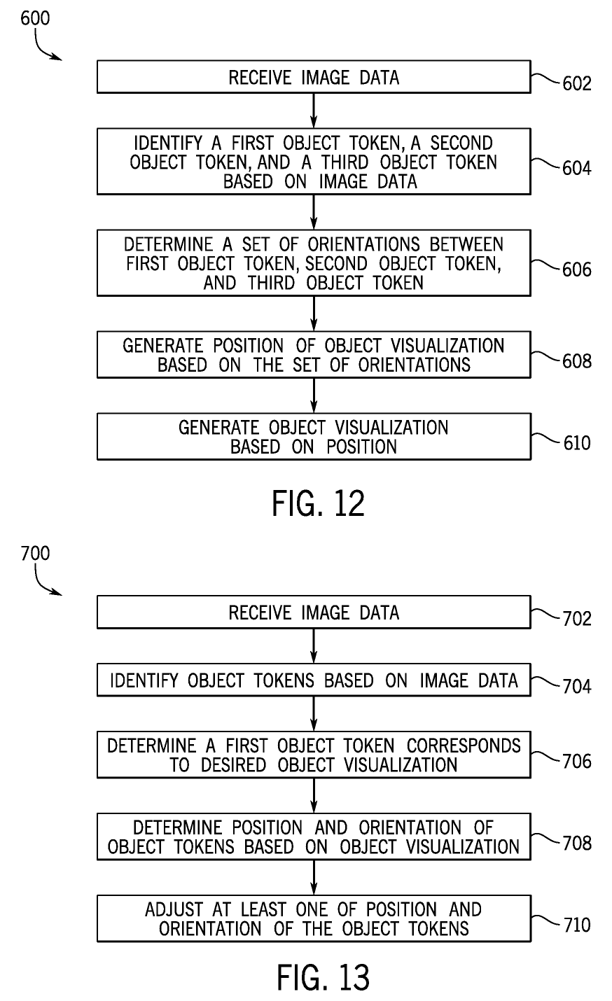

With the foregoing in mind, FIG. 12 illustrates a flowchart of a process 600 for operating the tangible/virtual design system 100 of FIG. 1, in accordance with an

embodiment of the present disclosure. While the process is described as being performed by the automation controller 102, it should be understood that the process 600 may be performed by any suitable device or processing circuitry, such as the processor 104 and so forth, that may control and/or communicate with components of a tangible/virtual design system. Furthermore, while the process 600 is described using steps in a specific sequence, it should be understood that the present disclosure contemplates that the described steps may be performed in different sequences than the sequence illustrated, and certain described steps may be skipped or not performed altogether. In some embodiments, the process 600 may be implemented by executing instructions stored in a tangible, non-transitory, computer-readable medium, such as the memory 106, using any suitable processing circuitry, such as the processor 104.

At block 602, the automation controller 102 receives image data via the image sensors 120. The image sensors 120 may detect one or more object tokens 110, one or more visualization tools 112, and one or more effect tiles 114 on the display surface 108 and may capture the image data based on the detection. In some embodiments, the image sensors 120 may detect trackers 330 and/or machine-readable indicia 332 displayed on the object tokens 110, the visualization tools 112, and the effect tiles 114. At block 604, the automation controller 102 may identify multiple object tokens 110 based on the image data, such as the first object token 110, 110A, the second object token 110, 110B, and the third object token 110, 110C. The automation controller 102 may process the image data to detect the trackers 330 and/or machine-readable indicia 332. In some embodiments, the automation controller 102 may scan the machine-readable indicia 332 to identify a corresponding object (e.g., building, ride vehicle, ride path, guest, scenery, and the like). The automation controller 102 may also determine a configuration of the trackers 330 displayed on a surface of the object token 110. Each object token 110 may have a unique configuration of trackers that may be mapped to a corresponding object stored in a database, such as the memory 106. As such, the configuration of the trackers may serve as an identifier of the object token 110.

At block 606, the automation controller 102 may generate position data and/or orientation data for one or more of the object tokens 110. In some embodiments, the automation controller 102 may determine distances between the object tokens 110

and angles between the object tokens 110. The automation controller 102 may generate (block 608) visualization position data and/or visualization orientation data for an object visualization 116 based on the image data. For example, as shown in FIG. 3, position data and/or orientation data for the first object token 110, 110A and the second object token 110, 110B may be utilized to determine visualization position data and/or visualization orientation data for the object visualization 116. The visualization position data may include a relative position of the object visualization 116 to one or more object tokens 110 and/or an absolute position of the object visualization 116 on the display surface 108. The visualization orientation data may include a relative orientation of the object visualization 116 to one or more object tokens 110 and/or an absolute orientation relative to the display surface 108.

At block 610, the automation controller 102 may generate the object visualization 116 based at least in part on the visualization position data, visualization orientation data, the identified object tokens 110, or any combination thereof. The automation controller 102 may detect the first object token 110, 110A and may identify the first object token 110, 110A corresponds to projected imagery. The automation controller 102 may receive image content based on the identified first object token 110, 110A and may instruct the projector 122 to project the object visualization 116 that includes reflected imagery. As such, the tangible/virtual design system 100 may provide for display of visual effects and representations of illusions, such as Pepper’s Ghost.

With the foregoing in mind, FIG. 13 illustrates a flowchart of a process 700 for operating the tangible/virtual design system 100 of FIG. 1, in accordance with an embodiment of the present disclosure. While the process is described as being performed by the automation controller 102, it should be understood that the process 700 may be performed by any suitable device or processing circuitry, such as the processor 104 and so forth, that may control and/or communicate with components of a tangible/virtual design system. Furthermore, while the process 700 is described using steps in a specific sequence, it should be understood that the present disclosure contemplates that the described steps may be performed in different sequences than the sequence illustrated, and certain described steps may be skipped or not performed altogether. In some embodiments, the process 700 may be implemented by executing

instructions stored in a tangible, non-transitory, computer-readable medium, such as the memory 106, using any suitable processing circuitry, such as the processor 104.

At block 702, the automation controller 102 receives image data via the image sensors 120. The image sensors 120 may detect one or more object tokens 110, one or more visualization tools 112, and one or more effect tiles 114 on the display surface 108 and may capture the image data based on the detection. In some embodiments, the image sensors 120 may detect trackers and/or machine-readable indicia displayed on the object tokens 110, the visualization tools 112, and the effect tiles 114. At block 704, the automation controller 102 may identify the object tokens 110 based on the image data. The automation controller 102 may process the image data to detect the trackers 330 and/or machine-readable indicia 332. In some embodiments, the automation controller 102 may scan the machine-readable indicia 332 to identify a corresponding object (e.g., building, ride vehicle, ride path, guest, scenery, and the like). The automation controller 102 may also determine a configuration of the trackers displayed on a surface of the object token 110. Each object token 110 may have a unique configuration of trackers 330 that may be mapped to a corresponding object stored in a database, such as the memory 106. As such, the configuration of the trackers 330 may serve as an identifier of the object token 110.

At block 706, the automation controller 102 may determine at least one of the object tokens 110 corresponds to a location and/or orientation for an object visualization 116. For example, the object token 110 may correspond to a location and/or orientation of reflected imagery for a Pepper’s Ghost illusion. The automation controller 102 may determine (block 708) location data (e.g., position data and/or orientation data) for any number of object tokens 110 based on the location and/or orientation of the reflected imagery. For example, the automation controller 102 may determine position data and/or orientation data for a reflective material object token and/or a projected imagery object token to facilitate design of the illusion.

At block 710, the automation controller 102 may adjust the position and/or the orientation of the reflective material object token and/or the projected imagery object token based on the position data and/or the orientation data. The automation controller 102 may instruct actuators of the display surface 108 and/or the object tokens 110 to move the object tokens to the adjusted position and/or the adjusted orientation.

Additionally or alternatively, the automation controller 102 may instruct the projectors 122 to project markers or indicators on the display surface 108 that correspond to the adjusted positions and/or adjusted orientations.

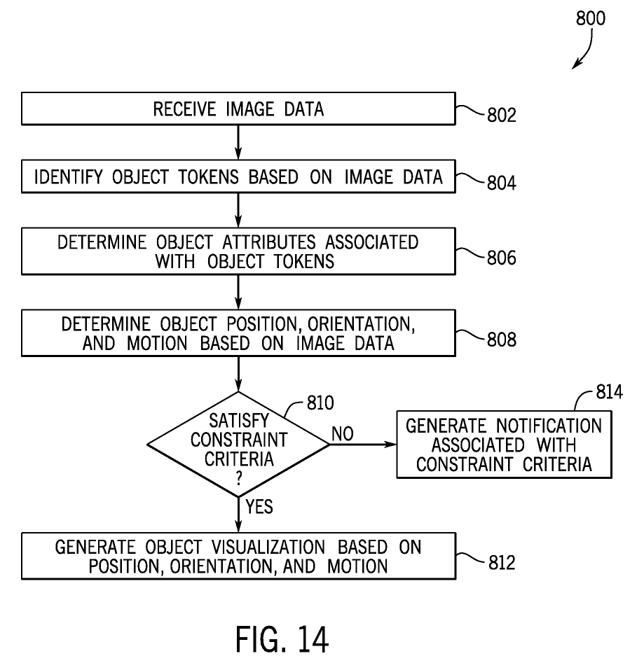

With the foregoing in mind, FIG. 14 illustrates a flowchart of a process 800 for operating the tangible/virtual design system 100 of FIG. 1, in accordance with an embodiment of the present disclosure. While the process is described as being performed by the automation controller 102, it should be understood that the process 800 may be performed by any suitable device or processing circuitry, such as the processor 104 and so forth, that may control and/or communicate with components of a tangible/virtual design system. Furthermore, while the process 800 is described using steps in a specific sequence, it should be understood that the present disclosure contemplates that the described steps may be performed in different sequences than the sequence illustrated, and certain described steps may be skipped or not performed altogether. In some embodiments, the process 800 may be implemented by executing instructions stored in a tangible, non-transitory, computer-readable medium, such as the memory 106, using any suitable processing circuitry, such as the processor 104.

At block 802, the automation controller 102 receives image data via the image sensors 120. The image sensors 120 may detect one or more object tokens 110, one or more visualization tools 112, and one or more effect tiles 114 on the display surface 108 and may capture the image data based on the detection. In some embodiments, the image sensors 120 may detect trackers and/or machine-readable indicia displayed on the object tokens 110, the visualization tools 112, and the effect tiles 114. At block 804, the automation controller 102 may identify the object tokens 110 based on the image data. The automation controller 102 may process the image data to detect the markers and/or machine-readable indicia. In some embodiments, the automation controller 102 may scan the machine-readable indicia to identify a corresponding object (e.g., building, ride vehicle, ride path, guest, scenery, and the like). The automation controller 102 may also determine a configuration of the trackers displayed on a surface of the object token 110. Each object token 110 may have a unique configuration of trackers 330 that may be mapped to a corresponding object stored in a database, such as the memory 106. As such, the configuration of the trackers may serve as an identifier of the object token 110.

The automation controller 102 may determine attributes (block 806) associated with the identified object tokens 110. For example, the automation controller 102 may retrieve physical attributes (e.g., size, color, texture, material, and the like) for the identified object token. For instance, the object token 110 may correspond to a ride vehicle. The automation controller 102 may receive and/or retrieve attributes of the ride vehicle, such as a design, a shape, a color, a size, a number of seats, a number of wheels, restraints, and so forth. At block 808, the automation controller 102 may generate position data and/or orientation data for one or more of the object tokens 110. In some embodiments, the automation controller 102 may determine distances and orientations between the object tokens 110, the visualization tools 112, and the effect tiles 114. Additionally or alternatively, the automation controller 102 may determine a speed or a velocity associated with the object tokens 110, the visualization tools 112, and the effect tiles 114. In some embodiments, the movement of the object tokens 110 may be scaled relative to a full-scale model. For example, a guest object token may move at a fraction of the speed (e.g., one fifth, one tenth, one twentieth, and so forth) of an actual guest of the amusement park attraction or experience, a ride vehicle object token may move at a fraction of the speed of a full-size ride vehicle, the ride vehicle object token may move a fraction of the distance of the full-size ride vehicle, and so forth.

At block 810, the automation controller 102 may determine whether any of the object tokens satisfy at least one constraint criteria. For example, the constraint criteria may include a maximum speed criteria for a ride vehicle. The automation controller 102 may compare the determined speed of the ride vehicle object token with the maximum speed criteria. If the determined speed exceeds the maximum speed criteria (NO path of block 810), the automation controller 102 may generate (block 814) a notification based on the failed constraint criteria and may instruct the projector 122 and/or the display 126 to display the notification. If the determined speed falls within the maximum speed criteria (YES path of block 810), the automation controller 102 may generate and/or adjust (block 812) the object visualization 116 based on the movement of the object token 110.

FIGS. 15A-15D are schematic diagrams that illustrate an example embodiment of visualization tools 112 of the tangible/virtual design system 100 of FIG.

1. The visualization tool 112 may include one or more trackers and/or machine-readable indicia positioned on one or more surfaces that may be captured by the image sensor 120. As such, the automation controller 102 may identify a type of the visualization tool 112 based on the one or more trackers and/or machine-readable indicia in the image data. Moreover, the automation controller 102 may identify interactions between the visualization tool 112 and the object token 110 and control the projectors 122 to update the object visualization 116 based on the interactions. For example, interactions may cause object attributes (e.g., color, material, texture) to be updated or measured (e.g., length, width, angle, angular motion, brightness, sound volume, temperature).

With the foregoing in mind, FIG. 15A is a schematic diagram illustrating an example embodiment of the visualization tool 112 of the tangible/virtual design system 100 of FIG. 1 as a paintbrush tool 112, 112A. As illustrated, the paintbrush tool 112, 112A includes trackers 850, which includes two dots configured in a line. The automation controller 102 may identify the paintbrush tool 112, 112A by comparing the configuration of the trackers 850 to stored tracker configurations in the memory 106. In certain instances, the automation controller 102 may use the trackers 850 and image processing techniques to identify the paintbrush tool 112, 112A.

The paintbrush tool 112, 112A may update one or more object attributes of the object token 110. In particular, a user may move the paintbrush tool 112, 112A to be disposed adjacent and/or come into contact with an object token 110. The automation controller 102 may determine the visualization tool 112 corresponds to a paintbrush tool 112, 112A that adjusts a color attribute for the object token 110. The automation controller 102 may retrieve and/or update the color attribute for the object token 110 and may control the projectors 122 to display the object visualizations 116 based on the adjusted color attribute. For example, a user may select the color attribute (e.g., via the GUI or an input on the paintbrush tool 112, 112A) to be applied by the paintbrush tool 112, 112A, or the paintbrush tool 112, 112A may be associated with the color attribute. Causing the paintbrush tool 112, 112A to be disposed adjacent and/or come into contact with an object token 110 may cause the projectors 122 to project an image having a color of the color attribute onto the object token 110, such that the object token 110 appears to be that color. In another example, the paintbrush tool 112, 112A

may adjust a texture attribute, a material attribute, and any other suitable visual attribute of the object token 110. As such, the automation controller 102 may generate and/or adjust image content (e.g., the object visualizations 116) displayed by the projectors 122 based on tracker data, scanning data, and/or the interaction criteria.

With the foregoing in mind, FIG. 15B is a schematic diagram illustrating an example embodiment of the visualization tool 112 of the tangible/virtual design system 100 of FIG. 1 as a magnifying tool 112, 112B. As illustrated, the magnifying tool 112, 112B includes trackers 850, which includes three dots on a lateral edge of the magnifying tool 112, 112B. The automation controller 102 may determine a configuration of the trackers 850 on the visualization tool 112 and compare the configuration with stored tracker configurations in the memory 106 to identify the magnifying tool 112, 112B.

The magnifying tool 112B may adjust a point of view of the object token 110 and/or a portion of the tangible/virtual design system 100, such as the image content 204 viewed by the user via the projector 122 and/or the display 126. For example, the user may want a close-up or zoomed-in view of a 10 centimeter (cm) by 10 cm area on the display surface 108 and point the magnifying tool 112, 112B in the direction of the area and/or hover the magnifying tool 112, 112B over the area. The automation controller 102 may determine a location of the magnifying tool 112, 112B and may control the projectors 122 and/or the display 126 to display a close-up view of the 10 cm by 10 cm area. In another example, the user may want a bird’s eye view (e.g., top perspective view) of the object token 110 and hover the magnifying tool 112, 112B over the object token 110. The automation controller 102 may identify the interaction between the magnifying tool 112, 112B and the object token 110 and may control the projectors 122 and/or the display 126 to display the bird’s eye view of the object token 110. In certain instances, the user may move the magnifying tool 112, 112B for a side perspective view of the object token 110 and the automation controller 102 may control the projectors 122 to update the projections to the side perspective view and/or the display 126 to update the displayed image content 204 to the side perspective view. In this way, the user may adjust a position or orientation of the magnifying tool 112, 112B to adjust a perspective view of the object token 110 (e.g., as projected by the projectors 122 or display 126).

With the foregoing in mind, FIG. 15C is a schematic diagram illustrating an example embodiment of the visualization tool 112 of the tangible/virtual design system 100 of FIG. 1 as an angle-measuring tool 112, 112C. The angle-measuring tool 112, 112C may include machine-readable indicia 852 (e.g., barcode, QR code, RF tag) on an exposed surface. The image sensor 120 may generate image data including the machine-readable indicia 852 and the automation controller 102 may identify the corresponding visualization tool based on the image data.

The angle-measuring tool 112, 112C may measure angles within the tangible/virtual design system 100. As illustrated, the angle-measuring tool 112, 112C includes a first wing 854, 854A, a second wing 854, 854B, and a hinge 856 between the two wings 854. To extend a length of the first wing 854, 854A and the second wing 854B, one or more laser-emitting devices (e.g., laser pointers) may be integrated along one or more longitudinal edges of the wings 854. In this way, light 860 from the laser-emitting devices may emit from the first wing 854A and the second wing 854, 854B, respectively. To measure the angle (e.g., between object tokens 110, structures on the display surface 108 representing, for example, buildings, or other structures), the first wing 854, 854A may align with a first point (e.g., a first object token 110, 110A) and the second wing 854, 854B may align with a second point (e.g., a second object token 110, 110B). In certain instances, the light 860 may be emitted from the first wing 854, 854A, the second wing 854, 854B, or both and intersect with the object tokens 110. The image sensor 120 may capture image data of the angle-measuring tool 112, 112C, including the first wing 854, 854A, the second wing 854, 854B, and the hinge 856, as well as the first object token 110 and the second object token 110. The automation controller 102 may receive the image data and determine the angle 858 between the first wing 854, 854A and the second wing 854, 854B, thereby determining the angle between the first point and second point. By way of example, the angle-measuring tool 112, 112C may determine an angle between an object visualization 116 and a wall of the tangible/virtual design system 100. The first wing 854, 854A may align with a corresponding object token 110 and the second wing 854, 854B may align with a second object token 110. The automation controller 102 may receive indication of this interaction and determine the angle 858 between the object visualization 116 and the wall.

In another example, the angle-measuring tool 112, 112C may be used to detect angular motion of the object token 110 and/or corresponding object visualization 116. In other examples, the angle-measuring tool 112, 112C may be used to determine a surface area of the object token 110. Still in another example, the angle-measuring tool 112, 112C may determine an amount and/or an angle of light within the tangible/virtual design system 100. For example, the angle-measuring tool 112, 112C may measure light from a first direction. Indeed, the first wing 854, 854A may point to a direction of incoming light and the second wing 854, 854B may point to a direction of reference or observation to measure ambient light in the direction of reference or observation within the tangible/virtual design system 100. Additionally or alternatively, the angle-measuring tool 112, 112C may measure light within the angle 858 between the first wing 854, 854A and the second wing 854, 854B.

With the foregoing in mind, FIG. 15D is a schematic diagram illustrating an example embodiment of the visualization tool 112 of the tangible/virtual design system 100 of FIG. 1 as a ruler tool 112, 112D. As illustrated, the ruler tool 112, 112D may include machine-readable indicia 852 (e.g., barcode, QR code, RF tag) on an exposed surface and the automation controller 102 may receive sensor data including the machine-readable indicia 852 to identify the ruler tool 112, 112D.

The ruler tool 112, 112D may measure physical attributes of object visualizations 116, object tokens 110, and/or other structures within the tangible/virtual design system 100. For example, the ruler tool 112, 112D may interact with the object token 110 to cause the automation controller 102 to determine a physical attribute of a corresponding object visualization 116. In certain instances, a range of the ruler tool 112D may be extended for improved measurements. As such, a first end and a second end of the ruler tool 112, 112D may each include a laser-emitting device (e.g., a laser pointer) that generates (e.g., emits) a light 860 in a straight line. This may allow the range of the ruler tool 112, 112D to be extended beyond the length of the ruler tool 112, 112D.

The automation controller 102 to determine physical attributes of the object token 110. For example, the user may select a physical attribute (e.g., length, width, surface area) via the GUI and/or an input on the ruler tool 112, 112D to be determined. Interactions between the ruler tool 112, 112D and one or more object tokens 110 may

cause the automation controller 102 to determine the physical attribute associated with the object visualization 116 corresponding to the object token 110 and control the projectors 122 to project the physical attribute. For example, the automation controller 102 may determine a length of an edge of the object visualization 116 in response to the ruler tool 112, 112D being placed adjacent to an edge of the object token 110. In another example, the automation controller 102 may determine a distance between two object visualizations 116. For example, the ruler tool 112, 112D may be disposed between two object tokens 110 to cause the automation controller 102 to determine a distance between two corresponding object visualizations 116. In certain instances, a length of the ruler tool 112, 112D may not extend from the first object token 110, 110A to the second object token 110. As such, the light 860 may be emitted from a first end, a second end, or both to extend the length of the ruler tool 112, 112D. The light 860 emitting from the first end may intersect with the first object token 110, 110A and the light 860 emitting from the second end may intersect with the second object token 110, 110B. In this way, the user may visually confirm that the measurement may be between the first object token 110, 110A and the second object token 110, 110B. Additionally or alternatively, the automation controller 102 may receive image data indicative of the first object token 110, 110A the second object token 110, 110B, and the light 860 and determine the measurement in response to receiving the image data. For example, the first object token 110, 110A may correspond to a building and the second object token 110, 110B may correspond to a ride attraction. As such, the measurement determined by the automation controller 102 may correspond to a distance between the building and the ride attraction. Additionally or alternatively, the ruler tool 112, 112D may be utilized to get dimensions of rooms (e.g., a length and a width) within the tangible/virtual design system 100.

The visualization tool 112 may include one or more of the embodiments described with respect to FIGS. 15A-15D but not limited to other tools, such as pens, pencils, input devices (e.g., mice, displays), AR/VR control devices, laser pointers, presentation clickers, and/or any combination of the above. Any of the tool, object token, sensors, or other part of this system may include a control which may make determinations and/or send instructions. These controllers may be communicatively coupled to the automation controller 102, receivers, transceivers, and/or transmitters in order to send and/or receive instructions. Any controller and/or combination of

controllers from this disclosure may perform controller functions described in this disclosure.

With the foregoing in mind, FIG. 15E is a block diagram of an example embodiment of a visualization tool 112 of the tangible/virtual design system 100. The visualization tool 112 may include a first end 862 and a second end 864. The visualization tool 112 may also include identification information 866, such as images, text, colors, numbers, and/or patterns to provide identification information 866 to the user. For example, the identification information 866 may be used by the user to distinguish between each of the visualization tools 112 described above. Additionally or alternatively, the identification information 866 may be used by the system (e.g., automation controller 102) to identify the respective visualization tool 112. For example, the automation controller 102 may identify the visualization tool 112 based on the tracker 850. In another example, the automation controller 102 may identify the visualization tool 112 based on machine-readable indicia 852. The machine-readable indicia 852 may include QR codes, bar codes, RFID, light pulses, and the like. The automation controller 102 may identify the visualization tool 112 using sensors 853, such as RFID readers, QR readers, bar code readers, light detectors, cameras, etc. Additionally or alternatively, the visualization tool 112 may include sensor(s) 853, such as distance sensors (e.g., distance sensor that utilizes light (e.g., laser light) and/or sound), accelerometers, proximity sensors, LiDAR sensors, infrared sensors, ultraviolet sensors, and the like that may be used to identify the type of visualization tool 112, measure and/or track position and/or orientation of the visualization tool within the tangible/virtual design system 100 , and/or measure and/or identify parameters within tangible/virtual design system 100 (e.g., distance between two or more object tokens 110).

The visualization tool 112 may include input device(s) 868, such as buttons, touch screens, dials, touch pads, microphones, and the like. The visualization tool 112 may receive an input (e.g., from the user) and determine a type of visualization tool 112 and/or a parameter for measuring. For example, the user may select the type of visualization tool 112 using the input device(s) 868. In another example, gesture recognition may be used to adjust the parameters while the user is interacting with the visualization tool 112. For example, the automation controller 102 may receive sensor

data from the image sensors 120 and identify a gesture (e.g., motion) of the user, such as the user’s free hand while the user is interacting with the visualization tool 112. In some embodiments, the type of visualization tool 112 and/or the parameter for measuring may be set by default. The automation controller 102 may dynamically update the type of visualization tool 112 and/or a parameter being measured by the visualization tool 112. To this end, the visualization tool 112 may include output device(s) 870 such as light emitters (e.g., LEDs, lasers) and/or sound emitters. The visualization tool 112 may be dynamically updated from emitting light to emitting sound. Additionally or alternatively, the automation controller 102 may receive voice commands from the user. For example, the visualization tool 112 may generate audio recordings via the sensors 853, such as microphones, that may be partially integrated with and/or coupled to the visualization tool. In another example, the tangible/virtual design system 100 may include one or more voice input devices (e.g., microphones). As such, fewer steps may be performed by the user, which may improve efficiency of the tangible/virtual design system 100.

In an embodiment, the visualization tool 112 may include a brightness tool, a sound volume tool, a temperature tool, an odor tool, and/or other tool that measures a property of the object token 110 and a corresponding object visualization 116. In an instance, the brightness tool may interact with at least part of the object token 110 to cause the automation controller 102 to determine a brightness (e.g., luminance) level of the corresponding object visualization 116. For example, a first end 862 of the brightness tool may interact with an object token 110, 110A and a corresponding brightness value may be measured and/or determined. In addition, the brightness tool may measure a change in brightness levels from a first end 862 of the visualization tool and a second end 864 of the visualization tool. For example, the brightness tool may measure and/or determine a difference in brightness levels between brightness associated with the first object token 110, 110A and brightness associated with the second object token 110, 110B. For example, the brightness tool may measure and/or determine the brightness associated with at least part of the first object token 110, 110A located at, near, or in front of the first end 862 of the brightness tool, the brightness tool may measure and/or determine the brightness associated with at least part of the second object token 110, 110B, and then the brightness tool and/or the automation controller 102 may determine a difference in brightness associated between at least part of the

first object token 110, 110A and at least part of the second object token 110, 110B. Additionally or alternatively, the brightness tool may indicate to the automation controller 102 where (e.g., location relative to the location of the token indicated by the tool) to measure and/or determine the brightness levels associated with at least part (e.g., a portion, an end) of that token. The brightness tool may include a light emitting from the first end 862, the second end 864, or both to extend a range of the brightness tool. For example, light emitted from the first end may intersect with the first object token 110, 110A and light emitting from the second end 864 may intersect with the second object token 110, 110B. The brightness tool and/or the automation controller 102 may then determine and/or compare (e.g., determine difference between) an associated brightness with at least part of any object token 110 intersecting light emitted from either end of the brightness tool (e.g., at least part of the first object token 110, 110A intersecting light emitted from the first end 862 of the brightness tool and at least part of the second object token 110, 110B intersecting light emitted from the second end 864 of the brightness tool).

In another instance, the sound volume tool may interact with the object token 110 to cause the automation controller 102 to determine the sound volume at, near, and/or at least partially being output by a corresponding object visualization 116 and/or a change in the sound volume between two corresponding object visualizations 116. For example, the sound volume tool may measure and/or determine the sound volume levels associated with (e.g., occurring in the area of) and/or output at least partially by a first object token 110, 110A located at, near, or in front of the first end 862 of the sound volume tool. Additionally or alternatively, a second object token 110, 110B may be located at a second end 864 of the sound volume tool and the sound volume tool may determine a sound volume difference between the sound volume at, around, and/or output by the first object token 110, 110A and the second object token 110, 110B, or between the first end 862 and the second end 864 of the sound volume tool. Additionally or alternatively, the sound volume tool may indicate to the automation controller 102 where (e.g., location relative to the location of the token indicated by the tool) to measure and/or to determine the sound volume associated with at least part (e.g., a portion, an end) of that token. To extend a range of the sound volume tool, light may be emitted from the first end 862, the second end 864, or both. As such, the sound volume tool and/or the automation controller 102 may determine a

sound volume associated with at least part of any object token 110 intersecting light emitted from either end of the sound volume tool (e.g., at least part of the first object token 110, 110A intersecting light emitted from the first end 862 of the brightness tool) and/or measure and/or derive a sound volume difference between at least part of any two object tokens 110 intersecting light emitted from either end of the sound volume tool (e.g., at least part of the first object token 110, 110A intersecting light emitted from the first end 862 of the brightness tool and at least part of the second object token 110110B intersecting light emitted from the second end 864 of the brightness tool). The light may intersect with the object tokens 110 to provide a visual indication to the user of the measurement and/or determination being made.

Still in another instance, interactions between the temperature tool and an object token 110 may cause the automation controller 102 to determine a temperature of the corresponding object visualization 116. For example, the temperature tool may measure and/or determine the temperature associated with at least part of the first object token 110, 110A located at, near, or in front of the first end 862 of the temperature tool. In addition, the temperature tool may measure a temperature difference associated with at least the first object token 110, 110A located at a first end 862 of the temperature tool and associated with at least part of the second object token 110, 110B located at, near, or in front of the second end of the temperature tool and/or the automation controller 102 may determine a difference in temperature between a temperature associated with at least part of the first object token 110, 110A and a temperature associated with at least part of the second object token 110, 110B. Additionally or alternatively, the temperature tool may indicate to the automation controller 102 where (e.g., location relative to the location of the token indicated by the tool) to measure and/or determine the temperature associated with at least part (e.g., a portion, an end) of that token. Additionally or alternatively, a range of the temperature tool may be extended by a light emitted from the first end, the second end, or both. For example, the temperature tool and/or the automation controller 102 may determine a temperature associated with at least part of any object token 110 intersecting light emitted from either end of the temperature tool and/or compare (e.g., determine difference between) two or more temperatures associated with at least part of any two object tokens 110 intersecting light emitted from either end of the temperature tool.

In another instance, the odor tool may measure an odor level (e.g., odor intensity) of the corresponding object visualization 116. The odor tool may measure and/or determine the odor level associated with at least part of the first object token 110, 110A located at, near, or in front of the first end 862 of the odor tool. The odor tool and/or the automation controller 102 may determine a difference in odor levels associated with at least part of the first object token 110, 110A and at least part of the second object token 110, 110B located at, near, or in front of the second end of the odor tool. Additionally or alternatively, the odor tool may indicate to the automation controller 102 where (e.g., location relative to the location of the token indicated by the tool) to measure and/or determine the odor associated with at least part (e.g., a portion, an end) of that token. In certain instances, a length of the odor tool may be smaller than the distance between the first object token 110, 110A and the second object token 110, 110B. To this end, the range of the odor tool may be extended by a light emitting from the first end, the second end, or both. For example, the light emitting from the first end 862 may intersect with the first object token 110, 110A and/or the light emitting from the second end 864 may intersect with the second object token 110, 110B. The odor tool and/or the automation controller 102 may determine and/or compare an associated odor level with at least part of any object token 110 intersecting light emitted from either end of the odor tool. Additionally or alternatively, the odor tool may measure and/or determine an odor type (e.g., banana scent, rose scent, bread scent) associated with an object token 110. Certain features of certain visualization tools 112 may be combined with certain additional features of other visualization tools. For example, the range extension may be combined with the paintbrush tool 112, 112A such that light emitted from one end of the paintbrush tool may be pointed at an object token 110 to identify an object token for attribute (e.g., color, texture) changing instead of bringing the paintbrush tool 112, 112A close to or touching the object token 110. As such, the visualization tools 112 may provide a measurement and/or determination of physical attributes of the object token 110 and the corresponding object visualization. In this way, the tangible/virtual design system 100 may allow for efficient design and/or troubleshooting for amusement park attractions or experiences.

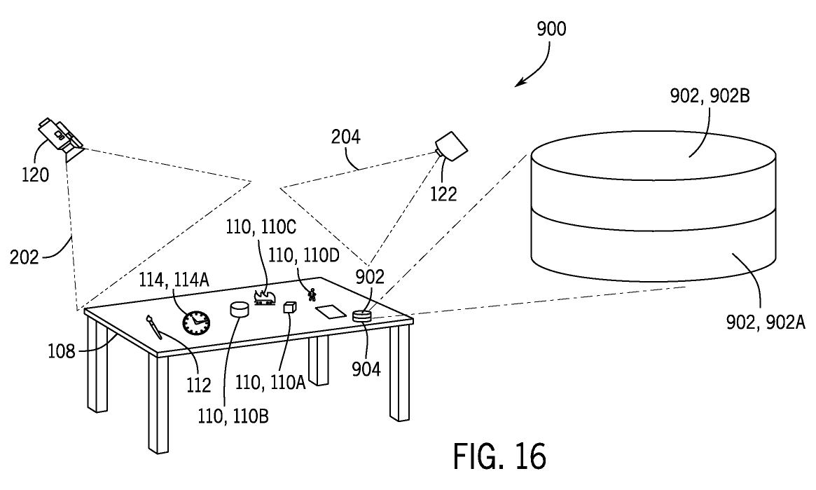

FIG. 16 is a perspective diagram that illustrates an example embodiment 900 of the tangible/virtual design system 100 in FIG. 1 including the display surface 108, the image sensor 120, and the projector 122, in accordance with an embodiment

of the present disclosure. The example embodiment 900 of the tangible/virtual design system 100 is similar to the example embodiment 200 of the tangible/virtual design system 100 described with respect to FIG. 2, with the addition of filter tools 902 (e.g., visualization tools 112 described with respect to FIG. 15A-E). The filter tools 902 may be utilized to provide a visual representation of one or more attributes of the object token 110. The filter tools 902 may include a cost filter, a brightness filter, a sound volume filter, a water usage filter, a viewing time filter, a sound level filter, a user input filter, and the like. The filter tool 902 may include markers and/or machine-readable indicia that may enable the automation controller 102 to detect the filter tool 902 based on image data captured by the image sensor 120. The automation controller 102 may detect the type of filter tool 902 based on the trackers and/or machine-readable indicia and update the object visualization 116 based on the type of filter tool 902. For example, the automation controller 102 may control the projectors 122 to generate an updated object visualization 116 for display. In this way, heuristic data of the object token 110 may be displayed by the projectors 122.

For example, the automation controller 102 may receive image data with a cost filter located on the display surface 108. The cost filter may be utilized to generate a cost associated with the object token 110 (e.g., portions of the object token 110). The automation controller 102 may retrieve a cost associated with the object token 110 from a data structure, such as a database, stored in the memory 106, and update the visualization of the object token 110 with the cost. For example, a color may be associated with each range of prices, such as red for a high price, yellow for medium price, and green for low price. In another example, a legend may be provided with a sliding scale for each price. In yet another example, the cost may be displayed in text next to the object token 110.

In another example, a brightness filter may be used to provide a visualization indicative of a surface brightness of the object token 110 and/or within a room. For example, the user may design a haunted house and may want to understand an amount of light hitting a scare mirror (e.g., a mirror that displays an illusion intended to scare a viewer). The automation controller 102 may generate combined imagery of both the object token 110 and an amount of light hitting surfaces of the scare mirror. In another example, a room may include one or more object tokens 110 representative of light

sources and the brightness filter may be set to a threshold amount (e.g., due to a brightness constraint, building code, amusement park code, or the like). The automation controller 102 may generate a visualization of the room illustrating brightness above and/or below the threshold amount. For example, the visualization of the room may include portions with a brightness below the threshold that may be shaded by a first color or pattern and portions of the room with a brightness above the threshold may be shaded by a second color or pattern.

Additionally or alternatively, the user may adjust the object tokens 110 to adjust the brightness within the visualization. For example, the automation controller 102 may update the visualization and/or the brightness calculation in response to identifying movement of the object tokens 110. Indeed, the updated visualization of the room may include portions of the room with a brightness below the threshold shaded by a first color or pattern and portions of the room with a brightness above the threshold shaded by a second color or pattern. In certain instances, the adjustment may result in visualization of the room shaded by one color or pattern, which may indicate that the brightness is below the threshold or above the threshold.

Additionally or alternatively, a sound volume filter may be used to provide visualization indicative of sound levels on a surface of the object visualization 116 and/or within visualization of a room. The sound volume filter may be set to a threshold amount (e.g., sound volume constraint, building code constraint). The automation controller 102 may generate a visualization of a room with one or more object visualizations 116 (e.g., corresponding to one or more identified object tokens 110) and illustrate sound volumes being above or below the threshold level. For example, the object tokens 110 may correspond to speakers and/or any suitable sound system. Based on a configuration of the object tokens 110, the automation controller 102 may determine the sound volume outputted by each of the corresponding objects and generate visualization of the room. Indeed, the visualization of the room may include portions with sound volumes below the threshold that may be shaded by a first color or pattern and portions with volumes above the threshold that may be shaded by a second color or pattern.

Moreover, the automation controller 102 may provide suggest configurations of the object tokens 110 to meet a constraint. In certain instances, the

filter tool 902 may receive input (e.g., via a GUI, via an input of the filter tool 902) of a constraint (e.g., brightness threshold, sound volume threshold, energy usage threshold). Returning to the brightness example, the user may use the GUI to set a brightness constraint of 30 lumens within the visualization of the room. The user may place two object tokens 110 corresponding to light sources on the display surface 108. The automation controller 102 may determine attributes (e.g., light output, position, orientation, configuration, location) of corresponding object visualizations 116 of the object tokens 110 to determine levels of brightness in different areas of the room. In response to determining the brightness may be below the threshold, the automation controller 102 may adjust a position and/or an orientation one or more object visualizations 116 to adjust the brightness within the room to achieve the brightness of 30 lumens at the position and/or orientations.

In another example, the filter tool 902 may include a physical property filter. The physical property filter may provide geometric properties of an object visualization 116, such as a height, a length, a width, a surface area, a volume, and the like. For example, the object visualization 116 may represent a rock and the physical property filter may be used to provide physical attributes of the rock, such as a material of the rock, a size of the rock, a weight of the rock, and the like. In another example, the object visualization 116 may represent a waterfall attraction and the physical property filter may be used to determine areas of calcium deposits due to running water over a period of time. Still in another example, the object visualization 116 may represent a building and the physical property filter may be used to determine wind loads on different portions of the building. In certain instances, the physical property filter may simulate guest throughput for an attraction, such as for a store, a ride, a restaurant, and the like. For example, when designing the amusement park, the physical property filter may be used to map a movement of guests in a crowd flow simulation. The object tokens 110 may correspond to object visualizations 116, such as store, restaurant, ride, or sidewalk, and addition of the physical property filter may cause the automation controller 102 to generate visualizations of guest movements to and from the object visualizations 116. For example, automation controller 102 may generate visualizations of guests walking on sidewalks during peak crowd flow periods to get to or leave from a store. Based on the visualization, the user may determine if a size of the sidewalk is wide enough to accommodate the guests.

Still in another example, the filter tool 902 may include a user input tool that causes the automation controller 102 to generate image data with the object visualization 116 and a tag (e.g., badges, notification, text label, color). The tag may indicate a most recent user to edit the object visualization 116, a date or time of the editing, a number of times of editing, and other suitable editing attributes of a project. For example, the object visualization 116 may be an animated figure that multiple users may have worked on. A head of the animated figure may be edited three times by one user. As such, the object visualization 116 may include a tag on the head indicating a name of the user and the number of times edited. In this way, the object visualization 116 may be accompanied by editor annotations associated with the project for reference.

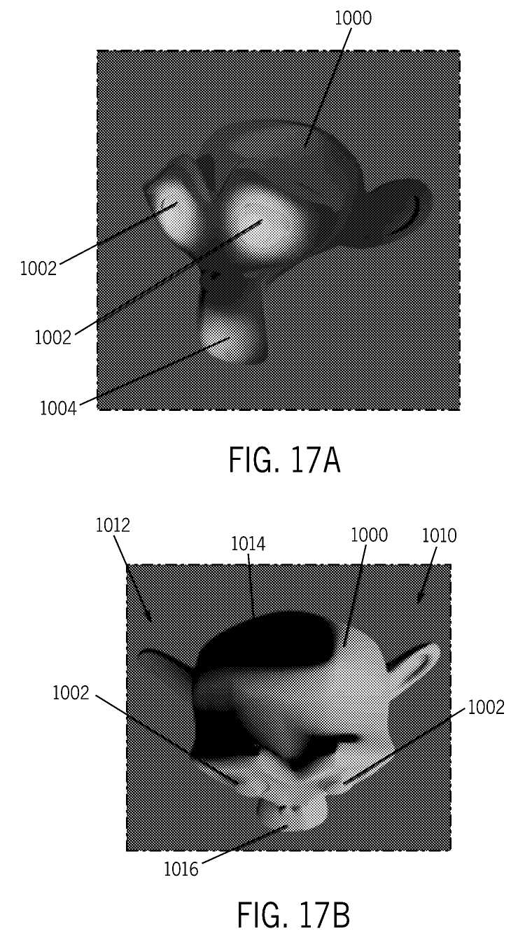

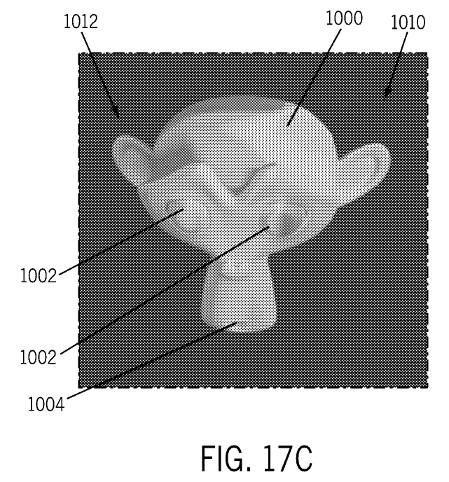

In another example, the filter tool 902 may include a viewing time filter. For example, certain portions of an object visualization 116 may be viewed more frequently by guests in comparison to other portions. For example, guests may only view a portion of an object, such as a figure, from a ride vehicle. The automation controller 102 may update the object visualization 116 to illustrate viewing time. As further described with respect to FIG. 17B, the object visualization 116 may be updated with a color gradient to illustrate the viewing time. For example, portions of the object visualization 116 may be shaded with a first color or pattern to illustrate high viewing time and other portions of the object visualization 116 may be shaded with a second color or pattern to illustrate low viewing time.

The filter tools 902 may be placed in a designated area 904 of the display surface 108. For example, the designated area 904 may be a corner of the display surface 108, however the designated area 904 may be any suitable area on the display surface 108. The image sensor 120 may generate image data including the filter tools 902 in the designated area 904 and the automation controller 102 may control the projectors 122 to update the object visualizations 116 based on the filter tools 902. In certain instances, two or more filter tools 902 may be utilized to display a relationship between properties of the filter tools 902. For example, a cost filter may be combined with or stacked on a viewing time filter, and the resulting projection mapping may indicate a relationship between the cost associated with building and/or maintaining the object visualization 116 divided by viewing time by the guest. In another example, a

brightness filter may be combined with or stacked on the cost filter and the resulting projection mapping may indicate a relationship between brightness within a room and the cost associated with generating the brightness. Additionally or alternatively, the object tokens 110 may be moved or shifted within the tangible/virtual design system 100 and the automation controller 102 may update the object visualization 116 in real time or near real time based on the filter tools 902 applied. For example, object tokens 110 may correspond to one or more light sources within an attraction. The automation controller 102 may determine an operation cost associated with each light source as well as the brightness (e.g., luminous flux, luminance) of each light source and control the projectors 122 to project the visualization. The user may adjust a configuration of the light sources (e.g., by moving one or more object tokens 110) and the automation controller 102 may update the visualization based on the adjusted configuration. For example, adjust the position of one light source may cause the overall brightness to change and/or an operation cost to change.

With the foregoing in mind, FIGS. 17A, 17B, and 17C illustrate embodiments of projection mapping by the tangible/virtual design system 100 of FIG. 1. For example, the user may place two object tokens 110 on the display surface 108 for projection mapping. The first object token 110 may correspond to an animated FIG. 1000 and the second object token 110 may correspond to a ride attraction. For example, the ride attraction may include tracks that pass by the animated FIG. 1000 and the guests may view certain portions the animated FIG. 1000 for a period of time. Moreover, the animated FIG. 1000 may include moveable components, which may be more expensive in comparison to non-moveable components. To determine such attributes, the user may place one or more filter tools 902 on the display surface 108 and the automation controller 102 may update and/or adjust the object visualization 116 based on the identified filter tools 902. For example, the automation controller 102 may control the projectors 122 to project a projection map of the animated FIG. 1000 based on the filter tool 902.

With the foregoing in mind, FIG. 17A is a cost projection map of an animated FIG. 1000 (e.g., associated with an object token 110 on the display surface 108). In particular, the display surface 108 may include one or more object tokens 110, including the object token 110 associated with the animated FIG. 1000 and an object

token 110 representing a ride attraction, and the user may place one or more filter tools 902 (e.g., including a cost filter) on the display surface 108, causing the cost projection map of FIG. 17A to be projected. the animated FIG. 1000 may include a monkey with animated eyes 1002 and an animated mouth 1004. For example, both the animated eyes 1002 and the animated mouth 1004 may appear to blink, change colors, emit a sound, and/or emit a light. The remaining portions of the animated FIG. 1000, such as the head, the ears, the nose, and the like may remain still. As such, a cost associated with the animated eyes 1002 and the animated mouth 1004 may be higher in comparison to the still portions (e.g., head, ears, nose).

The projection mapping of the animated FIG. 1000 may illustrate a relative cost associated with each portion of the animated FIG. 1000. As illustrated, the animated eyes 1002 are white, the animated mouth 1004 is gray, and the remaining portions are dark gray or black. In certain instances, the darker colors may represent a low cost, while the lighter colors represent a high cost. For example, the projection mapping illustrates that the animated eyes 1002 may cost more than the animated mouth 1004 to make and/or maintain over time. Additionally, the projection mapping illustrates that the animated mouth 1004 may cost more than the remaining (e.g., still) portions of the animated FIG. 1000. As such, the user may visually understand a relative cost associated with each portion of the animated FIG. 1000. In certain instances, a legend may be displayed adjacent the projection mapping to provide a cost corresponding to each color. For example, the white color may correspond to five-thousand dollars while the black color may correspond to with five-hundred dollars. In other embodiments, the color scale may start at white for low cost and go to black for high cost, the color scale may include red, green, and blue, or the color scale may include any suitable colors selected by user input.

With the foregoing in mind, FIG. 17B is viewing time projection map of the animated FIG. 1000. For example, the user may want to understand how often each portion of the animated FIG. 1000 may be viewed by guests). In an instance, the first object token 110 may be adjacent to the second object token 110, which may correspond to the animated FIG. 1000 being adjacent the ride attraction. As such, a first lateral side 1010 of the animated FIG. 1000 may face the track of the ride attraction, which may be viewed by the guests may view the first lateral side 1010 more often (e.g., longer

period of time) in comparison to a second lateral side 1012. Indeed, the second lateral side 1012 may face away from the track. To this end, the projection mapping of the animated FIG. 1000 may provide a visualization indicative of the amount of time each portion of the animated FIG. 1000 may be viewed by the guests during the ride attraction. For example, the first lateral side 1010 may be generally white or light gray to represent viewing by the guest over a longer period of time in comparison to the second lateral side 1012, which may be generally black or dark gray.

In certain instances, the ride attraction associated with the second object token 110 may wrap around a bottom portion of the animated FIG. 1000. As such, the projection mapping may illustrate a first longitudinal edge 1014 of the animated FIG. 1000 being generally black or dark gray, while a second longitudinal edge 1016 of the animated FIG. 1000 may be generally white or light gray. In other words, the first longitudinal edge 1014 may be viewed for a period of time less than the second longitudinal edge 1016. In certain instances, the user may utilize the viewing time projection to determine the attributes each portion of the animated FIG. 1000. For example, the user may select relatively cheaper materials for the second lateral side 1012 and relatively more expensive materials for the first lateral side 1010, since guests may view the first lateral side 1010 for a longer period of time in comparison to the second lateral side 1012. In another example, the user may spend less time designing the second lateral side 1012 in comparison to the first lateral side 1010.

With the foregoing in mind, FIG. 17C is a cost per viewing time projection map of the animated FIG. 1000. In certain instances, the user may want to understand the relationship between two attributes of the object token 110. As such, the user may combine or stack multiple filter tools 902 to overlay multiple attributes on the object visualization 116. For example, a first filter tool 902, 902A may include a cost filter that may be combined or stacked on top of a second filter tool 902, 902B that may include a viewing time filter. The automation controller 102 may identify the combined or stacked configuration of the first filter tool 902, 902A and the second filter tool 902, 902B and determine a relationship. For example, the automation controller 102 may determine the relationship to be cost per viewing time associated with each portion of the animated FIG. 1000.

As illustrated in the projection mapping, the animated eyes 1002 of the animated FIG. 1000 may be lighter in color in comparison to the remaining (e.g., still) portions of the animated FIG. 1000, such as the head or the ears. As such, projection mapping may indicate that the cost per viewing time of the animated eyes 1002 may be higher in comparison to the still portions of the animated FIG. 1000. Additionally, the first lateral side 1010 of the animated FIG. 1000 may be lighter in color in comparison to the second lateral side 1012, which may indicate that the cost per viewing may be higher in comparison to the second lateral side 1012. Based on the visualization, the user may put more resources into the first lateral side 1010 in comparison to the second lateral side 1012 as the viewing time by guests may be higher.

In an embodiment, the automation controller 102 may generate projection map of brightness per cost in response to identifying the brightness filter combined or stacked on top of the cost filter. For example, the eyes 1002 of the animated FIG. 1000 may emit an amount of light which may be associated with a cost. In certain instances, each eye 1002 may emit light at different times and/or for different lengths. As such, the projection map may visualize differences between the two eyes 1002. Additionally, the user may be interested in the viewing time for each eye 1002. As such, the user may place the brightness filter, the cost filter, and the viewing time filter in a combined or stacked configuration on the display surface 108 to cause the automation controller 102 projection map the brightness per cost and viewing time of the animated FIG. 1000. In an embodiment, the eyes 1002 of the animated FIG. 1000 may emit a sound. The filter tools 902 may include a volume filter, a cost filter, and a viewing time filter in a combined or stacked configuration. As such, the automation controller 102 may determine volume per cost and viewing time for each portion of the animated FIG. 1000 and control the projectors 122 to project the sound volume per cost and viewing time projection map.

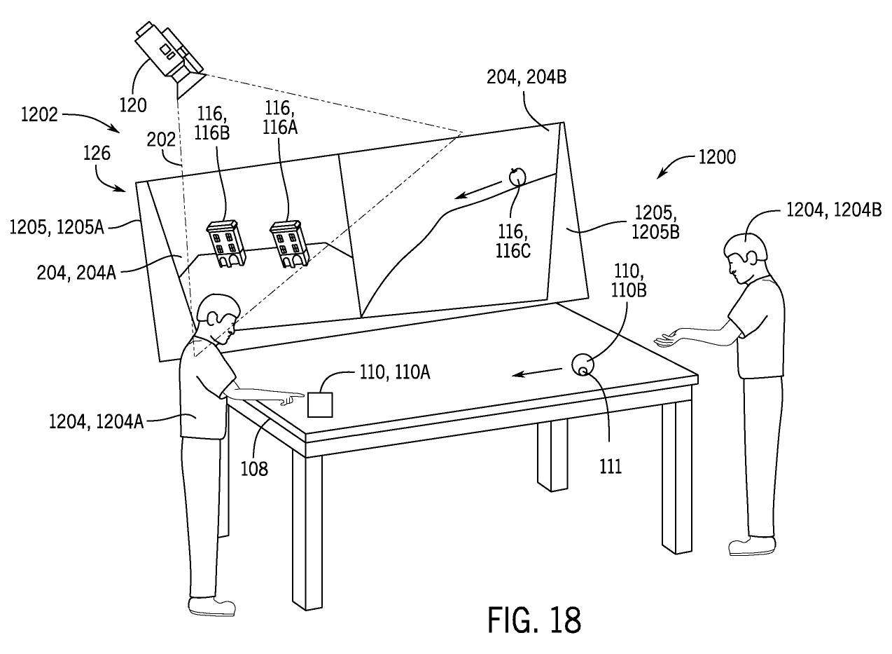

FIG. 18 is a perspective diagram that illustrates an example embodiment 1200 of the tangible/virtual design system 100 in FIG. 1 including the display surface 108, the image sensor 120, and the display 126, in accordance with an embodiment of the present disclosure. The tangible/virtual design system 1200 may include the image sensor 120 capturing images 202 of the display surface 108 and any number of object tokens 110, and the display 126 displaying the image content 204 for multiple users to

view. Additionally or alternatively, the image sensor 120 may capture images 1202 indicative of the multiple users and/or one or more users interacting with the tangible/virtual design system 1200. In the example embodiment of the tangible/virtual design system 1200, the display 126 may include an LED display that displays the image content 204. The image content 204 may include an object visualization 116 that corresponds to the object token 110 positioned on the display surface 108.

In certain instances, a first user 1204, 1204A and a second user 1204, 1204B (collectively referred herein as “the user 1204”) may interact with the tangible/virtual design system 1200, and the display 126 may display first image content 204, 204A for the first user 1204, 1204A and second image content 204, 204B for the second user 1204, 1204B. For example, the display 126 may display the first image content 204, 204A in a first portion 1205, 1205A of the display 126 and the second image content 204, 204B in a second portion 1205, 1205B of the display 126. As illustrated, the first image content 204, 204A may include a first object visualization 116, 116A and a second object visualization 116, 116B, and the second image content 204, 204B may include a third object visualization 116, 116C. As will be further described herein, the first object visualization 116, 116A may correspond to a first object token 110, 110A positioned on the display surface 108, and the third object visualization 116, 116C may correspond to a second object token 110, 110B positioned on the display surface 108. In an example, the first image content 204, 204A may be part of a first file (e.g., project) and the second image content 204, 204B may be part of a second file different from the first time. In other instances, the first image content 204, 204A and the second image content 204, 204B may be part of the same file. As such, the first user 1204, 1204A and the second user 1204, 1204B may edit (e.g., adjust) different projects, different portions of the same projects, different object visualizations 116, and so on.

The automation controller 102 may update one or more object visualization(s) 116 based on movement of the user 1204 (e.g., the user 450 described with respect to FIG. 9). For example, the automation controller 102 may identify movement of the first user 1204, 1204A and/or interactions between the first user 1204, 1204A and one or more object tokens 110 positioned on the display surface 108 based on the images 1202 and determine whether the movement of the first user 1204, 1204A corresponds to one or more stored movement(s) within the memory 106. The

automation controller 102 may use image analysis techniques to identify the movement of the user 1204 based on the image data. If the movement of the first user 1204, 1204A matches a stored movement of the one or more movement(s), the automation controller 102 may generate and/or adjust the first image content 204, 204A displayed by the display 126. Based on the images 1202, for example, the automation controller 102 may identify the first user 1204, 1204A pointing at the object token 110 positioned on the display surface 108, the first user 1204, 1204A turning a palm in different directions (e.g., along a yaw axis, a roll axis, a pitch axis), the first user 1204, 1204A rotating a hand (e.g., along the yaw axis, the roll axis, the pitch axis), the first user 1204, 1204A moving the hand in a horizontal direction (e.g., along a x-axis) or a vertical direction (e.g., along a y-axis), or any combination thereof. The automation controller 102 may compare the movement of the first user 1204, 1204A to the one or more stored movement(s) within the memory 106 to determine if the movement corresponds to instructions of adjusting the first image content 204, 204A. That is, the automation controller 102 may compare the movement to the one or more stored movement(s) to determine if a position and/or orientation of the first object visualization 116, 116A may be adjusted.

If the automation controller 102 determines that the movement matches a stored movement of the one or more stored movement(s), the automation controller 102 may generate updated first image content 204, 2024A for the display 126 to display based on the movement. For example, the automation controller 102 may identify the first user 1204, 1204A pointing at the first object token 110, 110A and subsequently pointing at another location of the display surface 108. The automation controller 102 may determine the pointing movements matches a stored movement, where the stored movement corresponds to instructions of generating a digital twin within the first image content 204, 204A. The second object visualization 116, 116B may be visually appear as a copy of the first object visualization 116, 116A, and as such, the second object visualization 116, 116B may be a “digital twin” of the first object visualization 116, 116A. The automation controller 102 may position the second object visualization 116, 116B at the location of the display surface 108 pointed at (e.g., selected) by the first user 1204, 1204A. The automation controller 102 may generate the updated first image content 204, 204A with a first object visualization 116, 116A corresponding to the first object token 110, 110A and a second object visualization 116, 116B corresponding to

a digital twin of the first object visualization 116, 116A. As such, the tangible/virtual design system 1200 may include object visualizations 116 that may not correspond to a physical object token 110 positioned on the display surface 108. The automation controller 102 may generate one or more digital twin(s) of any suitable object visualization 116 based on movement of the user 1204. Additionally, it should be understood that the movement of the user 1204 is merely exemplary, and any suitable movement of the user 1204 may provide instructions of generating a digital twin. For example, the user 1204 may input the movement by editing settings of the tangible/virtual design system 1200.

The automation controller 102 may adjust a position and/or orientation of the second object visualization 116, 116B based on movement of the first user 1204, 1204A. For example, the automation controller 102 may identify a palm of the first user 1204, 1204A rotating based on the images 1202 and determine if the rotating palms matches a stored movement of the one or more movement(s). The automation controller 102 may that the rotating palms correspond to instructions of adjusting a position and/or an orientation of the second object visualization 116, 116B. For example, the automation controller 102 may rotate a position of the second object visualization 116, 116B within the first image content 204, 204A based on the rotation of the palm. In another example, the automation controller 102 may zoom in on the second object visualization 116, 116B based on the palm (the palm of the left hand) rotating in a clockwise direction, and the automation controller 102 may zoom out on the second object visualization 116, 116B based on the palm (e.g., the palm of the right hand) rotating in a counterclockwise direction. In another example, the automation controller 102 may identify a pinching movement of the first user 1204, 1204A, which may correspond to zooming in or out of the second object visualization 116, 116B. As such, the automaton controller 102 may generate updated image content with an adjusted position and/or the orientation of the second object visualization 116, 116B. Still in another example, the automation controller 102 may identify the first user 1204, 1204A pointing at the second object visualization 116, 116B displayed by the display 126, and subsequently identify the user 1204 pointing at a different location of the display 126. The automation controller 102 may determine the pointing motion corresponds to adjusting the position of the second object visualization 116, 116B, and update the image content 204 based on the pointing. In this way, the user 1204 may

adjust a position and/or orientation of object visualizations 116 that may not be physically represented by (e.g., correspond to) object tokens 110. If the automation controller 102 does not determine a match between the movement of the user 1204 and a stored movement of the one or more movement(s), the automation controller 102 may not update the image content 204. It should be understood that the position and/or the orientation of the first object visualization 116, 116A may be adjusted based on the movement of the first user 1204, 1204A. For example, the first user 1204, 1204A may select the first object visualization 116, 116A by pointing at a location of the display 126 corresponding to the first object visualization 116, 116A. The automation controller 102 may adjust the first image content 204, 204A to provide an indication of the selection. For example, the automation controller 102 may highlight the first object visualization 116, 116A, increase an opacity of the first object visualization 116, 116A, decrease an opacity of the second object visualization 116, 116B, and so on. As such, the first user 1204, 1204A may adjust the position and/or the orientation of the first object visualization 116, 116A without adjusting the position and/or the orientation of the first object token 110, 110A.

The automation controller 102 may update a position and/or an orientation of the third object visualization 116, 116C based on movement of the second object token 110, 110B. For example, the automation controller 102 may identify the second user 1204, 1204B rolling or tossing the second object token 110, 110B across the display surface 108 within the images 1202. In another example, the automation controller 102 may receive an indication of movement from one or more sensor(s) 111 disposed within and/or coupled to the second object token 110, 110B. The automation controller 102 may generate updated second image content 204, 204B with the third object visualization 116, 116C moving in a similar manner as the second object token 110, 110B. That is, the position and/or the orientation of the third object visualization 116, 116C may be adjusted based on the movement of the second object token 110, 110B.

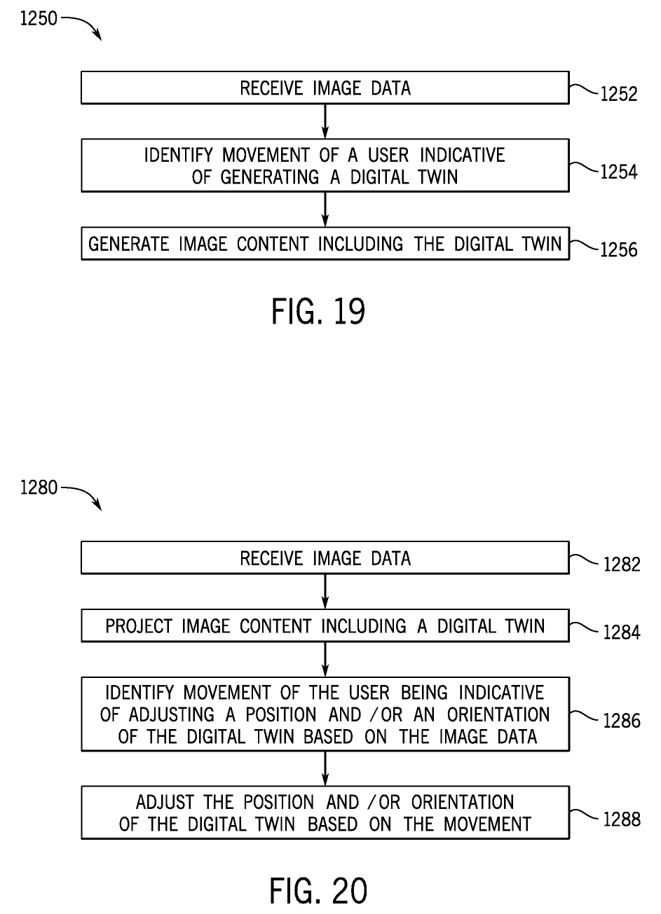

With the foregoing in mind, FIG. 19 illustrates a flowchart of a method or process 1250 for generating object visualizations using the tangible/virtual design system 1200 of FIG. 18, in accordance with embodiments of the present disclosure. While the process 1250 is described as being performed by the automation controller

102, it should be understood that the process 1250 may be performed by any suitable device or processing circuitry, such as the processor 104 and so forth, that may control and/or communicate with components of a tangible/virtual design system 1200. Furthermore, while the process 1250 is described using steps in a specific sequence, it should be understood that the present disclosure contemplates that the described steps may be performed in different sequences than the sequence illustrated, and certain described steps may be skipped or not performed altogether. In some embodiments, the process 1250 may be implemented by executing instructions stored in a tangible, non-transitory, computer-readable medium, such as the memory 106, using any suitable processing circuitry, such as the processor 104.

At block 1252, the automation controller 102 may receive image data. For example, the automation controller 102 may receive the images 202 and/or the images 1202 from the image sensor 120. The automation controller 102 may identify the display surface 108, one or more object tokens 110 positioned on the display surface 108, the user 1204, one or more movement(s) of the user 1204, and so on based on the images 202 and/or the images 1202.

At block 1254, the automation controller 102 may identify movement of the user 1204 being indicative of instructions to generate a digital twin (e.g., the second object visualization 116, 116B described with respect to FIG. 18) based on the image data. For example, the automation controller 102 may identify the user 1204 pointing at the object token 110 and pointing at another location of the display surface 108. The automation controller 102 may determine a match between the pointing movement and a stored movement of one or more stored movement(s) in the memory 106, where the stored movement may correspond to generating a digital twin within the image content 204. Although the illustrated example includes the user 1204 pointing at different locations of the display surface 108 to generate the digital twin, it should be understood that any suitable movement may correspond to movement of generating the digital twin. The movement may be set by the user 1204, adjusted by the user 1204, set by a manufacturer, and so on. For example, the user 1204 may set the movement for generating the digital twin as touching the object token 110 with a finger and touching a location of the display surface 108.

At block 1256, the automation controller 102 may generate image content 204 including the digital twin. The automation controller 102 may identify an object visualization 116 that corresponds to the object token 110 pointed at (e.g., selected) by the user 1204. The automation controller 102 may duplicate the object visualization 116 to generate the digital twin (e.g., the second object visualization 116, 116B) within the image content 204. The automation controller 102 may generate the image content such that a position the digital twin (as projected by the projectors 122 or displayed by the display 126) corresponds to the location pointed at by the user 1204. As such, the automation controller 102 may generate the object visualizations 116 that may not correspond to a physical object token 110, which may improve flexibility of the tangible/virtual design system 1200 and reduce a number of objects positioned on the display surface 108. In this way, the display surface 108 may not be limited by a size, and additionally, the tangible/virtual design system 1200 may not be limited in a number of objects that may be positioned on the display surface 108.

FIG. 20 is a flowchart of a method or a process 1280 for adjusting a position and/or an orientation of the object visualization 116 within the tangible/virtual design system 1200 of FIG. 18, in accordance with embodiments of the present disclosure. While the process 1280 is described as being performed by the automation controller 102, it should be understood that the process 1280 may be performed by any suitable device or processing circuitry, such as the processor 104 and so forth, that may control and/or communicate with components of a tangible/virtual design system 1200. Furthermore, while the process 1280 is described using steps in a specific sequence, it should be understood that the present disclosure contemplates that the described steps may be performed in different sequences than the sequence illustrated, and certain described steps may be skipped or not performed altogether. In some embodiments, the process 1280 may be implemented by executing instructions stored in a tangible, non-transitory, computer-readable medium, such as the memory 106, using any suitable processing circuitry, such as the processor 104.

At block 1282, the automation controller 102 may receive image data, similar to block 1252 described with respect to FIG. 19.

At block 1284, the automation controller 102 may instruct a display 126 and/or a projector 122 to project image content 204 including a digital twin. For

example, the tangible/virtual design system 1200 may include one object token 110 on the display surface 108, but the image content 204 may include two or more object visualizations 116. The object visualizations 116 may include a first object visualization 116, 116A that may correspond to the object token 110 and a second object visualization 116, 116B that may include a digital twin of the first object visualization 116, 116A. In certain instances, the object visualizations 116 may include a third object visualization 116, 116C that may include a digital twin of the first object visualization 116, 116A, and so on.

At block 1286, the automation controller 102 may identify movement of a user 1204 being indicative of instructions to adjust a position and/or an orientation of the digital twin based on the image data. The automation controller 102 may identify the user 1204 subsequently rotating their palm, moving their hand, pinching their fingers, and so on based on the images 1202. In certain instances, the image content 204 may include multiple digital twins. The automation controller 102 may identify the user 1204 pointing at a location of the display 126 that corresponds to a digital twin of the multiple digital twins. In another example, the automation controller 102 may identify the user 1204 pointing at a location of the display surface 108 that corresponds to a projection of the digital twin that may be projected by the projector 122. As such, the user 1204 may select a digital twin for adjustments.

At block 1288, the automation controller 102 may generate updated image content 204 based on the movement of the user 1204. The automation controller 102 may generate the updated image content 204 by adjusting a position and/or an orientation of the digital twin in a similar manner as the movement of the user 1204. For example, the automation controller 102 may rotate the position (e.g., along the yaw axis, the roll axis, the pitch axis) of the digital twin in a similar manner as a rotation of a hand of the user 1204. In another example, the automation controller 102 may adjust the position of the digital twin in the same direction as a movement of the hand of the user 1204. In certain instances, the automation controller 102 may adjust the position and/or the orientation of the digital twin based on a scaling factor. For example, the automation controller 102 may rotate the orientation of the digital twin by 30 degrees along the yaw axis based on identifying the hand of the user 1204 rotating by 15 degrees

along the yaw axis. As such, the automation controller 102 may apply a scaling factor of 2.

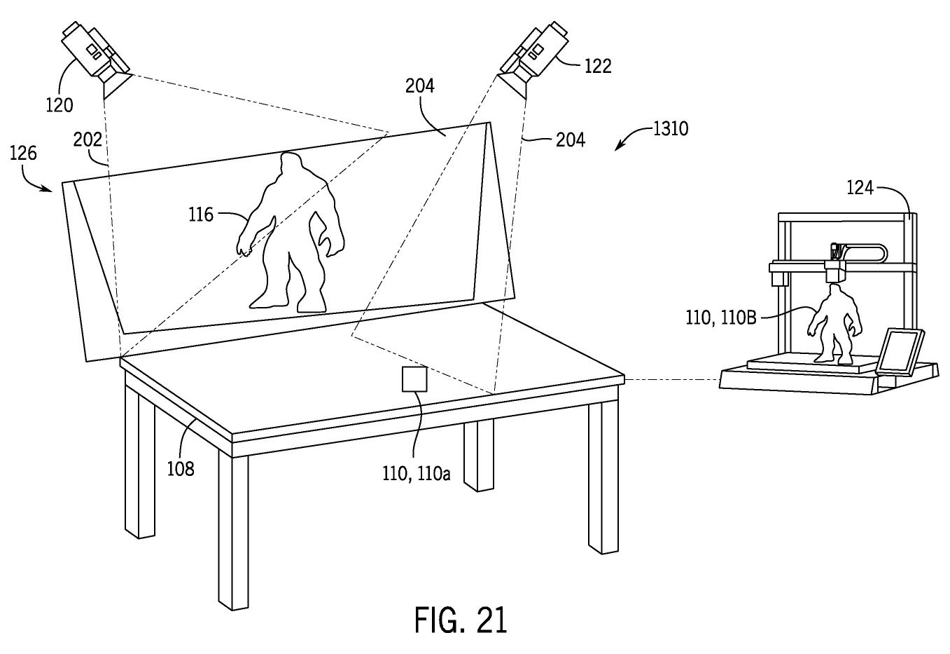

FIG. 21 is a perspective diagram of another example embodiment 1310 of the tangible/virtual design system 100 of FIG. 1 for designing and generating object tokens 110, in accordance with embodiments of the present disclosure. The image sensor 120 may generate images 202 indicative of the display surface 108 and any number of object tokens 110, and the display 126 may display the image content 204 for multiple users to view. In the example embodiment of the tangible/virtual design system 1310, the object tokens 110 may include a first object token 110, 110A shaped as a cube. The object visualization 116 corresponding to the first object token 110, 110A may include a monkey.

The object visualization 116 may be designed by a user (e.g., the user 1204 described with respect to FIG. 18), such as a prototype or a model, as part of a design process (e.g., design cycle). The user may modify and/or adjust object attributes of the object visualization 116 as part of the design process. As part of the design process, it may be beneficial to generate one or more object tokens 110 with similar object attributes as the object visualization may be modified and/or adjusted throughout the design process. That is, it may be beneficial to generate one or more object token(s) 110 visually resemble the object visualization 116 as the object visualization may be modified during the design process. To generate the object tokens 110, the automation controller 102 may transmit image data indicative of the object visualization 116 to the printer 128. The automation controller 102 may convert the image data into a file type used by the printer 1312. The image data may correspond to the image content 204 being displayed by the display 126 and/or the projectors 122. For example, the automation controller 102 may convert the image data into a stereolithography (STL) file, a wavefront object (OBJ) file, and so on. The file may include a three-dimensional (3D) representation of the object visualization 116. The printer 128 may include a three-dimensional (3D) printer that may print objects (e.g., models) using a wide range of materials, such as polylactic acid (PLA), polyethylene terephthalate glycol (PETG), polycarbonate (PC), Nylon, and so on. The automation controller 102 may instruct the printer 128 to generate a second object token 110, 110B that visually resembles the object visualization 116 based on the file. That is, the automation controller 102 may

instruct the printer 128 to generate the second object token 110, 110B corresponding to the object visualization 116 based on the 3D representation of the object visualization 116. As such, the tangible/virtual design system 1310 may generate object tokens 110 that resemble the corresponding object visualization 116. The user may analyze the second object token 110, 110B generated by the printer 128 as part of the design process.

The automation controller 102 may adjust the object attributes of second object token 110, 110B by instructing the projector 122 to projection map onto the second object token 110, 110B. The object attributes may include a color of the object token 110, details of the object token 110, and so on. For example, the projection mapping may overlay surface textures, lighting effects, shadowing, decorative elements, data visualization, and so on onto the second object token 110, 110B. For example, the projection mapping may include a heat map (e.g., the cost projection map described with respect to FIGS. 17A-C) corresponding to the object visualization 116. In another example, the projection mapping may overlay details, such as shading, shadows, and so on onto the second object token 110, 110B. As such, the second object token 110, 110B may visually resemble the object visualization 116.

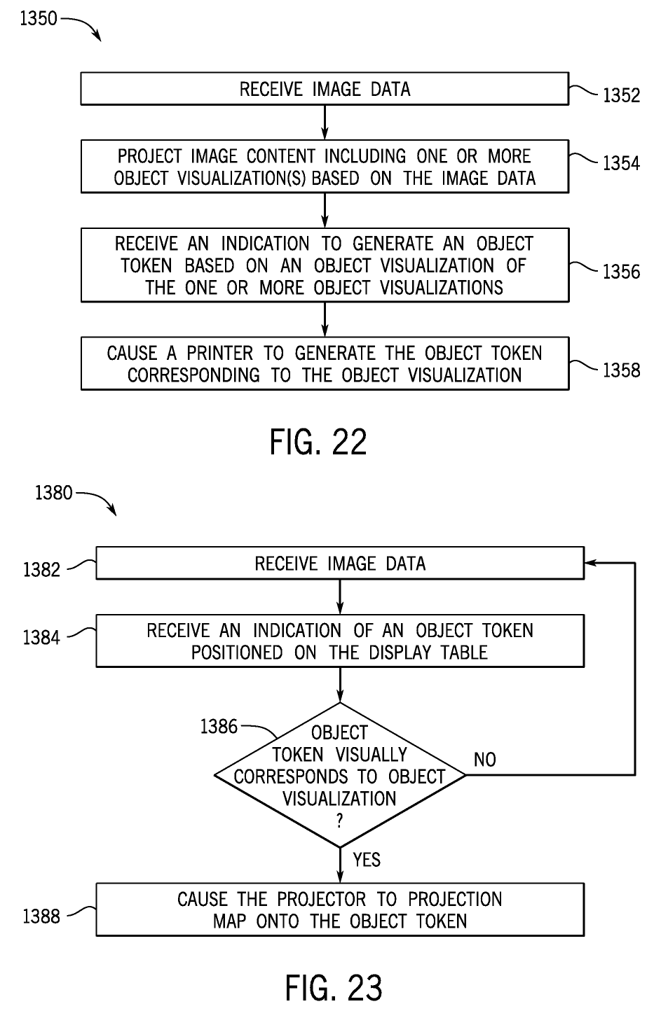

FIG. 22 is a flowchart of a method or a process 1350 for generating object tokens 110 using the tangible/virtual design system 1310 of FIG. 21, in accordance with embodiments of the present disclosure. While the process 1350 is described as being performed by the automation controller 102, it should be understood that the process 1350 may be performed by any suitable device or processing circuitry, such as the processor 104 and so forth, that may control and/or communicate with components of a tangible/virtual design system 1350. Furthermore, while the process 1350 is described using steps in a specific sequence, it should be understood that the present disclosure contemplates that the described steps may be performed in different sequences than the sequence illustrated, and certain described steps may be skipped or not performed altogether. In some embodiments, the process 1350 may be implemented by executing instructions stored in a tangible, non-transitory, computer-readable medium, such as the memory 106, using any suitable processing circuitry, such as the processor 104.

At block 1352, the automation controller 102 may receive image data, similar to block 1252 described with respect to FIG. 19 and block 1282 described with respect to FIG. 20.

At block 1354, the automation controller 102 may project image content based on the image data. For example, the automation controller 102 may instruct the display 126 and/or the projector 122 to project the image content 204. The image content 204 may include one or more object visualization(s) 116. For example, the user may work on existing project and/or file, and the automation controller 102 may adjust one or more object attribute(s) of the one or more object visualization(s) 116 based on input. In another example, the user may start a new object and/or file. The automation controller 102 may generate an object visualization based on input from the user.

At block 1356, the automation controller 102 may receive an indication to generate an object token 110 based on an object visualization 116 of the one or more object visualization(s) 116. For example, the automation controller 102 may receive the indication via the display surface 108. In another example, the automation controller 102 may receive the indication to generate the object token 110 based on the images 1202 being indicative of a movement the user corresponding to a movement indicative of generating the object token 110. For example, the movement may include the user pointing at the location of the display 126 that corresponds to the object visualization 116 and subsequently pointing at the printer 128.

At block 1358, the automation controller 102 may cause the printer 128 to generate the object token 110 corresponding to the selected object visualization 116. For example, the automation controller 102 may retrieve the image content 204 displayed by the display 126 and/or the projector 122, where the image content 204 may include the selected object visualization 116. The printer 128 may generate the object token 110 by 3D printing a model that corresponds to the object visualization 116. The object token 110 may be a model that may be generated as part of a design process and facilitate an iterative design process. The object token 110 may be positioned on the display surface 108 in place of a previous object token 110. In another example, the object token 110 may correspond to a digital twin and may be positioned on the display surface 108 to provide a physical representation of the digital twin.

FIG. 23 is a flowchart of a method or a process 1380 for adjusting object attributes of an object token 110 via the tangible/virtual design system 1310 of FIG. 21, in accordance with embodiments of the present disclosure. While the process 1380 is described as being performed by the automation controller 102, it should be understood that the process 1380 may be performed by any suitable device or processing circuitry, such as the processor 104 and so forth, that may control and/or communicate with components of a tangible/virtual design system 1310. Furthermore, while the process 1380 is described using steps in a specific sequence, it should be understood that the present disclosure contemplates that the described steps may be performed in different sequences than the sequence illustrated, and certain described steps may be skipped or not performed altogether. In some embodiments, the process 1380 may be implemented by executing instructions stored in a tangible, non-transitory, computer-readable medium, such as the memory 106, using any suitable processing circuitry, such as the processor 104.

At block 1382, the automation controller 102 may receive image data, similar to block 1352 described with respect to FIG. 22.

At block 1384, the automation controller 102 may receive an indication of an object token 110 positioned on the display surface 108. The automation controller 102 may store the image data over time to identify changes within the image data, such as an additional of object tokens 110 to the display surface 108, a removal of object tokens 110 from the display surface 108, an adjustment of a position and/or an orientation of the object tokens 110 with respect to the display surface 108, and so on. The automation controller 102 may identify changes to the display surface 108 by comparing image data from the image sensor 120 to stored image data in the memory 106. The stored image data may include image data generated by the image sensor 120 at a point in time prior to the generation of the image data. For example, the automation controller 102 may identify a new object token 110 positioned on the display surface 108 based on the comparison. In another example, the automation controller 102 may identify the new object token 110 based on an indication of the object token 110 being placed on the display surface 108 via a sensor coupled to and/or disposed within the display surface 108. The sensor may include a weight sensor that generates sensor data indicative of an amount of weight applied to the display surface 108. The automation

controller 102 may identify the addition of an object token 110 based on an increase in the weight.

In response to receiving the indication of the object token 110 being added to the display surface 108, the automation controller 102 may identify a corresponding object visualization 116. The automation controller 102 may update the image content 204 to include the object visualization 116.

At block 1386, the automation controller 102 may determine whether the object token 110 visually resembles the object visualization 116. The automation controller 102 may perform image analysis to identify a shape and/or object attributes of the object token 110 and compare the shape and/or the object attributes to a shape and/or attributes of the object visualization 116. For example, the automation controller 102 may determine that the object token 110 may be shaped as a cube using image analysis techniques based on the images 202, and the automation controller 102 may determine that the object visualization 116 may be shaped as a dragon. In certain instances, the automation controller 102 may determine a likelihood of whether the object token 110 visually resembles the object visualization 116 and compare the likelihood to a threshold likelihood. The threshold likelihood may be 50%, 75%, 90%, 95%, and so on, for example. If the likelihood is greater than or equal to the threshold likelihood, the automation controller 102 may determine that object token 110 visually represents the object visualization 116. If the likelihood is less than the threshold likelihood, the automation controller 102 may determine that the object token 110 does not visually represent the object visualization 116. As such, the automation controller 102 may determine the object token 110 does not visually resemble the object visualization 116. In another example, the automation controller 102 may determine the object token 110 may be shaped as a train and determine that the object visualization 116 may also be shaped as a train. As such, the automation controller 102 may determine the object token 110 does visually resemble the object visualization.

If the object token 110 visually resembles (e.g., corresponds) to the object visualization 116, at block 1388, the automation controller 102 may cause the projector 122 to projection map onto the object token 110. For example, the object token 110 may include a white dragon because the printer 124 may use white filament, and the object visualization includes a green dragon. To adjust the attributes of the object token

110, the projector 122 may overlay a color onto an exterior surface of the object token 110. The color projected by the projector 122 may correspond to a color of the object visualization 116. For example, the projector 122 may project the color green onto the object token 110 such that the object token 110 more closely resembles the object visualization 116. Additionally or alternatively, the projector 122 may project details onto the object token 110. For example, the projector 122 may project image content 204 corresponding to a scaly dragon texture onto the exterior surface of the object token 110. In another example, the projector 122 may project image content 204 corresponding to eyes of the dragon onto the exterior surface of the object token 110. That is, the eyes of the dragon may be too small or include too many details for the printer 124 to incorporate into the object token 110. As such, the projection mapping may adjust the object attributes of the object token 110 such that the object token 110 more closely resembles the object visualization 116. The details projected by the projector 122 may correspond to details of the object visualization 116. As such, the object token 110 may provide a physical representation of the object visualization 116.

If the object token 110 does not visually correspond to the object visualization 116, the process 1380 may return to block 1382 to receive the image data, block 1384 to receive an indication of an object token 110 positioned on the display surface 108, and block 1386 to determine if the object token 110 visually corresponds to the object visualization 116.

While only certain features of the invention have been illustrated and described herein, many modifications and changes will occur to those skilled in the art. It is, therefore, to be understood that the appended claims are intended to cover all such modifications and changes as fall within the true spirit of the invention.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for (perform)ing (a function)…” or “step for (perform)ing (a function)…”, it is intended that such elements are to be interpreted under 35 U.S.C. 112(f). However, for any claims containing elements designated in

any other manner, it is intended that such elements are not to be interpreted under 35 U.S.C. 112(f).

1. An amusement park attraction design system, comprising:
an object token comprising a sensor configured to generate a sensor signal;
an image sensor configured to generate image data indicative of the object token;
a controller communicatively coupled to the image sensor, wherein the controller is configured to:
receive the image data from the image sensor;
determine movement of the object token based on the image data;
generate first image content based on the sensor signal indicating that the movement is intentional; and
generate second image content based on the sensor signal indicating that the movement is unintentional; and
a projector communicatively coupled to the controller, wherein the projector is configured to output the first image content or the second image content.

2. The amusement park attraction design system of claim 1, wherein the controller is configured to:
determine that the movement of the object token is intentional based on the sensor signal indicating the movement of the object token; and
generate the first image content based on the movement of the object token.

3. The amusement park attraction design system of claim 1, wherein the controller is configured to:
determine the movement of the object token is unintentional based on the sensor signal not indicating the movement of the object token; and
generate the second image content based on a position or an orientation of the object token prior to the movement.

4. The amusement park attraction design system of claim 1, wherein the controller is configured to:
identify a user within the image data from the image sensor;
determine the movement of the object token is unintentional based on identifying the user inadvertently moving the object token within the image data; and
generate the second image content based on a position and/or an orientation of the object token prior to the user inadvertently moving the object token.

5. The amusement park attraction design system of claim 1, comprising a plurality of object tokens, wherein the plurality of object tokens comprises the object token, and wherein the controller is configured to:
identify similar movement between each object token of the plurality of object tokens;
determine the movement of each object token of the plurality of object tokens is intentional based on the similar movement; and
generate the first image content for each object token of the plurality of object tokens.

6. The amusement park attraction design system of claim 1, wherein the controller is configured to:
receive an indication of setting a portion of a display surface coupled to the object token to an inactive status; and
set a status of the object token to the inactive status based on the object token being within the portion of the display surface set to the inactive status.

7. The amusement park attraction design system of claim 6, wherein the controller is configured to:
receive additional image data from the image sensor;
identify additional movement of the object token based on the additional image data; and
determine the additional movement to be unintentional based on the inactive status of the object token.

8. The amusement park attraction design system of claim 1, wherein the object token comprises machine-readable indicia exposed on a surface of the object token, and wherein the controller is configured to:
identify the machine-readable indicia within the image data;
identify an object visualization based on the machine-readable indicia; and
generate the first image content based on the object visualization and the movement being intentional.

9. The amusement park attraction design system of claim 1, wherein the sensor comprises a capacitive touch sensor, an electronic switch, a button, a proximity sensor, a camera, or an optical mouse sensor.

10. A method, comprising:
receiving, via processing circuitry, image data indicative of an object token from an image sensor, wherein the object token comprises a sensor configured to generate a sensor signal;
determining, via the processing circuitry, an indication of movement of the object token based on the image data;
generating, via the processing circuitry, first image content based on the sensor signal indicating that the movement of the object token is intentional; and
generating, via the processing circuitry, second image content based on the sensor signal indicating that the movement of the object token is unintentional.

11. The method of claim 10, comprising:
receiving, via the processing circuitry, the sensor signal from the sensor indicating that the movement of the object token is intentional; and
generating, via the processing circuitry, the first image content based on the movement of the object token.

12. The method of claim 10, comprising determining, via the processing circuitry, the movement of the object token to be unintentional based on the sensor signal not indicating the movement of the object token.

13. The method of claim 12, comprising:
applying, via the processing circuitry, a rounding threshold to an image analysis technique used to determine the indication of movement of the object token.

14. The method of claim 10, comprising:
identifying, via the processing circuitry, a user within the image data;
determining, via the processing circuitry, the user interacting with the object token; and
determining, via the processing circuitry, the movement of the object token to be intentional based on the user interaction and the sensor signal indicating the movement of the object token is intentional.

15. The method of claim 10, comprising:
identifying, via the processing circuitry, the movement of the object token matching an additional movement of an additional object token based on the image data; and
grouping, via the processing circuitry, the object token and the additional object token; and
updating, via the processing circuitry, the first image content based on the grouping, the movement, and the additional movement.

16. An amusement park attraction design system, comprising:
an object token comprising a tracker, machine-readable indicia, and a sensor, wherein the sensor is configured to generate a sensor signal;
an image sensor configured to generate image data indicative of the object token; and
a controller communicatively coupled to the image sensor, wherein the controller is configured to:
receive the image data from the image sensor;
determine a position and/or an orientation of the object token based on the tracker;
determine movement of the object token from a first position to a second position based on the image data and the tracker;
generate first image content based on the sensor signal indicating that the movement is intentional; and
generate second image content based on the sensor signal indicating that the movement is unintentional; and
a projector communicatively coupled to the controller and configured to output the first image content or the second image content.

17. The amusement park attraction design system of claim 16, wherein the controller is configured to:
generate an object visualization corresponding to the object token based on the movement of the object token to the second position based on the sensor signal indicating the movement of the object token is intentional; and
generate the first image content comprising the object visualization based on the movement of the object token.

18. The amusement park attraction design system of claim 17, wherein the controller is configured to determine the object visualization associated with the object token based on the machine-readable indicia.

19. The amusement park attraction design system of claim 16, wherein the controller is configured to:
identify a user within the image data from the image sensor;
determine the movement of the object token is unintentional based on identifying the user inadvertently moving the object token within the image data; and
generate the second image content based on the position and/or the orientation of the object token in the first position.

20. The amusement park attraction design system of claim 16, wherein the controller is configured to:
receive user input indicative of a status of the object token; and
determine the movement is unintentional based on the status of the object token being inactive.
